(19) United States
(12) Patent Application Publication
(10) Pub. No.: US 2026/0139378 A1
(43) Pub. Date: May 21, 2026

(54) PULSED PLASMA ENHANCED CHEMICAL VAPOR DEPOSITION PROCESS, SYSTEM, AND COATED VESSELS

(71) Applicant: SiO2 Medical Products, Inc., Auburn, AL (US)

(72) Inventors: Ahmad Taha, Auburn, AL (US); Matthew Wills, Aurburn, AL (US); Robert Abrams, Auburn, AL (US)

(21) Appl. No.: 19/449,007

(22) Filed: Jan. 14, 2026

Related U.S. Application Data
(63) Continuation of application No. 18/020,867, filed on Feb. 10, 2023.

(51) Int. Cl. C23C 16/505; C23C 16/02; C23C 16/40; C23C 16/54

(52) U.S. Cl. CPC C23C 16/505; C23C 16/0272; C23C 16/401; C23C 16/54

(57) ABSTRACT

Methods and systems for processing a plurality of vessels, for example to provide a gas barrier, are disclosed. The gas barrier may be deposited using pulsed plasma enhanced chemical vapor deposition concurrently in a plurality of vessels where each vessel is within an opening of an RF electrode.

The present application is a continuation of U.S. patent application Ser. No. 18/020,867, filed on Feb. 10, 2023, as a national stage entry of International Application No. PCT/US2021/045819, filed on Aug. 12, 2021, which claims priority to U.S. Provisional Patent Application No. 63/064,831, filed on Aug. 12, 2020.

The present invention relates to the technical field of coated vessels and fabrication of coated vessels for storing pharmaceutical solutions, biologically active compounds, or blood. For example, the invention relates to a system for coating of a vessel by plasma enhanced chemical vapor deposition (PECVD), to a pulsed plasma enhanced chemical vapor deposition system for coating an interior surface of a vessel, to a method for coating a vessel, e.g. an interior surface of a vessel by pulsed PECVD, and to vessels coated by the pulsed plasma enhanced chemical vapor deposition methods and systems described herein.

The present disclosure also relates to improved methods for processing vessels, for example multiple identical vessels used for venipuncture and other medical sample collection, pharmaceutical preparation storage and delivery, and other purposes. Such vessels are used in large numbers for these purposes, and must be relatively economical to manufacture, consistent in properties from one vessel to the next, and highly reliable in storage and use.

### BACKGROUND OF THE INVENTION

One important consideration in manufacturing pharmaceutical packages or other vessels for storing or other contact with fluids, for example vials and pre-filled syringes, is that the contents of the pharmaceutical package or other vessel desirably will have a substantial shelf life.

The traditional glass pharmaceutical packages or other vessels are prone to breakage or degradation during manufacture, filling operations, shipping and use, which means that glass particulates may enter the drug. The presence of glass particles has led to many FDA Warning Letters and to product recalls.

As a result, some companies have turned to plastic pharmaceutical packages or other vessels, which provide greater dimensional tolerance and less breakage than glass, but its use for primary pharmaceutical packaging remains limited due to its gas (oxygen) permeability: Plastic allows small molecule gases to permeate into (or out of) the article. In addition to oxygen, many plastic materials also allow moisture, i.e. water vapor, to permeate into (or out of) the article. The permeability of plastics to gases is significantly greater than that of glass and, in many cases (as with oxygen-sensitive drugs such as epinephrine), plastics have been unacceptable for that reason.

The problem of permeability has been addressed by using Cyclic Olefin Polymer (“COP”) or Cyclic Olefin Copolymer (“COC”) resins and by adding a barrier coating or layer to the plastic pharmaceutical package where it contacts fluid contents of the package. One such barrier layer is a very thin coating of SiOₓ, as defined below, applied by plasma enhanced chemical vapor deposition. But the coating of plastic packages of this sort, e.g. syringe barrels, vials, and the like, has conventionally been performed on a vessel-by-vessel basis, in which a single vessel or a small number (4 or less) of vessels are coated by a given system at one time. The use of such a system has made it difficult to obtain consistency between the coating(s) applied to vessels. In addition to the small number of vessels being coated at a given time, the low powers used with such systems cause the process to take a relatively long time (e.g., about 1.5 minutes per layer, resulting in a process that takes about four minutes to coat 4 vessels with a trilayer coating described herein).

Moreover, resins such as COP and COC are also relatively expensive and difficult to produce or obtain in high quantities. Accordingly, the cost of those materials plays a significant role in the overall cost to manufacture a pharmaceutical package. And as the scale and rate of vessel coating is increased by embodiments of the present disclosure, the difficulty to produce or obtain COP and COC in high quantities may pose significant limitations on the overall scale and/or rate of production of coated vessels and pharmaceutical packages utilizing those coated vessels.

### SUMMARY OF THE INVENTION

An aspect of the invention is a vessel having a lumen defined at least in part by a wall, the wall having an interior surface facing the lumen, an outer surface, and a coating set on the interior surface comprising an optional tie coating or layer, a barrier coating or layer, and an optional pH protective coating or layer.

The tie coating or layer, if present, can comprise SiOxCy or Si(NH)xCy. In either formulation, x is from about 0.5 to about 2.4 and y is from about 0.6 to about 3. The tie coating or layer has an interior surface facing the lumen and an outer surface facing the wall interior surface.

The barrier coating or layer can comprise SiOx, wherein x is from 1.5 to 2.9. Alternatively, the barrier coating or layer can comprise one or more metals or metal oxides, such as Al₂O₃, or combinations thereof. The barrier layer can be from 2 to 1000 nm thick. It can have an interior surface facing the lumen and an outer surface facing the interior surface of the tie coating or layer. The barrier coating or layer is effective to reduce the ingress of atmospheric gas into the lumen compared to a vessel without a barrier coating or layer. In some embodiments, the barrier coating or layer can comprise both one or more layers of SiOₓ, wherein x is from 1.5 to 2.9, and one or more layers of metal or metal oxide, such as Al₂O₃. The SiOₓ coating or layer may be effective to reduce the ingress of oxygen into the lumen compared to a vessel without a barrier coating or layer and the Al₂O₃ layer may be effective to reduce the ingress of water vapor (i.e. moisture) into the lumen compared to a vessel without a barrier coating or layer.

The pH protective coating or layer, if present, can comprise SiOxCy or Si(NH)xCy, where x is from about 0.5 to about 2.4 and y is from about 0.6 to about 3. The pH protective coating or layer can have an interior surface facing the lumen and an outer surface facing the interior surface of the barrier coating or layer.

In an embodiment, a vessel having a lumen is defined at least in part by a wall, the wall comprising a thermoplastic material and having an interior surface facing the lumen, an outer surface, and a coating on the interior surface comprising at least one barrier coating or layer and optionally at least one pH protective coating or layer and/or at least one tie coating or layer. The at least one barrier coating or layer comprising SiOx, wherein x is from 1.5 to 2.9, the barrier coating or layer being effective to reduce the ingress of atmospheric gas into the lumen compared to a vessel without a barrier coating or layer, the at least one pH protective coating or layer, if present, comprising SiOₓC_{y} or SiNₓC_{y}, wherein x is from about 0.5 to about 2.4 and y is from about 0.6 to about 3, the at least one tie coating or layer, if present, comprising SiOₓC_{y} or SiNₓC_{y}, wherein x is from about 0.5 to about 2.4 and y is from about 0.6 to about 3; the at least one barrier coating or layer and the at least one pH protective coating or layer and/or tie coating or layer, if present, being applied by pulsed RF plasma enhanced chemical vapor deposition, optionally with no interface layer between the barrier layer and the pH protection layer and/or tie layer from being exposed to air; under conditions by which at least the barrier coating or layer has a reduced thickness relative to conventional barrier coatings of SiOx (e.g. having a thickness of less than 20 nm compared to a conventional barrier coating with a thickness of about 80 nm) and an improved (i.e. lower) oxygen transmission relative to conventional barrier coatings of SiOx (e.g. having an oxygen transmission rate at a thickness of 15 nm, which would not be obtained by a conventional barrier coating of SiOx until the conventional coating reached a thickness of about 80 nm).

In some embodiments, for instance, the barrier coating or layer of SiOx may have an average thickness less than 200 nm, optionally less than 150 nm, optionally less than 125 nm, optionally less than 100 nm, optionally less than 80 nm, optionally less than 60 nm, optionally less than 50 nm, optionally less than 40 nm, optionally less than 30 nm, optionally less than 25 nm, optionally less than 20 nm, optionally less than 15 nm, optionally less than 10 nm, and the oxygen transmission rate (d-1) of the vessel wall may be less than 0.020, optionally less than 0.015, optionally less than 0.010, optionally less than 0.005, optionally less than 0.0025, optionally less than 0.0015, optionally less than 0.0010, optionally less than 0.0008, optionally less than 0.0006, optionally less than 0.0005, optionally less than 0.0004, optionally less than 0.0003, optionally less than 0.0002, optionally less than 0.0001.

In addition to vessels having improved oxygen transmission rates per thickness of coating, vessels prepared according to the methods and systems described herein are provided with greater consistency in coating thicknesses and properties (e.g. oxygen transmission rate, silicon dissolution by fluids at a given pH, etc.) throughout a plurality of vessels manufactured over long periods of time, e.g. hours, days, weeks, months, etc. By scaling up the number of vessels that can be coated by a system at a given time, the cost to produce each vessel may also be reduced.

Moreover, in some embodiments, the vessel, vessel wall, or at least a portion of the vessel wall may be made of a lower cost thermoplastic than the COP and COC resins that have been used in the past. In some embodiments, for example, the vessel, vessel wall, or at least a portion of the vessel wall may comprise or be made of a cyclic block co-polymer (CBC). Cyclic block copolymers are fully hydrogenated polymers based on styrene and conjugated dienes via anionic polymerization. Examples of cyclic block co-polymers include, for example, those in the VIVION™ family, such as VIVION™ 0510 or VIVION™ 0510HF or VIVION™ 1325, manufactured by USI Corporation (Taiwan). Cyclic block copolymers are lower cost materials relative to COP and COC resins, due at least in part to lower cost raw materials (styrene, butadiene, hydrogen, and cyclohexane solvent) and lower cost catalysts used in the polymerization and finishing processes. The use of cyclic block copolymers is limited by the fact that they are much more permeable to oxygen than COP and COC resins. However, the improvements in oxygen transmission rate (d-1) provided by embodiments of the present invention have allowed, for the first time, the use of cyclic block copolymers for the preparation of pharmaceutical vessels and packages such as vials, syringes, and the like, which require significant barrier properties.

Just as the methods and systems described herein provide for the scaling-up of the vessel coating process, both in the amount of time required for the coating process and the number of vessels that can be coated with a given system, the ability to move from COP and COC resins to CBC resins provides for additional improvements in the ability to scale up the production of coated vessels and filled pharmaceutical packages.

Because the raw materials, e.g. monomers, catalysts, etc., used to produce COP and COC resins are not available in large quantities, the number of COP or COC vessels that can be made within a defined time may be limited. Accordingly, as the speed and scale by which the vessels are coated is increased by the methods and systems disclosed herein, the ability to produce the COP or COC resins and vessels may become a limitation on the scale and/or rate of production of the final product, i.e. the coated (and optionally filled) vessel. In contrast, the raw materials, e.g. the monomers, catalysts, etc., used to produce and finish CBC resins are commodity grade materials that are readily available in large quantities and from multiple manufacturers. Thus, by enabling the use of vessels made from CBC resins, the methods and systems described herein may also remove additional limitations on production scale and/or rate, such as those associated with the production the vessels themselves.

Many additional and alternative aspects and embodiments of the invention are also contemplated, and are described in the specification and claims that follow. Some optional features contemplated for any of the embodiments include the following:

A vessel as previously described is contemplated in any embodiment, in which at least a portion of the wall of the vessel comprises, consists essentially of, or consists of a cyclic olefin polymer such as Cyclic Olefin Polymer (“COP”) or Cyclic Olefin Copolymer (“COC”), a lower-cost cyclic block copolymer (CBC) resin as described above, or any of a variety of other known thermoplastics such as PET, polyethylene, nylon, polypropylene, a polyamide, polystyrene, polycarbonate, TRITAN™ (a product of Eastman Chemical Company), a thermoplastic olefinic polymer, or the like.

A vessel as previously described is contemplated in any embodiment is contemplated in any embodiment in any embodiment, comprising a syringe barrel, a vial, a blister package, or a blood collection tube.

A vessel as previously described is contemplated in any embodiment, in which the barrier coating or layer is applied by pulsed radio frequency (RF) plasma enhanced chemical vapor deposition (PECVD) which may also be known as pulsed plasma impulse chemical vapor deposition (pulsed PICVD) and is from 1 to 50 nm thick, alternatively from 1 to 20 nm thick, alternatively from 2 to 15 nm thick.

A vessel as previously described is contemplated in any embodiment, in which the tie layer and/or the pH protective coating or layer comprises SiOxCy.

A vessel as previously described is contemplated in any embodiment, in which the tie layer and/or the pH protective coating or layer is applied by pulsed RF PECVD of a precursor feed comprising an acyclic siloxane, a monocyclic siloxane, a polycyclic siloxane, a polysilsesquioxane, a monocyclic silazane, a polycyclic silazane, a polysilsesquiazane, a silatrane, a silquasilatrane, a silproatrane, an azasilatrane, an azasilquasiatrane, an azasilproatrane, or a combination of any two or more of these precursors.

A vessel as previously described is contemplated in any embodiment, in which the tie layer and/or the pH protective coating or layer is applied by pulsed RF PECVD of a precursor feed comprising a linear siloxane or linear silazane, for example hexamethyldisiloxane (HMDSO) or tetramethyldisiloxane (TMDSO), or a cyclic siloxane, for example octamethylenecyclotetrasiloxane (OMCTS).

A vessel as previously described is contemplated in any embodiment, in which the pH protective coating or layer as applied is between 10 and 1000 nm thick.

A vessel as previously described is contemplated in any embodiment, in which the rate of erosion of the pH protective coating or layer, if directly contacted by a fluid composition having a pH of 8, is less than 20% of the rate of erosion of the barrier coating or layer, if directly contacted by the same fluid composition under the same conditions.

A vessel as previously described is contemplated in any embodiment, in which the pH protective coating or layer is at least coextensive with the barrier coating or layer.

A vessel as previously described is contemplated in any embodiment, in which the fluid composition removes the pH protective coating or layer at a rate of 1 nm or less of pH protective coating or layer thickness per 44 hours of contact with the fluid composition.

A vessel as previously described is contemplated in any embodiment, further comprising a lubricity coating or layer applied between the pH protective coating or layer and the lumen.

A vessel as previously described is contemplated in any embodiment, in which an FTIR absorbance spectrum of the pH protective coating or layer has a ratio greater than 0.75 between:
the maximum amplitude of the Si—O—Si symmetrical stretch peak between about 1000 and 1040 cm-1, and
the maximum amplitude of the Si—O—Si asymmetric stretch peak between about 1060 and about 1100 cm⁻¹.

A vessel as previously described is contemplated in any embodiment, in which the silicon dissolution rate by a 50 mM potassium phosphate buffer diluted in water for injection, adjusted to pH 8 with concentrated nitric acid, and containing 0.2 wt. % polysorbate-80 surfactant from the vessel is less than 170 ppb/day.

A vessel as previously described is contemplated in any embodiment, in which the total silicon content of the pH protective coating or layer and barrier coating or layer, upon dissolution into 0.1 N potassium hydroxide aqueous solution at 40° C. from the vessel, is less than 66 ppm.

A vessel as previously described is contemplated in any embodiment, in which the calculated shelf life (total Si/Si dissolution rate) is more than 2 years.

A vessel as previously described is contemplated in any embodiment, wherein the pH protective coating or layer shows an O-Parameter measured with attenuated total reflection (ATR) of less than 0.4, measured as:

$$O - Parameter = ( Intensity at 1253 {cm}^{- 1} / Maximum intensity in the range 1000 - 1100 {cm}^{- 1} ) .$$

A vessel as previously described is contemplated in any embodiment, wherein the pH protective coating or layer shows an N-Parameter measured with attenuated total reflection (ATR) of less than 0.7, measured as:

$$N - Parameter = ( Intensity at 840 {cm}^{- 1} / Intensity at 799 {cm}^{- 1} ) .$$

A vessel as previously described is contemplated in any embodiment, in which the pH protective coating or layer and/or the tie coating or layer is applied by pulsed RF PECVD of a precursor feed comprising octamethylcyclotetrasiloxane (OMCTS), tetramethyldisiloxane (TMDSO), or hexamethyldisiloxane (HMDSO).

A vessel as previously described is contemplated in any embodiment, in which the tie coating or layer, if present, is on average between 5 and 200 nm thick.

A vessel as previously described is contemplated in any embodiment, in which the tie coating or layer is at least coextensive with the barrier coating or layer.

A vessel as previously described is contemplated in any embodiment, in which the tie coating or layer is applied by pulsed RF PECVD.

A vessel as previously described is contemplated in any embodiment, in which the barrier coating or layer is 1 to 50 nm thick, alternatively from 1 to 20 nm thick, alternatively from 2 to 15 nm thick.

A vessel as previously described is contemplated in any embodiment, in which the barrier coating or layer is applied by pulsed RF PECVD.

A vessel is contemplated in any embodiment, in which the vessel has a lumen defined at least in part by a plastic wall, the plastic wall having an interior surface facing the lumen, an outer surface, and a coating set on the interior surface comprising: a barrier coating or layer of SiOx, wherein x is from 1.5 to 2.9 as determined by XPS, and optionally at least one, or both, of: a tie coating or layer of SiOxCy or SiNxCy, wherein x is from about 0.5 to about 2.4 and y is from about 0.6 to about 3, each as determined by XPS, and a pH protective coating or layer of SiOxCy or SiNxCy, wherein x is from about 0.5 to about 2.4 and y is from about 0.6 to about 3, each as determined by XPS; wherein the vessel is made of a cyclic block copolymer (CBC) resin; and wherein the oxygen transmission rate (d⁻¹) of the vessel wall is less than 0.020, optionally less than 0.015, optionally less than 0.010, optionally less than 0.005, optionally less than 0.0025, optionally less than 0.0015, optionally less than 0.0010, optionally less than 0.0008, optionally less than 0.0006, optionally less than 0.0005. The barrier coating or layer may have an average thickness less than 500 nm, optionally less than 400 nm, optionally less than 300 nm, optionally less than 200 nm, optionally less than 150 nm, optionally less than 125 nm, optionally less than 100 nm, optionally less than 80 nm, optionally less than 60 nm, optionally less than 50 nm, optionally less than 40 nm, optionally less than 30 nm, optionally less than 25 nm, optionally less than 20 nm, optionally less than 15 nm, optionally less than 10 nm.

A vessel is contemplated in any embodiment, in which the vessel has a lumen defined at least in part by a plastic wall, the plastic wall having an interior surface facing the lumen, an outer surface, and a coating set on the interior surface comprising: a barrier coating or layer of SiOx, wherein x is from 1.5 to 2.9 as determined by XPS, and optionally at least one, or both, of: a tie coating or layer of SiOxCy or SiNxCy, wherein x is from about 0.5 to about 2.4 and y is from about 0.6 to about 3, each as determined by XPS, and a pH protective coating or layer of SiOxCy or SiNxCy, wherein x is from about 0.5 to about 2.4 and y is from about 0.6 to about 3, each as determined by XPS; wherein the barrier coating or layer of SiOx has an average thickness less than 200 nm, optionally less than 150 nm, optionally less than 125 nm, optionally less than 100 nm, optionally less than 80 nm, optionally less than 60 nm, optionally less than 50 nm, optionally less than 40 nm, optionally less than 30 nm, optionally less than 25 nm, optionally less than 20 nm, optionally less than 15 nm, optionally less than 10 nm, and the oxygen transmission rate (d⁻¹) of the vessel wall is less than 0.020, optionally less than 0.015, optionally less than 0.010, optionally less than 0.005, optionally less than 0.0025, optionally less than 0.0015, optionally less than 0.0010, optionally less than 0.0008, optionally less than 0.0006, optionally less than 0.0005, optionally less than 0.0004, optionally less than 0.0003, optionally less than 0.0002, optionally less than 0.0001.

A vessel as previously described is contemplated in any embodiment, in which the fluid comprises a member selected from the group consisting of:

### Biologic Drugs

abatacept; abciximab; abobotulinumtoxinA; adalimumab; adalimumab-adaz; adalimumab-adbm; adalimumab-afzb; adalimumab-atto; adalimumab-bwwd; ado-trastuzumab emtansine; aflibercept; agalsidase beta; albiglutide; albumin chromated CR-51 serum; aldesleukin; alefacept; alemtuzumab; alglucosidase alfa; alirocumab; alteplase; anakinra; aprotinin; asfotas alfa; asparaginase; asparaginase Erwinia chrysanthemi; atezolizumab; avelumab; basiliximab; becaplermin; belatacept; belimumab; benralizumab; beractant; bevacizumab; bevacizumab-awwb; bevacizumab-bvzr; bezlotoxumab; blinatumomab; brentuximab vedotin; brodalumab; brolucizumab-dbll; burosumab-twza; calaspargase pegol-mknl; calfactant; canakinumab; caplacizumab-yhdp; capromab pendetide; cemiplimab-rwlc; cenegermin-bkbj; cerliponase alfa; certolizumab pegol; cetuximab; choriogonadotropin alfa; chorionic gonadotropin; chymopapain; collagenase; collagenase clostridium histolyticum; corticorelin ovine triflutate; crizanlizumab-tmca; daclizumab; daratumumab; daratumumab and hyaluronidase-fihj; darbepoetin alpha; denileukin diftitox; denosumab; desirudin; dinutuximab; dornase alfa; drotrecogin alfa; dulaglutide; dupilumab; durvalumab; ecallantide; eculizumab; efalizumab; elapegademase-IvIr; elosulfase alfa; elotuzumab; emapalumab-lzsg; emicizumab-kxwh; enfortumab vedotin-ejfv; epoetin alfa; epoetin alfa-epbx; erenumab-aooe; etanercept; etanercept-szzs; etanercept-ykro; evolocumab; fam-trastuzumab deruxetecan-nxki; fibrinolysin and desoxyribonuclease combined [bovine], with chloramphenicol; filgrastim; filgrastim-aafi; filgrastim-sndz; follitropin alfa; follitropin beta; fremanezumab-vfrm; galcanezumab-gnlm; galsulfase; gemtuzumab ozogamicin; glucarpidase; golimumab; guselkumab; hyaluronidase; hyaluronidase human; ibalizumab-uiyk; ibritumomab tiuxetan; idarucizumab; idursulfase; imiglucerase; incobotulinumtoxinA; inebilizumab-cdon; infliximab; infliximab-abda; infliximab-axxq; infliximab-dyyb; infliximab-qbtx; inotuzumab ozogamicin; insulin aspart; insulin aspart protamine and insulin aspart; insulin degludec; insulin degludec and insulin aspart; insulin degludec and liraglutide; insulin detemir; insulin glargine; insulin glargine and lixisenatide; insulin glulisine; insulin human; insulin isophane human; insulin isophane human and insulin human; insulin lispro; insulin lispro protamine and insulin lispro; insulin lispro-aabc; interferon alfa-2a; interferon alfa-2b; interferon alfacon-1; interferon alfa-n3 (human leukocyte derived); interferon beta-1a; interferon beta-1b; interferon gamma-1b; ipilimumab; isatuximab-irfc; ixekizumab; lanadelumab-flyo; laronidase; lixisenatide; luspatercept-aamt; mecasermin; mecasermin rinfabate; menotropins; mepolizumab; methoxy polyethylene glycol-epoetin beta; metreleptin; mogamulizumab-kpkc; moxetumomab pasudotox-tdfk; muromanab-CD3; natalizumab; necitumumab; nivolumab; nofetumomab; obiltoxaximab; obinutuzumab; ocrelizumab; ocriplasmin; ofatumumab; olaratumab; omalizumab; onabotulinumtoxinA; oprelvekin; palifermin; palivizumab; pancrelipase; panitumumab; parathyroid hormone; pegademase bovine; pegaspargase; pegfilgrastim; pegfilgrastim-apgf; pegfilgrastim-bmez; pegfilgrastim-cbqv; pegfilgrastim-jmdb; peginterferon alfa-2a; peginterferon alfa-2a and ribavirin; peginterferon alfa-2b; peginterferon alfa-2b and ribavirin; peginterferon beta-1a; pegloticase; pegvaliase-pqpz; pegvisomant; pembrolizumab; pertuzumab; polatuzumab vedotin-piiq; poractant alfa; prabotulinumtoxinA-xvfs; radiolabeled albumin technetium Tc-99m albumin colloid kit; ramucirumab; ranibizumab; rasburicase; ravulizumab-cwvz; raxibacumab; reslizumab; reteplase; rilonacept; rimabotulinumtoxinB; risankizumab-rzaa; rituximab; rituximab and hyaluronidase human; rituximab-abbs; rituximab-pvvr; romiplostim; romosozumab-aqqg; sacituzumab govitecan-hziy; sacrosidase; sargramostim; sarilumab; sebelipase alfa; secukinumab; siltuximab; somatropin; tagraxofusp-erzs; taliglucerase alfa; tbo-filgrastim; technetium 99m tc fanolesomab; tenecteplase; teprotumumab-trbw; tesamorelin acetate; thyrotropin alfa; tildrakizumab-asmn; tocilizumab; tositumomab and iodine 1-131 tositumomab; trastuzumab; trastuzumab and hyaluronidase-oysk; trastuzumab-anns; trastuzumab-dkst; trastuzumab-dttb; trastuzumab-pkrb; trastuzumab-qyyp; urofollitropin; urokinase; ustekinumab; vedolizumab; velaglucerase alfa; vestronidase alfa-vjbk; Ziv-Aflibercept; Amjevita (adalimumab-atto); Dupixent (dupilumab); Fulphila (pegfilgrastim-jmdb); Ilaris (canakinumab); Ixifi (infliximab-qbtx); Lyumjev (insulin lispro-aabc); Nyvepria (pegfilgrastim-apgf); Ogivri (trastuzumab-dkst); Semglee (insulin glargine); Uplizna (inebilizumab-cdon); A.P.L. (chorionic gonadotropin); Abrilada (adalimumab-afzb); Accretropin (somatropin); Actemra (tocilizumab); Acthrel (corticorelin ovine triflutate); Actimmune (interferon gamma-1b); Activase (alteplase); Adagen (pegademase bovine); Adakveo (crizanlizumab-tmca); Adcetris (brentuximab vedotin); Adlyxin (lixisenatide); Admelog (insulin lispro); Afrezza (insulin human); Aimovig (erenumab-aooe); Ajovy (fremanezumab-vfrm); Aldurazyme (laronidase); Alferon N Injection (interferon alfa-n3 (human leukocyte derived)); Amevive (alefacept); Amphadase (hyaluronidase); Anthim (obiltoxaximab); Apidra (insulin glulisine); Aranesp (darbepoetin alpha); Arcalyst (rilonacept); Arzerra (ofatumumab); Asparlas (calaspargase pegol-mknl); Avastin (bevacizumab); Avonex (interferon beta-1a); Avsola (infliximab-axxq); Basaglar (insulin glargine); Bavencio (avelumab); Benlysta (belimumab); Beovu (brolucizumab-dbll); Besponsa (inotuzumab ozogamicin); Betaseron (interferon beta-1b); Bexxar (tositumomab and iodine 1-131 tositumomab); Blincyto (blinatumomab); Botox (onabotulinumtoxinA); Botox Cosmetic (onabotulinumtoxinA); Bravelle (urofollitropin); Brineura (cerliponase alfa); Cablivi (caplacizumab-yhdp); Campath (alemtuzumab); Cathflo Activase (alteplase); Cerezyme (imiglucerase); Chorionic Gonadotropin (chorionic gonadotropin); Chromalbin (albumin chromated CR-51 serum); Chymodiactin (chymopapain); Cimzia (certolizumab pegol); Cinqair (reslizumab); Cosentyx (secukinumab); Cotazym (pancrelipase); Creon (pancrelipase); Crysvita (burosumab-twza); Curosurf (poractant alfa); Cyltezo (adalimumab-adbm); Cyramza (ramucirumab); Darzalex (daratumumab); Darzalex Faspro (daratumumab and hyaluronidase-fihj); Draximage MAA (kit for the preparation of technetium Tc-99m albumin aggregated); Dysport (abobotulinumtoxinA); Egrifta (tesamorelin acetate); Egrifta SV (tesamorelin acetate); Elaprase (idursulfase); Elase-chloromycetin (fibrinolysin and desoxyribonuclease combined [bovine], with chloramphenicol); Elelyso (taliglucerase alfa); Elitek (rasburicase); Elspar (asparaginase); Elzonris (tagraxofusp-erzs); Emgality (galcanezumab-gnlm); Empliciti (elotuzumab); Enbrel (etanercept); Enbrel Mini (etanercept); Enhertu (fam-trastuzumab deruxetecan-nxki); Entyvio (vedolizumab); Epogen/Procrit (epoetin alfa); Erbitux (cetuximab); Erelzi (etanercept-szzs); Erelzi Sensoready (etanercept-szzs); Erwinaze (asparaginase Erwinia chrysanthemi); Eticovo (etanercept-ykro); Evenity (romosozumab-aqqg); Extavia (interferon beta-1b); Eylea (aflibercept); Fabrazyme (agalsidase beta); Fasenra (benralizumab); Fiasp (insulin aspart); Follistim (follitropin beta); Follistim AQ (follitropin beta); Follistim AQ Cartridge (follitropin beta); Gamifant (emapalumab-Izsg); Gazyva (obinutuzumab); Genotropin (somatropin); Gonal-f (follitropin alfa); Gonal-f RFF (follitropin alfa); Gonal-f RFF RediJect (follitropin alfa); Granix (tbo-filgrastim); Hadlima (adalimumab-bwwd); Hemlibra (emicizumab-kxwh); Herceptin (trastuzumab); Herceptin Hylecta (trastuzumab and hyaluronidase-oysk); Herzuma (trastuzumab-pkrb); Humalog (insulin lispro); Humalog Mix 50/50 (insulin lispro protamine and insulin lispro); Humalog Mix 75/25 (insulin lispro protamine and insulin lispro); Humatrope (somatropin); Humegon (menotropins); Humira (adalimumab); Humulin 70/30 (insulin isophane human and insulin human); Humulin N (insulin isophane human); Humulin R U-100 (insulin human); Humulin R U-500 (insulin human); Hydase (hyaluronidase); Hylenex recombinant (hyaluronidase human); Hyrimoz (adalimumab-adaz); Ilumya (tildrakizumab-asmn); Imfinzi (durvalumab); Increlex (mecasermin); Infasurf (calfactant); Infergen (interferon alfacon-1); Inflectra (infliximab-dyyb); Intron A (interferon alfa-2b); Iplex (mecasermin rinfabate); Iprivask (desirudin); Jeanatope (kit for iodinated 1-125 albumin); Jetrea (ocriplasmin); Jeuveau (prabotulinumtoxinA-xvfs); Kadcyla (ado-trastuzumab emtansine); Kalbitor (ecallantide); Kanjinti (trastuzumab-anns); Kanuma (sebelipase alfa); Kepivance (palifermin); Kevzara (sarilumab); Keytruda (pembrolizumab); Kineret (anakinra); Kinlytic (urokinase); Krystexxa (pegloticase); Lantus (insulin glargine); Lartruvo (olaratumab); Lemtrada (alemtuzumab); Leukine (sargramostim); Levemir (insulin detemir); Libtayo (cemiplimab-rwlc); Lucentis (ranibizumab); Lumizyme (alglucosidase alfa); Lumoxiti (moxetumomab pasudotox-tdfk); Macrotec (kit for the preparation of technetium Tc-99m albumin aggregated); Megatope (kit for iodinated 1-131 albumin); Menopur (menotropins); Mepsevii (vestronidase alfa-vjbk); Microlite (radiolabeled albumin technetium Tc-99m albumin colloid kit); Mircera (methoxy polyethylene glycol-epoetin beta); Mvasi (bevacizumab-awwb); Myalept (metreleptin); Mylotarg (gemtuzumab ozogamicin); Myobloc (rimabotulinumtoxinB); Myozyme (alglucosidase alfa); Myxredlin (insulin human); N/A (raxibacumab); Naglazyme (galsulfase); Natpara (parathyroid hormone); Neulasta (pegfilgrastim); Neulasta Onpro (pegfilgrastim); Neumega (oprelvekin); Neupogen (filgrastim); NeutroSpec (technetium 99m tc fanolesomab); Nivestym (filgrastim-aafi); Norditropin (somatropin); Novarel (chorionic gonadotropin); Novolin 70/30 (insulin isophane human and insulin human); Novolin N (insulin isophane human); Novolin R (insulin human); Novolog (insulin aspart); Novolog Mix 50/50 (insulin aspart protamine and insulin aspart); Novolog Mix 70/30 (insulin aspart protamine and insulin aspart); Nplate (romiplostim); Nucala (mepolizumab); Nulojix (belatacept); Nutropin (somatropin); Nutropin AQ (somatropin); Ocrevus (ocrelizumab); Omnitrope (somatropin); Oncaspar (pegaspargase); Ontak (denileukin diftitox); Ontruzant (trastuzumab-dttb); Opdivo (nivolumab); Orencia (abatacept); Orthoclone OKT3 (muromanab-CD3); Ovidrel (choriogonadotropin alfa); Oxervate (cenegermin-bkbj); Padcev (enfortumab vedotin-ejfv); Palynziq (pegvaliase-pqpz); Pancreaze (pancrelipase); Pegasys (peginterferon alfa-2a); Pegasys Copegus Combination Pack (peginterferon alfa-2a and ribavirin); Pegintron (peginterferon alfa-2b); Pegintron/Rebetol Combo Pack (peginterferon alfa-2b and ribavirin); Pergonal (menotropins); Perjeta (pertuzumab); Pertzye (pancrelipase); Plegridy (peginterferon beta-1a); Polivy (polatuzumab vedotin-piiq); Portrazza (necitumumab); Poteligeo (mogamulizumab-kpkc); Praluent (alirocumab); Praxbind (idarucizumab); Pregnyl (chorionic gonadotropin); Procrit (epoetin alfa); Proleukin (aldesleukin); Prolia (denosumab); ProstaScint (capromab pendetide); Pulmolite (kit for the preparation of technetium Tc-99m albumin aggregated); Pulmotech MAA (kit for the preparation of technetium Tc-99m albumin aggregated); Pulmozyme (dornase alfa); Raptiva (efalizumab); Rebif (interferon beta-1a); Reblozyl (luspatercept-aamt); Regranex (becaplermin); Remicade (infliximab); Renflexis (infliximab-abda); Reopro (abciximab); Repatha (evolocumab); Repronex (menotropins); Retacrit (epoetin alfa-epbx); Retavase (reteplase); Revcovi (elapegademase-Ivlr); Rituxan (rituximab); Rituxan Hycela (rituximab and hyaluronidase human); Roferon-A (interferon alfa-2a); Ruxience (rituximab-pvvr); Ryzodeg 70/30 (insulin degludec and insulin aspart); Saizen (somatropin); Santyl (collagenase); Sarclisa (isatuximab-irfc); Serostim (somatropin); Siliq (brodalumab); Simponi (golimumab); Simponi Aria (golimumab); Simulect (basiliximab); Skyrizi (risankizumab-rzaa); Soliqua 100/33 (insulin glargine and lixisenatide); Soliris (eculizumab); Somavert (pegvisomant); Stelara (ustekinumab); Strensiq (asfotas alfa); Sucraid (sacrosidase); Survanta (beractant); Sylvant (siltuximab); Synagis (palivizumab); Takhzyro (lanadelumab-flyo); Taltz (ixekizumab); Tanzeum (albiglutide); Tecentriq (atezolizumab); Tepezza (teprotumumab-trbw); Thyrogen (thyrotropin alfa); TNKase (tenecteplase); Toujeo (insulin glargine); Trasylol (aprotinin); Trazimera (trastuzumab-qyyp); Tremfya (guselkumab); Tresiba (insulin degludec); Trodelvy (sacituzumab govitecan-hziy); Trogarzo (ibalizumab-uiyk); Trulicity (dulaglutide); Truxima (rituximab-abbs); Tysabri (natalizumab); Udenyca (pegfilgrastim-cbqv); Ultomiris (ravulizumab-cwvz); Unituxin (dinutuximab); Vectibix (panitumumab); Verluma (nofetumomab); Vimizim (elosulfase alfa); Viokace (pancrelipase); Vitrase (hyaluronidase); Voraxaze (glucarpidase); VPRIV (velaglucerase alfa); Xeomin (incobotulinumtoxinA); Xgeva (denosumab); Xiaflex (collagenase clostridium histolyticum); Xigris (drotrecogin alfa); Xolair (omalizumab); Xultophy 100/3.6 (insulin degludec and liraglutide); Yervoy (ipilimumab); Zaltrap (Ziv-Aflibercept); Zarxio (filgrastim-sndz); Zenapax (daclizumab); Zenpep (pancrelipase); Zevalin (ibritumomab tiuxetan); Ziextenzo (pegfilgrastim-bmez); Zinbryta (daclizumab); Zinplava (bezlotoxumab); Zirabev (bevacizumab-bvzr); Zomacton (somatropin); Zorbtive/Serostim (somatropin); mRNA, including for instance any one or more of mRNA-1647, mRNA-1653, mRNA-1893, mRNA-1345, mRNA-1851, mRNA-1944, mRNA-4157, mRNA-5671, mRNA-2416, mRNA-2752, MED 11191, AZD8601, mRNA-3927, mRNA-1010, mRNA-1020, mRNA-1030, mRNA-1273, mRNA-1273.351/-211, mRNA-1283, mRNA-1189, mRNA-1644, mRNA-1574, mRNA-0184, mRNA-6981, mRNA-6231, mRNA-1215, mRNA-3705, mRNA-3283, mRNA-3745, BNT111, BNT112, BNT113, BNT114, BNT115, BNT116, R07198457 (BNT1223), SAR441000 (BNT131), BNT141, BNT142, BNT151, BNT152, BNT153, BNT211, BNT212, BNT221 (NEO-PTC-01), Gen1046 (BNT311), Gen1042 (BNT312), BNT321 (MVT-5873), BNT411, BNT161, BNT162, or BNT171; short interfering RNA (siRNA); micro-RNA (miRNA); CRISPR-based therapies, such as therapies that include a Cas9 nuclease (enzyme) and one or more single guide RNA (sgRNA); plasmids, i.e. DNA-based molecules that contain protein-encoding transgenes; non-plasmid DNA. one or more proteins or peptides; an Antisense Oligonucleotide (ASO), including for example a gapmer-based ASO or a mixmer-based ASO; small nuclear RNA (U-RNA); small nucleolar RNA (snoRNA); Piwi-interacting RNA (piRNA); repeat associated small interfering RNA (rasiRNA); small rDNA-derived RNA (srRNA); transfer RNA derived small RNA (tsRNA); ribosomal RNA derived small RNA (rsRNA); large non-coding RNA derived small RNA (IncsRNA); messenger RNA derived small RNA (msRNA); short-harpin RNA (shRNA); dicer-dependent siRNA (di-siRNA); double-stranded RNAs (dsRNA); single stranded RNAi (ssRNAi); DNA-directed RNA interference (ddRNAi); RNA activating oligonucleotide (RNAa); an exon skipping oligonucleotide;

### Inhalation Anesthetics

Aliflurane; Chloroform; Cyclopropane; Desflurane (Suprane); Diethyl Ether; Enflurane (Ethrane); Ethyl Chloride; Ethylene; Halothane (Fluothane); Isoflurane (Forane, Isoflo); Isopropenyl vinyl ether; Methoxyflurane; methoxyflurane; Methoxypropane; Nitrous Oxide; Roflurane; Sevoflurane (Sevorane, Ultane, Sevoflo); Teflurane; Trichloroethylene; Vinyl Ether; Xenon

### Injectable Drugs

Ablavar (Gadofosveset Trisodium Injection); Abarelix Depot; Abobotulinumtoxin A Injection (Dysport); ABT-263; ABT-869; ABX-EFG; Accretropin (Somatropin Injection); Acetadote (Acetylcysteine Injection); Acetazolamide Injection (Acetazolamide Injection); Acetylcysteine Injection (Acetadote); Actemra (Tocilizumab Injection); Acthrel (Corticorelin Ovine Triflutate for Injection); Actummune; Activase; Acyclovir for Injection (Zovirax Injection); Adacel; Adalimumab; Adenoscan (Adenosine Injection); Adenosine Injection (Adenoscan); Adrenaclick; AdreView (lobenguane I 123 Injection for Intravenous Use); Afluria; Ak-Fluor (Fluorescein Injection); Aldurazyme (Laronidase); Alglucerase Injection (Ceredase); Alkeran Injection (Melphalan Hcl Injection); Allopurinol Sodium for Injection (Aloprim); Aloprim (Allopurinol Sodium for Injection); Alprostadil; Alsuma (Sumatriptan Injection); ALTU-238; Amino Acid Injections; Aminosyn; Apidra; Apremilast; Alprostadil Dual Chamber System for Injection (Caverject Impulse); AMG 009; AMG 076; AMG 102; AMG 108; AMG 114; AMG 162; AMG 220; AMG 221; AMG 222; AMG 223; AMG 317; AMG 379; AMG 386; AMG 403; AMG 477; AMG 479; AMG 517; AMG 531; AMG 557; AMG 623; AMG 655; AMG 706; AMG 714; AMG 745; AMG 785; AMG 811; AMG 827; AMG 837; AMG 853; AMG 951; Amiodarone HCl Injection (Amiodarone HCl Injection); Amobarbital Sodium Injection (Amytal Sodium); Amytal Sodium (Amobarbital Sodium Injection); Anakinra; Anti-Abeta; Anti-Beta7; Anti-Beta20; Anti-CD4; Anti-CD20; Anti-CD40; Anti-IFNalpha; Anti-IL13; Anti-OX40L; Anti-oxLDS; Anti-NGF; Anti-NRP1; Arixtra; Amphadase (Hyaluronidase Inj); Ammonul (Sodium Phenylacetate and Sodium Benzoate Injection); Anaprox; Anzemet Injection (Dolasetron Mesylate Injection); Apidra (Insulin Glulisine [rDNA origin] Inj); Apomab; Aranesp (darbepoetin alfa); Argatroban (Argatroban Injection); Arginine Hydrochloride Injection (R-Gene 10); Aristocort; Aristospan; Arsenic Trioxide Injection (Trisenox); Articane HCl and Epinephrine Injection (Septocaine); Arzerra (Ofatumumab Injection); Asclera (Polidocanol Injection); Ataluren; Ataluren-DMD; Atenolol Inj (Tenormin I.V. Injection); Atracurium Besylate Injection (Atracurium Besylate Injection); Avastin; Azactam Injection (Aztreonam Injection); Azithromycin (Zithromax Injection); Aztreonam Injection (Azactam Injection); Baclofen Injection (Lioresal Intrathecal); Bacteriostatic Water (Bacteriostatic Water for Injection); Baclofen Injection (Lioresal Intrathecal); Bal in Oil Ampules (Dimercarprol Injection); BayHepB; BayTet; Benadryl; Bendamustine Hydrochloride Injection (Treanda); Benztropine Mesylate Injection (Cogentin); Betamethasone Injectable Suspension (Celestone Soluspan); Bexxar; Bicillin C-R 900/300 (Penicillin G Benzathine and Penicillin G Procaine Injection); Blenoxane (Bleomycin Sulfate Injection); Bleomycin Sulfate Injection (Blenoxane); Boniva Injection (Ibandronate Sodium Injection); Botox Cosmetic (OnabotulinumtoxinA for Injection); BR3-FC; Bravelle (Urofollitropin Injection); Bretylium (Bretylium Tosylate Injection); Brevital Sodium (Methohexital Sodium for Injection); Brethine; Briobacept; BTT-1023; Bupivacaine HCl; Byetta; Ca-DTPA (Pentetate Calcium Trisodium Inj); Cabazitaxel Injection (Jevtana); Caffeine Alkaloid (Caffeine and Sodium Benzoate Injection); Calcijex Injection (Calcitrol); Calcitrol (Calcijex Injection); Calcium Chloride (Calcium Chloride Injection 10%); Calcium Disodium Versenate (Edetate Calcium Disodium Injection); Campath (Altemtuzumab); Camptosar Injection (Irinotecan Hydrochloride); Canakinumab Injection (Ilaris); Capastat Sulfate (Capreomycin for Injection); Capreomycin for Injection (Capastat Sulfate); Cardiolite (Prep kit for Technetium Tc99 Sestamibi for Injection); Carticel; Cathflo; Cefazolin and Dextrose for Injection (Cefazolin Injection); Cefepime Hydrochloride; Cefotaxime; Ceftriaxone; Cerezyme; Carnitor Injection; Caverject; Celestone Soluspan; Celsior; Cerebyx (Fosphenytoin Sodium Injection); Ceredase (Alglucerase Injection); Ceretec (Technetium Tc99m Exametazime Injection); Certolizumab; CF-101; Chloramphenicol Sodium Succinate (Chloramphenicol Sodium Succinate Injection); Chloramphenicol Sodium Succinate Injection (Chloramphenicol Sodium Succinate); Cholestagel (Colesevelam HCL); Choriogonadotropin Alfa Injection (Ovidrel); Cimzia; Cisplatin (Cisplatin Injection); Clolar (Clofarabine Injection); Clomiphine Citrate; Clonidine Injection (Duraclon); Cogentin (Benztropine Mesylate Injection); Colistimethate Injection (Coly-Mycin M); Coly-Mycin M (Colistimethate Injection); Compath; Conivaptan Hcl Injection (Vaprisol); Conjugated Estrogens for Injection (Premarin Injection); Copaxone; Corticorelin Ovine Triflutate for Injection (Acthrel); Corvert (Ibutilide Fumarate Injection); Cubicin (Daptomycin Injection); CF-101; Cyanokit (Hydroxocobalamin for Injection); Cytarabine Liposome Injection (DepoCyt); Cyanocobalamin; Cytovene (ganciclovir); D.H.E. 45; Dacetuzumab; Dacogen (Decitabine Injection); Dalteparin; Dantrium IV (Dantrolene Sodium for Injection); Dantrolene Sodium for Injection (Dantrium IV); Daptomycin Injection (Cubicin); Darbepoietin Alfa; DDAVP Injection (Desmopressin Acetate Injection); Decavax; Decitabine Injection (Dacogen); Dehydrated Alcohol (Dehydrated Alcohol Injection); Denosumab Injection (Prolia); Delatestryl; Delestrogen; Delteparin Sodium; Depacon (Valproate Sodium Injection); Depo Medrol (Methylprednisolone Acetate Injectable Suspension); DepoCyt (Cytarabine Liposome Injection); DepoDur (Morphine Sulfate XR Liposome Injection); Desmopressin Acetate Injection (DDAVP Injection); Depo-Estradiol; Depo-Provera 104 mg/mi; Depo-Provera 150 mg/ml; Depo-Testosterone; Dexrazoxane for Injection, Intravenous Infusion Only (Totect); Dextrose/Electrolytes; Dextrose and Sodium Chloride Inj (Dextrose 5% in 0.9% Sodium Chloride); Dextrose; Diazepam Injection (Diazepam Injection); Digoxin Injection (Lanoxin Injection); Dilaudid-HP (Hydromorphone Hydrochloride Injection); Dimercarprol Injection (Bal in Oil Ampules); Diphenhydramine Injection (Benadryl Injection); Dipyridamole Injection (Dipyridamole Injection); DMOAD; Docetaxel for Injection (Taxotere); Dolasetron Mesylate Injection (Anzemet Injection); Doribax (Doripenem for Injection); Doripenem for Injection (Doribax); Doxercalciferol Injection (Hectorol Injection); Doxil (Doxorubicin Hcl Liposome Injection); Doxorubicin Hcl Liposome Injection (Doxil); Duraclon (Clonidine Injection); Duramorph (Morphine Injection); Dysport (Abobotulinumtoxin A Injection); Ecallantide Injection (Kalbitor); EC-Naprosyn (naproxen); Edetate Calcium Disodium Injection (Calcium Disodium Versenate); Edex (Alprostadil for Injection); Engerix; Edrophonium Injection (Enlon); Eliglustat Tartate; Eloxatin (Oxaliplatin Injection); Emend Injection (Fosaprepitant Dimeglumine Injection); Enalaprilat Injection (Enalaprilat Injection); Enlon (Edrophonium Injection); Enoxaparin Sodium Injection (Lovenox); Eovist (Gadoxetate Disodium Injection); Enbrel (etanercept); Enoxaparin; Epicel; Epinepherine; Epipen; Epipen Jr.; Epratuzumab; Erbitux; Ertapenem Injection (Invanz); Erythropoieten; Essential Amino Acid Injection (Nephramine); Estradiol Cypionate; Estradiol Valerate; Etanercept; Exenatide Injection (Byetta); Evlotra; Fabrazyme (Adalsidase beta); Famotidine Injection; FDG (Fludeoxyglucose F 18 Injection); Feraheme (Ferumoxytol Injection); Feridex I.V. (Ferumoxides Injectable Solution); Fertinex; Ferumoxides Injectable Solution (Feridex I.V.); Ferumoxytol Injection (Feraheme); Flagyl Injection (Metronidazole Injection); Fluarix; Fludara (Fludarabine Phosphate); Fludeoxyglucose F 18 Injection (FDG); Fluorescein Injection (Ak-Fluor); Follistim AQ Cartridge (Follitropin Beta Injection); Follitropin Alfa Injection (Gonal-f RFF); Follitropin Beta Injection (Follistim AQ Cartridge); Folotyn (Pralatrexate Solution for Intravenous Injection); Fondaparinux; Forteo (Teriparatide (rDNA origin) Injection); Fostamatinib; Fosaprepitant Dimeglumine Injection (Emend Injection); Foscarnet Sodium Injection (Foscavir); Foscavir (Foscarnet Sodium Injection); Fosphenytoin Sodium Injection (Cerebyx); Fospropofol Disodium Injection (Lusedra); Fragmin; Fuzeon (enfuvirtide); GA101; Gadobenate Dimeglumine Injection (Multihance); Gadofosveset Trisodium Injection (Ablavar); Gadoteridol Injection Solution (ProHance); Gadoversetamide Injection (OptiMARK); Gadoxetate Disodium Injection (Eovist); Ganirelix (Ganirelix Acetate Injection); Gardasil; GC1008; GDFD; Gemtuzumab Ozogamicin for Injection (Mylotarg); Genotropin; Gentamicin Injection; GENZ-112638; Golimumab Injection (Simponi Injection); Gonal-f RFF (Follitropin Alfa Injection); Granisetron Hydrochloride (Kytril Injection); Gentamicin Sulfate; Glatiramer Acetate; Glucagen; Glucagon; HAE1; Haldol (Haloperidol Injection); Havrix; Hectorol Injection (Doxercalciferol Injection); Hedgehog Pathway Inhibitor; Heparin; Herceptin; hG-CSF; Humalog; Human Growth Hormone; Humatrope; HuMax; Humegon; Humira; Humulin; Ibandronate Sodium Injection (Boniva Injection); Ibuprofen Lysine Injection (NeoProfen); Ibutilide Fumarate Injection (Corvert); Idamycin PFS (Idarubicin Hydrochloride Injection); Idarubicin Hydrochloride Injection (Idamycin PFS); Ilaris (Canakinumab Injection); Imipenem and Cilastatin for Injection (Primaxin I.V.); Imitrex; Incobotulinumtoxin A for Injection (Xeomin); Increlex (Mecasermin [rDNA origin] Injection); Indocin IV (Indomethacin Inj); Indomethacin Inj (Indocin IV); Infanrix; Innohep; Insulin; Insulin Aspart [rDNA origin] Inj (NovoLog); Insulin Glargine [rDNA origin] Injection (Lantus); Insulin Glulisine [rDNA origin] Inj (Apidra); Interferon alfa-2b, Recombinant for Injection (Intron A); Intron A (Interferon alfa-2b, Recombinant for Injection); Invanz (Ertapenem Injection); Invega Sustenna (Paliperidone Palmitate Extended-Release Injectable Suspension); Invirase (saquinavir mesylate); lobenguane I 123 Injection for Intravenous Use (AdreView); lopromide Injection (Ultravist); loversol Injection (Optiray Injection); Iplex (Mecasermin Rinfabate [rDNA origin] Injection); Iprivask; Irinotecan Hydrochloride (Camptosar Injection); Iron Sucrose Injection (Venofer); Istodax (Romidepsin for Injection); Itraconazole Injection (Sporanox Injection); Jevtana (Cabazitaxel Injection); Jonexa; Kalbitor (Ecallantide Injection); KCL in D5NS (Potassium Chloride in 5% Dextrose and Sodium Chloride Injection); KCL in D5W; KCL in NS; Kenalog 10 Injection (Triamcinolone Acetonide Injectable Suspension); Kepivance (Palifermin); Keppra Injection (Levetiracetam); Keratinocyte; KFG; Kinase Inhibitor; Kineret (Anakinra); Kinlytic (Urokinase Injection); Kinrix; Klonopin (clonazepam); Kytril Injection (Granisetron Hydrochloride); lacosamide Tablet and Injection (Vimpat); Lactated Ringer's; Lanoxin Injection (Digoxin Injection); Lansoprazole for Injection (Prevacid I.V.); Lantus; Leucovorin Calcium (Leucovorin Calcium Injection); Lente (L); Leptin; Levemir; Leukine Sargramostim; Leuprolide Acetate; Levothyroxine; Levetiracetam (Keppra Injection); Lovenox; Levocarnitine Injection (Carnitor Injection); Lexiscan (Regadenoson Injection); Lioresal Intrathecal (Baclofen Injection); Liraglutide [rDNA] Injection (Victoza); Lovenox (Enoxaparin Sodium Injection); Lucentis (Ranibizumab Injection); Lumizyme; Lupron (Leuprolide Acetate Injection); Lusedra (Fospropofol Disodium Injection); Maci; Magnesium Sulfate (Magnesium Sulfate Injection); Mannitol Injection (Mannitol IV); Marcaine (Bupivacaine Hydrochloride and Epinephrine Injection); Maxipime (Cefepime Hydrochloride for Injection); MDP Multidose Kit of Technetium Injection (Technetium Tc99m Medronate Injection); Mecasermin [rDNA origin] Injection (Increlex); Mecasermin Rinfabate [rDNA origin] Injection (Iplex); Melphalan Hcl Injection (Alkeran Injection); Methotrexate; Menactra; Menopur (Menotropins Injection); Menotropins for Injection (Repronex); Methohexital Sodium for Injection (Brevital Sodium); Methyldopate Hydrochloride Injection, Solution (Methyldopate Hcl); Methylene Blue (Methylene Blue Injection); Methylprednisolone Acetate Injectable Suspension (Depo Medrol); MetMab; Metoclopramide Injection (Reglan Injection); Metrodin (Urofollitropin for Injection); Metronidazole Injection (Flagyl Injection); Miacalcin; Midazolam (Midazolam Injection); Mimpara (Cinacalet); Minocin Injection (Minocycline Inj); Minocycline Inj (Minocin Injection); Mipomersen; Mitoxantrone for Injection Concentrate (Novantrone); Morphine Injection (Duramorph); Morphine Sulfate XR Liposome Injection (DepoDur); Morrhuate Sodium (Morrhuate Sodium Injection); Motesanib; Mozobil (Plerixafor Injection); Multihance (Gadobenate Dimeglumine Injection); Multiple Electrolytes and Dextrose Injection; Multiple Electrolytes Injection; Mylotarg (Gemtuzumab Ozogamicin for Injection); Myozyme (Alglucosidase alfa); Nafcillin Injection (Nafcillin Sodium); Nafcillin Sodium (Nafcillin Injection); Naltrexone XR Inj (Vivitrol); Naprosyn (naproxen); NeoProfen (Ibuprofen Lysine Injection); Nandrol Decanoate; Neostigmine Methylsulfate (Neostigmine Methylsulfate Injection); NEO-GAA; NeoTect (Technetium Tc 99m Depreotide Injection); Nephramine (Essential Amino Acid Injection); Neulasta (pegfilgrastim); Neupogen (Filgrastim); Novolin; Novolog; NeoRecormon; Neutrexin (Trimetrexate Glucuronate Inj); NPH (N); Nexterone (Amiodarone HCl Injection); Norditropin (Somatropin Injection); Normal Saline (Sodium Chloride Injection); Novantrone (Mitoxantrone for Injection Concentrate); Novolin 70/30 Innolet (70% NPH, Human Insulin Isophane Suspension and 30% Regular, Human Insulin Injection); NovoLog (Insulin Aspart [rDNA origin] Inj); Nplate (romiplostim); Nutropin (Somatropin (rDNA origin) for Inj); Nutropin AQ; Nutropin Depot (Somatropin (rDNA origin) for Inj); Octreotide Acetate Injection (Sandostatin LAR); Ocrelizumab; Ofatumumab Injection (Arzerra); Olanzapine Extended Release Injectable Suspension (Zyprexa Relprevv); Omnitarg; Omnitrope (Somatropin [rDNA origin] Injection); Ondansetron Hydrochloride Injection (Zofran Injection); OptiMARK (Gadoversetamide Injection); Optiray Injection (loversol Injection); Orencia; Osmitrol Injection in Aviva (Mannitol Injection in Aviva Plastic Vessel); Osmitrol Injection in Viaflex (Mannitol Injection in Viaflex Plastic Vessel); Osteoprotegrin; Ovidrel (Choriogonadotropin Alfa Injection); Oxacillin (Oxacillin for Injection); Oxaliplatin Injection (Eloxatin); Oxytocin Injection (Pitocin); Paliperidone Palmitate Extended-Release Injectable Suspension (Invega Sustenna); Pamidronate Disodium Injection (Pamidronate Disodium Injection); Panitumumab Injection for Intravenous Use (Vectibix); Papaverine Hydrochloride Injection (Papaverine Injection); Papaverine Injection (Papaverine Hydrochloride Injection); Parathyroid Hormone; Paricalcitol Injection Fliptop Vial (Zemplar Injection); PARP Inhibitor; Pediarix; PEGintron; Peginterferon; Pegfilgrastim; Penicillin G Benzathine and Penicillin G Procaine; Pentetate Calcium Trisodium Inj (Ca-DTPA); Pentetate Zinc Trisodium Injection (Zn-DTPA); Pepcid Injection (Famotidine Injection); Pergonal; Pertuzumab; Phentolamine Mesylate (Phentolamine Mesylate for Injection); Physostigmine Salicylate (Physostigmine Salicylate (injection)); Physostigmine Salicylate (injection) (Physostigmine Salicylate); Piperacillin and Tazobactam Injection (Zosyn); Pitocin (Oxytocin Injection); Plasma-Lyte 148 (Multiple Electrolytes Inj); Plasma-Lyte 56 and Dextrose (Multiple Electrolytes and Dextrose Injection in Viaflex Plastic Vessel); PlasmaLyte; Plerixafor Injection (Mozobil); Polidocanol Injection (Asclera); Potassium Chloride; Pralatrexate Solution for Intravenous Injection (Folotyn); Pramlintide Acetate Injection (Symlin); Premarin Injection (Conjugated Estrogens for Injection); Prep kit for Technetium Tc99 Sestamibi for Injection (Cardiolite); Prevacid I.V. (Lansoprazole for Injection); Primaxin I.V. (Imipenem and Cilastatin for Injection); Prochymal; Procrit; Progesterone; ProHance (Gadoteridol Injection Solution); Prolia (Denosumab Injection); Promethazine HCl Injection (Promethazine Hydrochloride Injection); Propranolol Hydrochloride Injection (Propranolol Hydrochloride Injection); Quinidine Gluconate Injection (Quinidine Injection); Quinidine Injection (Quinidine Gluconate Injection); R-Gene 10 (Arginine Hydrochloride Injection); Ranibizumab Injection (Lucentis); Ranitidine Hydrochloride Injection (Zantac Injection); Raptiva; Reclast (Zoledronic Acid Injection); Recombivarix HB; Regadenoson Injection (Lexiscan); Reglan Injection (Metoclopramide Injection); Remicade; Renagel; Renvela (Sevelamer Carbonate); Repronex (Menotropins for Injection); Retrovir IV (Zidovudine Injection); rhApo2L/TRAIL; Ringer's and 5% Dextrose Injection (Ringers in Dextrose); Ringer's Injection (Ringers Injection); Rituxan; Rituximab; Rocephin (ceftriaxone); Rocuronium Bromide Injection (Zemuron); Roferon-A (interferon alfa-2a); Romazicon (flumazenil); Romidepsin for Injection (Istodax); Saizen (Somatropin Injection); Sandostatin LAR (Octreotide Acetate Injection); Sclerostin Ab; Sensipar (cinacalcet); Sensorcaine (Bupivacaine HCl Injections); Septocaine (Articane HCl and Epinephrine Injection); Serostim LQ (Somatropin (rDNA origin) Injection); Simponi Injection (Golimumab Injection); Sodium Acetate (Sodium Acetate Injection); Sodium Bicarbonate (Sodium Bicarbonate 5% Injection); Sodium Lactate (Sodium Lactate Injection in AVIVA); Sodium Phenylacetate and Sodium Benzoate Injection (Ammonul); Somatropin (rDNA origin) for Inj (Nutropin); Sporanox Injection (Itraconazole Injection); Stelara Injection (Ustekinumab); Stemgen; Sufenta (Sufentanil Citrate Injection); Sufentanil Citrate Injection (Sufenta); Sumavel; Sumatriptan Injection (Alsuma); Symlin; Symlin Pen; Systemic Hedgehog Antagonist; Synvisc-One (Hylan G-F 20 Single Intra-articular Injection); Tarceva; Taxotere (Docetaxel for Injection); Technetium Tc 99m; Telavancin for Injection (Vibativ); Temsirolimus Injection (Torisel); Tenormin I.V. Injection (Atenolol Inj); Teriparatide (rDNA origin) Injection (Forteo); Testosterone Cypionate; Testosterone Enanthate; Testosterone Propionate; Tev-Tropin (Somatropin, rDNA Origin, for Injection); tgAAC94; Thallous Chloride; Theophylline; Thiotepa (Thiotepa Injection); Thymoglobulin (Anti-Thymocyte Globulin (Rabbit); Thyrogen (Thyrotropin Alfa for Injection); Ticarcillin Disodium and Clavulanate Potassium Galaxy (Timentin Injection); Tigan Injection (Trimethobenzamide Hydrochloride Injectable); Timentin Injection (Ticarcillin Disodium and Clavulanate Potassium Galaxy); TNKase; Tobramycin Injection (Tobramycin Injection); Tocilizumab Injection (Actemra); Torisel (Temsirolimus Injection); Totect (Dexrazoxane for Injection, Intravenous Infusion Only); Trastuzumab-DM1; Travasol (Amino Acids (Injection)); Treanda (Bendamustine Hydrochloride Injection); Trelstar (Triptorelin Pamoate for Injectable Suspension); Triamcinolone Acetonide; Triamcinolone Diacetate; Triamcinolone Hexacetonide Injectable Suspension (Aristospan Injection 20 mg); Triesence (Triamcinolone Acetonide Injectable Suspension); Trimethobenzamide Hydrochloride Injectable (Tigan Injection); Trimetrexate Glucuronate Inj (Neutrexin); Triptorelin Pamoate for Injectable Suspension (Trelstar); Twinject; Trivaris (Triamcinolone Acetonide Injectable Suspension); Trisenox (Arsenic Trioxide Injection); Twinrix; Typhoid Vi; Ultravist (lopromide Injection); Urofollitropin for Injection (Metrodin); Urokinase Injection (Kinlytic); Ustekinumab (Stelara Injection); Ultralente (U); Valium (diazepam); Valproate Sodium Injection (Depacon); Valtropin (Somatropin Injection); Vancomycin Hydrochloride (Vancomycin Hydrochloride Injection); Vancomycin Hydrochloride Injection (Vancomycin Hydrochloride); Vaprisol (Conivaptan Hcl Injection); VAQTA; Vasovist (Gadofosveset Trisodium Injection for Intravenous Use); Vectibix (Panitumumab Injection for Intravenous Use); Venofer (Iron Sucrose Injection); Verteporfin Inj (Visudyne); Vibativ (Telavancin for Injection); Victoza (Liraglutide [rDNA] Injection); Vimpat (lacosamide Tablet and Injection); Vinblastine Sulfate (Vinblastine Sulfate Injection); Vincasar PFS (Vincristine Sulfate Injection); Victoza; Vincristine Sulfate (Vincristine Sulfate Injection); Visudyne (Verteporfin Inj); Vitamin B-12; Vivitrol (Naltrexone XR Inj); Voluven (Hydroxyethyl Starch in Sodium Chloride Injection); Xeloda; Xenical (orlistat); Xeomin (Incobotulinumtoxin A for Injection); Xolair; Zantac Injection (Ranitidine Hydrochloride Injection); Zemplar Injection (Paricalcitol Injection Fliptop Vial); Zemuron (Rocuronium Bromide Injection); Zenapax (daclizumab); Zevalin; Zidovudine Injection (Retrovir IV); Zithromax Injection (Azithromycin); Zn-DTPA (Pentetate Zinc Trisodium Injection); Zofran Injection (Ondansetron Hydrochloride Injection); Zingo; Zoledronic Acid for Inj (Zometa); Zoledronic Acid Injection (Reclast); Zometa (Zoledronic Acid for Inj); Zosyn (Piperacillin and Tazobactam Injection); Zyprexa Relprevv (Olanzapine Extended Release Injectable Suspension)

### Liquid Drugs (Non-Injectable)

Abilify; AccuNeb (Albuterol Sulfate Inhalation Solution); Actidose Aqua (Activated Charcoal Suspension); Activated Charcoal Suspension (Actidose Aqua); Advair; Agenerase Oral Solution (Amprenavir Oral Solution); Akten (Lidocaine Hydrochloride Ophthalmic Gel); Alamast (Pemirolast Potassium Ophthalmic Solution); Albumin (Human) 5% Solution (Buminate 5%); Albuterol Sulfate Inhalation Solution; Alinia; Alocril; Alphagan; Alrex; Alvesco; Amprenavir Oral Solution; Analpram-HC; Arformoterol Tartrate Inhalation Solution (Brovana); Aristospan Injection 20 mg (Triamcinolone Hexacetonide Injectable Suspension); Asacol; Asmanex; Astepro; Astepro (Azelastine Hydrochloride Nasal Spray); Atrovent Nasal Spray (Ipratropium Bromide Nasal Spray); Atrovent Nasal Spray 0.06; Augmentin ES-600; Azasite (Azithromycin Ophthalmic Solution); Azelaic Acid (Finacea Gel); Azelastine Hydrochloride Nasal Spray (Astepro); Azelex (Azelaic Acid Cream); Azopt (Brinzolamide Ophthalmic Suspension); Bacteriostatic Saline; Balanced Salt; Bepotastine; Bactroban Nasal; Bactroban; Beclovent; Benzac W; Betimol; Betoptic S; Bepreve; Bimatoprost Ophthalmic Solution; Bleph 10 (Sulfacetamide Sodium Ophthalmic Solution 10%); Brinzolamide Ophthalmic Suspension (Azopt); Bromfenac Ophthalmic Solution (Xibrom); Bromhist; Brovana (Arformoterol Tartrate Inhalation Solution); Budesonide Inhalation Suspension (Pulmicort Respules); Cambia (Diclofenac Potassium for Oral Solution); Capex; Carac; Carboxine-PSE; Carnitor; Cayston (Aztreonam for Inhalation Solution); Cellcept; Centany; Cerumenex; Ciloxan Ophthalmic Solution (Ciprofloxacin HCL Ophthalmic Solution); Ciprodex; Ciprofloxacin HCL Ophthalmic Solution (Ciloxan Ophthalmic Solution); Clemastine Fumarate Syrup (Clemastine Fumarate Syrup); CoLyte (PEG Electrolytes Solution); Combiven; Comtan; Condylox; Cordran; Cortisporin Ophthalmic Suspension; Cortisporin Otic Suspension; Cromolyn Sodium Inhalation Solution (Intal Nebulizer Solution); Cromolyn Sodium Ophthalmic Solution (Opticrom); Crystalline Amino Acid Solution with Electrolytes (Aminosyn Electrolytes); Cutivate; Cuvposa (Glycopyrrolate Oral Solution); Cyanocobalamin (CaloMist Nasal Spray); Cyclosporine Oral Solution (Gengraf Oral Solution); Cyclogyl; Cysview (Hexaminolevulinate Hydrochloride Intravesical Solution); DermOtic Oil (Fluocinolone Acetonide Oil Ear Drops); Desmopressin Acetate Nasal Spray; DDAVP; Derma-Smoothe/FS; Dexamethasone Intensol; Dianeal Low Calcium; Dianeal PD; Diclofenac Potassium for Oral Solution (Cambia); Didanosine Pediatric Powder for Oral Solution (Videx); Differin; Dilantin 125 (Phenytoin Oral Suspension); Ditropan; Dorzolamide Hydrochloride Ophthalmic Solution (Trusopt); Dorzolamide Hydrochloride-Timolol Maleate Ophthalmic Solution (Cosopt); Dovonex Scalp (Calcipotriene Solution); Doxycycline Calcium Oral Suspension (Vibramycin Oral); Efudex; Elaprase (Idursulfase Solution); Elestat (Epinastine HCl Ophthalmic Solution); Elocon; Epinastine HCl Ophthalmic Solution (Elestat); Epivir HBV; Epogen (Epoetin alfa); Erythromycin Topical Solution 1.5% (Staticin); Ethiodol (Ethiodized Oil); Ethosuximide Oral Solution (Zarontin Oral Solution); Eurax; Extraneal (Icodextrin Peritoneal Dialysis Solution); Felbatol; Feridex I.V. (Ferumoxides Injectable Solution); Flovent; Floxin Otic (Ofloxacin Otic Solution); Flo-Pred (Prednisolone Acetate Oral Suspension); Fluoroplex; Flunisolide Nasal Solution (Flunisolide Nasal Spray 0.025%); Fluorometholone Ophthalmic Suspension (FML); Flurbiprofen Sodium Ophthalmic Solution (Ocufen); FML; Foradil; Formoterol Fumarate Inhalation Solution (Perforomist); Fosamax; Furadantin (Nitrofurantoin Oral Suspension); Furoxone; Gammagard Liquid (Immune Globulin Intravenous (Human) 10%); Gantrisin (Acetyl Sulfisoxazole Pediatric Suspension); Gatifloxacin Ophthalmic Solution (Zymar); Gengraf Oral Solution (Cyclosporine Oral Solution); Glycopyrrolate Oral Solution (Cuvposa); Halcinonide Topical Solution (Halog Solution); Halog Solution (Halcinonide Topical Solution); HEP-LOCK U/P (Preservative-Free Heparin Lock Flush Solution); Heparin Lock Flush Solution (Hepflush 10); Hexaminolevulinate Hydrochloride Intravesical Solution (Cysview); Hydrocodone Bitartrate and Acetaminophen Oral Solution (Lortab Elixir); Hydroquinone 3% Topical Solution (Melquin-3 Topical Solution); IAP Antagonist; Isopto; Ipratropium Bromide Nasal Spray (Atrovent Nasal Spray); Itraconazole Oral Solution (Sporanox Oral Solution); Ketorolac Tromethamine Ophthalmic Solution (Acular LS); Kaletra; Lanoxin; Lexiva; Leuprolide Acetate for Depot Suspension (Lupron Depot 11.25 mg); Levobetaxolol Hydrochloride Ophthalmic Suspension (Betaxon); Levocarnitine Tablets, Oral Solution, Sugar-Free (Carnitor); Levofloxacin Ophthalmic Solution 0.5% (Quixin); Lidocaine HCl Sterile Solution (Xylocaine MPF Sterile Solution); Lok Pak (Heparin Lock Flush Solution); Lorazepam Intensol; Lortab Elixir (Hydrocodone Bitartrate and Acetaminophen Oral Solution); Lotemax (Loteprednol Etabonate Ophthalmic Suspension); Loteprednol Etabonate Ophthalmic Suspension (Alrex); Low Calcium Peritoneal Dialysis Solutions (Dianeal Low Calcium); Lumigan (Bimatoprost Ophthalmic Solution 0.03% for Glaucoma); Lupron Depot 11.25 mg (Leuprolide Acetate for Depot Suspension); Megestrol Acetate Oral Suspension (Megestrol Acetate Oral Suspension); MEK Inhibitor; Mepron; Mesnex; Mestinon; Mesalamine Rectal Suspension Enema (Rowasa); Melquin-3 Topical Solution (Hydroquinone 3% Topical Solution); MetMab; Methyldopate Hcl (Methyldopate Hydrochloride Injection, Solution); Methylin Oral Solution (Methylphenidate HCl Oral Solution 5 mg/5 mL and 10 mg/5 mL); Methylprednisolone Acetate Injectable Suspension (Depo Medrol); Methylphenidate HCl Oral Solution 5 mg/5 mL and 10 mg/5 mL (Methylin Oral Solution); Methylprednisolone sodium succinate (Solu Medrol); Metipranolol Ophthalmic Solution (Optipranolol); Migranal; Miochol-E (Acetylcholine Chloride Intraocular Solution); Micro-K for Liquid Suspension (Potassium Chloride Extended Release Formulation for Liquid Suspension); Minocin (Minocycline Hydrochloride Oral Suspension); Nasacort; Neomycin and Polymyxin B Sulfates and Hydrocortisone; Nepafenac Ophthalmic Suspension (Nevanac); Nevanac (Nepafenac Ophthalmic Suspension); Nitrofurantoin Oral Suspension (Furadantin); Noxafil (Posaconazole Oral Suspension); Nystatin (oral) (Nystatin Oral Suspension); Nystatin Oral Suspension (Nystatin (oral)); Ocufen (Flurbiprofen Sodium Ophthalmic Solution); Ofloxacin Ophthalmic Solution (Ofloxacin Ophthalmic Solution); Ofloxacin Otic Solution (Floxin Otic); Olopatadine Hydrochloride Ophthalmic Solution (Pataday); Opticrom (Cromolyn Sodium Ophthalmic Solution); Optipranolol (Metipranolol Ophthalmic Solution); Patanol; Pediapred; PerioGard; Phenytoin Oral Suspension (Dilantin 125); Phisohex; Posaconazole Oral Suspension (Noxafil); Potassium Chloride Extended Release Formulation for Liquid Suspension (Micro-K for Liquid Suspension); Pataday (Olopatadine Hydrochloride Ophthalmic Solution); Patanase Nasal Spray (Olopatadine Hydrochloride Nasal Spray); PEG Electrolytes Solution (CoLyte); Pemirolast Potassium Ophthalmic Solution (Alamast); Penlac (Ciclopirox Topical Solution); PENNSAID (Diclofenac Sodium Topical Solution); Perforomist (Formoterol Fumarate Inhalation Solution); Peritoneal Dialysis Solution; Phenylephrine Hydrochloride Ophthalmic Solution (Neo-Synephrine); Phospholine Iodide (Echothiophate Iodide for Ophthalmic Solution); Podofilox (Podofilox Topical Solution); Pred Forte (Prednisolone Acetate Ophthalmic Suspension); Pralatrexate Solution for Intravenous Injection (Folotyn); Pred Mild; Prednisone Intensol; Prednisolone Acetate Ophthalmic Suspension (Pred Forte); Prevacid; PrismaSol Solution (Sterile Hemofiltration Hemodiafiltration Solution); ProAir; Proglycem; ProHance (Gadoteridol Injection Solution); Proparacaine Hydrochloride Ophthalmic Solution (Alcaine); Propine; Pulmicort; Pulmozyme; Quixin (Levofloxacin Ophthalmic Solution 0.5%); QVAR; Rapamune; Rebetol; Relacon-HC; Rotarix (Rotavirus Vaccine, Live, Oral Suspension); Rotavirus Vaccine, Live, Oral Suspension (Rotarix); Rowasa (Mesalamine Rectal Suspension Enema); Sabril (Vigabatrin Oral Solution); Sacrosidase Oral Solution (Sucraid); Sandimmune; Sepra; Serevent Diskus; Solu Cortef (Hydrocortisone Sodium Succinate); Solu Medrol (Methylprednisolone sodium succinate); Spiriva; Sporanox Oral Solution (Itraconazole Oral Solution); Staticin (Erythromycin Topical Solution 1.5%); Stalevo; Starlix; Sterile Hemofiltration Hemodiafiltration Solution (PrismaSol Solution); Stimate; Sucralfate (Carafate Suspension); Sulfacetamide Sodium Ophthalmic Solution 10% (Bleph 10); Synarel Nasal Solution (Nafarelin Acetate Nasal Solution for Endometriosis); Taclonex Scalp (Calcipotriene and Betamethasone Dipropionate Topical Suspension); Tamiflu; Tobi; TobraDex; Tobradex ST (Tobramycin/Dexamethasone Ophthalmic Suspension 0.3%/0.05%); Tobramycin/Dexamethasone Ophthalmic Suspension 0.3%/0.05% (Tobradex ST); Timolol; Timoptic; Travatan Z; Treprostinil Inhalation Solution (Tyvaso); Trusopt (Dorzolamide Hydrochloride Ophthalmic Solution); Tyvaso (Treprostinil Inhalation Solution); Ventolin; Vfend; Vibramycin Oral (Doxycycline Calcium Oral Suspension); Videx (Didanosine Pediatric Powder for Oral Solution); Vigabatrin Oral Solution (Sabril); Viokase; Viracept; Viramune; Vitamin K1 (Fluid Colloidal Solution of Vitamin K1); Voltaren Ophthalmic (Diclofenac Sodium Ophthalmic Solution); Zarontin Oral Solution (Ethosuximide Oral Solution); Ziagen; Zyvox; Zymar (Gatifloxacin Ophthalmic Solution); Zymaxid (Gatifloxacin Ophthalmic Solution)

### Drug Classes

5-alpha-reductase inhibitors; 5-aminosalicylates; 5HT3 receptor antagonists; adamantane antivirals; adrenal cortical steroids; adrenal corticosteroid inhibitors; adrenergic bronchodilators; agents for hypertensive emergencies; agents for pulmonary hypertension; aldosterone receptor antagonists; alkylating agents; alpha-adrenoreceptor antagonists; alpha-glucosidase inhibitors; alternative medicines; amebicides; aminoglycosides; aminopenicillins; aminosalicylates; amylin analogs; Analgesic Combinations; Analgesics; androgens and anabolic steroids; angiotensin converting enzyme inhibitors; angiotensin II inhibitors; anorectal preparations; anorexiants; antacids; anthelmintics; anti-angiogenic ophthalmic agents; anti-CTLA-4 monoclonal antibodies; anti-infectives; antiadrenergic agents, centrally acting; antiadrenergic agents, peripherally acting; antiandrogens; antianginal agents; antiarrhythmic agents; antiasthmatic combinations; antibiotics/antineoplastics; anticholinergic antiemetics; anticholinergic antiparkinson agents; anticholinergic bronchodilators; anticholinergic chronotropic agents; anticholinergics/antispasmodics; anticoagulants; anticonvulsants; antidepressants; antidiabetic agents; antidiabetic combinations; antidiarrheals; antidiuretic hormones; antidotes; antiemetic/antivertigo agents; antifungals; antigonadotropic agents; antigout agents; antihistamines; antihyperlipidemic agents; antihyperlipidemic combinations; antihypertensive combinations; antihyperuricemic agents; antimalarial agents; antimalarial combinations; antimalarial quinolines; antimetabolites; antimigraine agents; antineoplastic detoxifying agents; antineoplastic interferons; antineoplastic monoclonal antibodies; antineoplastics; antiparkinson agents; antiplatelet agents; antipseudomonal penicillins; antipsoriatics; antipsychotics; antirheumatics; antiseptic and germicides; antithyroid agents; antitoxins and antivenins; antituberculosis agents; antituberculosis combinations; antitussives; antiviral agents; antiviral combinations; antiviral interferons; anxiolytics, sedatives, and hypnotics; aromatase inhibitors; atypical antipsychotics; azole antifungals; bacterial vaccines; barbiturate anticonvulsants; barbiturates; BCR-ABL tyrosine kinase inhibitors; benzodiazepine anticonvulsants; benzodiazepines; beta-adrenergic blocking agents; beta-lactamase inhibitors; bile acid sequestrants; biologicals; bisphosphonates; bone resorption inhibitors; bronchodilator combinations; bronchodilators; calcitonin; calcium channel blocking agents; carbamate anticonvulsants; carbapenems; carbonic anhydrase inhibitor anticonvulsants; carbonic anhydrase inhibitors; cardiac stressing agents; cardioselective beta blockers; cardiovascular agents; catecholamines; CD20 monoclonal antibodies; CD33 monoclonal antibodies; CD52 monoclonal antibodies; central nervous system agents; cephalosporins; cerumenolytics; chelating agents; chemokine receptor antagonist; chloride channel activators; cholesterol absorption inhibitors; cholinergic agonists; cholinergic muscle stimulants; cholinesterase inhibitors; CNS stimulants; coagulation modifiers; colony stimulating factors; contraceptives; corticotropin; coumarins and indandiones; cox-2 inhibitors; decongestants; dermatological agents; diagnostic radiopharmaceuticals; dibenzazepine anticonvulsants; digestive enzymes; dipeptidyl peptidase 4 inhibitors; diuretics; dopaminergic antiparkinsonism agents; drugs used in alcohol dependence; echinocandins; EGFR inhibitors; estrogen receptor antagonists; estrogens; expectorants; factor Xa inhibitors; fatty acid derivative anticonvulsants; fibric acid derivatives; first generation cephalosporins; fourth generation cephalosporins; functional bowel disorder agents; gallstone solubilizing agents; gamma-aminobutyric acid analogs; gamma-aminobutyric acid reuptake inhibitors; gamma-aminobutyric acid transaminase inhibitors; gastrointestinal agents; general anesthetics; genitourinary tract agents; GI stimulants; glucocorticoids; glucose elevating agents; glycopeptide antibiotics; glycoprotein platelet inhibitors; glycylcyclines; gonadotropin releasing hormones; gonadotropin-releasing hormone antagonists; gonadotropins; group I antiarrhythmics; group II antiarrhythmics; group III antiarrhythmics; group IV antiarrhythmics; group V antiarrhythmics; growth hormone receptor blockers; growth hormones; H. pylori eradication agents; H2 antagonists; hematopoietic stem cell mobilizer; heparin antagonists; heparins; HER2 inhibitors; herbal products; histone deacetylase inhibitors; hormone replacement therapy; hormones; hormones/antineoplastics; hydantoin anticonvulsants; illicit (street) drugs; immune globulins; immunologic agents; immunosuppressive agents; impotence agents; in vivo diagnostic biologicals; incretin mimetics; inhaled anti-infectives; inhaled corticosteroids; inotropic agents; insulin; insulin-like growth factor; integrase strand transfer inhibitor; interferons; intravenous nutritional products; iodinated contrast media; ionic iodinated contrast media; iron products; ketolides; laxatives; leprostatics; leukotriene modifiers; lincomycin derivatives; lipoglycopeptides; local injectable anesthetics; loop diuretics; lung surfactants; lymphatic staining agents; lysosomal enzymes; macrolide derivatives; macrolides; magnetic resonance imaging contrast media; mast cell stabilizers; medical gas; meglitinides; metabolic agents; methylxanthines; mineralocorticoids; minerals and electrolytes; miscellaneous agents; miscellaneous analgesics; miscellaneous antibiotics; miscellaneous anticonvulsants; miscellaneous antidepressants; miscellaneous antidiabetic agents; miscellaneous antiemetics; miscellaneous antifungals; miscellaneous antihyperlipidemic agents; miscellaneous antimalarials; miscellaneous antineoplastics; miscellaneous antiparkinson agents; miscellaneous antipsychotic agents; miscellaneous antituberculosis agents; miscellaneous antivirals; miscellaneous anxiolytics, sedatives and hypnotics; miscellaneous biologicals; miscellaneous bone resorption inhibitors; miscellaneous cardiovascular agents; miscellaneous central nervous system agents; miscellaneous coagulation modifiers; miscellaneous diuretics; miscellaneous genitourinary tract agents; miscellaneous GI agents; miscellaneous hormones; miscellaneous metabolic agents; miscellaneous ophthalmic agents; miscellaneous otic agents; miscellaneous respiratory agents; miscellaneous sex hormones; miscellaneous topical agents; miscellaneous uncategorized agents; miscellaneous vaginal agents; mitotic inhibitors; monoamine oxidase inhibitors; monoclonal antibodies; mouth and throat products; mTOR inhibitors; mTOR kinase inhibitors; mucolytics; multikinase inhibitors; muscle relaxants; mydriatics; narcotic analgesic combinations; narcotic analgesics; nasal anti-infectives; nasal antihistamines and decongestants; nasal lubricants and irrigations; nasal preparations; nasal steroids; natural penicillins; neuraminidase inhibitors; neuromuscular blocking agents; next generation cephalosporins; nicotinic acid derivatives; nitrates; NNRTIs; non-cardioselective beta blockers; non-iodinated contrast media; non-ionic iodinated contrast media; non-sulfonylureas; nonsteroidal anti-inflammatory agents; norepinephrine reuptake inhibitors; norepinephrine-dopamine reuptake inhibitors; nucleoside reverse transcriptase inhibitors (NRTIs); nutraceutical products; nutritional products; ophthalmic anesthetics; ophthalmic anti-infectives; ophthalmic anti-inflammatory agents; ophthalmic antihistamines and decongestants; ophthalmicdiagnostic agents; ophthalmic glaucoma agents; ophthalmic lubricants and irrigations; ophthalmic preparations; ophthalmic steroids; ophthalmic steroids with anti-infectives; ophthalmic surgical agents; oral nutritional supplements; otic anesthetics; otic anti-infectives; otic preparations; otic steroids; otic steroids with anti-infectives; oxazolidinedione anticonvulsants; parathyroid hormone and analogs; penicillinase resistant penicillins; penicillins; peripheral opioid receptor antagonists; peripheral vasodilators; peripherally acting antiobesity agents; phenothiazine antiemetics; phenothiazine antipsychotics; phenylpiperazine antidepressants; plasma expanders; platelet aggregation inhibitors; platelet-stimulating agents; polyenes; potassium-sparing diuretics; probiotics; progesterone receptor modulators; progestins; prolactin inhibitors; prostaglandin D2 antagonists; protease inhibitors; proton pump inhibitors; psoralens; psychotherapeutic agents; psychotherapeutic combinations; purine nucleosides; pyrrolidine anticonvulsants; quinolones; radiocontrast agents; radiologic adjuncts; radiologic agents; radiologic conjugating agents; radiopharmaceuticals; RANK ligand inhibitors; recombinant human erythropoietins; renin inhibitors; respiratory agents; respiratory inhalant products; rifamycin derivatives; salicylates; sclerosing agents; second generation cephalosporins; selective estrogen receptor modulators; selective serotonin reuptake inhibitors; serotonin-norepinephrine reuptake inhibitors; serotoninergic neuroenteric modulators; sex hormone combinations; sex hormones; skeletal muscle relaxant combinations; skeletal muscle relaxants; smoking cessation agents; somatostatin and somatostatin analogs; spermicides; statins; sterile irrigating solutions; streptomyces derivatives; succinimide anticonvulsants; sulfonamides; sulfonylureas; synthetic ovulation stimulants; tetracyclic antidepressants; tetracyclines; therapeutic radiopharmaceuticals; thiazide diuretics; thiazolidinediones; thioxanthenes; third generation cephalosporins; thrombin inhibitors; thrombolytics; thyroid drugs; tocolytic agents; topical acne agents; topical agents; topical anesthetics; topical anti-infectives; topical antibiotics; topical antifungals; topical antihistamines; topical antipsoriatics; topical antivirals; topical astringents; topical debriding agents; topical depigmenting agents; topical emollients; topical keratolytics; topical steroids; topical steroids with anti-infectives; toxoids; triazine anticonvulsants; tricyclic antidepressants; trifunctional monoclonal antibodies; tumor necrosis factor (TNF) inhibitors; tyrosine kinase inhibitors; ultrasound contrast media; upper respiratory combinations; urea anticonvulsants; urinary anti-infectives; urinary antispasmodics; urinary pH modifiers; uterotonic agents; vaccine; vaccine combinations; vaginal anti-infectives; vaginal preparations; vasodilators; vasopressin antagonists; vasopressors; VEGFNEGFR inhibitors; viral vaccines; viscosupplementation agents; vitamin and mineral combinations; vitamins

### Diagnostic Tests

17-Hydroxyprogesterone; ACE (Angiotensin I converting enzyme); Acetaminophen; Acid phosphatase; ACTH; Activated clotting time; Activated protein C resistance; Adrenocorticotropic hormone (ACTH); Alanine aminotransferase (ALT); Albumin; Aldolase; Aldosterone; Alkaline phosphatase; Alkaline phosphatase (ALP); Alpha1-antitrypsin; Alpha-fetoprotein; Alpha-fetoprotien; Ammonia levels; Amylase; ANA (antinuclear antibodies); ANA (antinuclear antibodies); Angiotensin-converting enzyme (ACE); Anion gap; Anticardiolipin antibody; Anticardiolipin antibodies (ACA); Anti-centromere antibody; Antidiuretic hormone; Anti-DNA; Anti-Dnase-B; Anti-Gliadin antibody; Anti-glomerular basement membrane antibody; Anti-HBc (Hepatitis B core antibodies; Anti-HBs (Hepatitis B surface antibody; Antiphospholipid antibody; Anti-RNA polymerase; Anti-Smith (Sm) antibodies; Anti-Smooth Muscle antibody; Antistreptolysin O (ASO); Antithrombin III; Anti-Xa activity; Anti-Xa assay; Apolipoproteins; Arsenic; Aspartate aminotransferase (AST); B12; Basophil; Beta-2-Microglobulin; Beta-hydroxybutyrate; B-HCG; Bilirubin; Bilirubin, direct; Bilirubin, indirect; Bilirubin, total; Bleeding time; Blood gases (arterial); Blood urea nitrogen (BUN); BUN; BUN (blood urea nitrogen); CA 125; CA 15-3; CA 19-9; Calcitonin; Calcium; Calcium (ionized); Carbon monoxide (CO); Carcinoembryonic antigen (CEA); CBC; CEA; CEA (carcinoembryonic antigen); Ceruloplasmin; CH50Chloride; Cholesterol; Cholesterol, HDL; Clot lysis time; Clot retraction time; CMP; CO2; Cold agglutinins; Complement C3; Copper; Corticotrophin releasing hormone (CRH) stimulation test; Cortisol; Cortrosyn stimulation test; C-peptide; CPK (Total); CPK-MB; C-reactive protein; Creatinine; Creatinine kinase (CK); Cryoglobulins; DAT (Direct antiglobulin test); D-Dimer; Dexamethasone suppression test; DHEA-S; Dilute Russell viper venom; Elliptocytes; Eosinophil; Erythrocyte sedimentation rate (ESR); Estradiol; Estriol; Ethanol; Ethylene glycol; Euglobulin lysis; Factor V Leiden; Factor VIII inhibitor; Factor VIII level; Ferritin; Fibrin split products; Fibrinogen; Folate; Folate (serum; Fractional excretion of sodium (FENA); FSH (follicle stimulating factor); FTA-ABS; Gamma glutamyl transferase (GGT); Gastrin; GGTP (Gamma glutamyl transferase); Glucose; Growth hormone; Haptoglobin; HBeAg (Hepatitis Be antigen); HBs-Ag (Hepatitis B surface antigen); Helicobacter pylori; Hematocrit; Hematocrit (HCT); Hemoglobin; Hemoglobin A1C; Hemoglobin electrophoresis; Hepatitis A antibodies; Hepatitis C antibodies; IAT (Indirect antiglobulin test); Immunofixation (IFE); Iron; Lactate dehydrogenase (LDH); Lactic acid (lactate); LDH; LH (Leutinizing hormone; Lipase; Lupus anticoagulant; Lymphocyte; Magnesium; MCH (mean corpuscular hemoglobin; MCHC (mean corpuscular hemoglobin concentration); MCV (mean corpuscular volume); Methylmalonate; Monocyte; MPV (mean platelet volume); Myoglobin; Neutrophil; Parathyroid hormone (PTH); Phosphorus; Platelets (pit); Potassium; Prealbumin; Prolactin; Prostate specific antigen (PSA); Protein C; Protein S; PSA (prostate specific antigen); PT (Prothrombin time); PTT (Partial thromboplastin time); RDW (red cell distribution width); Renin; Rennin; Reticulocyte count; reticulocytes; Rheumatoid factor (RF); Sed Rate; Serum glutamic-pyruvic transaminase (SGPT; Serum protein electrophoresis (SPEP); Sodium; T3-resin uptake (T3RU); T4, Free; Thrombin time; Thyroid stimulating hormone (TSH); Thyroxine (T4); Total iron binding capacity (TIBC); Total protein; Transferrin; Transferrin saturation; Triglyceride (TG); Troponin; Uric acid; Vitamin B12; White blood cells (WBC); Widal test.

Another aspect of the invention is a method for applying one or more coatings to a vessel, particularly to a vessel having a lumen defined at least in part by a plastic wall, the plastic wall having an inner surface facing the lumen and an outer surface, and more particularly to the inner surface of the vessel wall. The one or more coatings may include any combination of those described above.

In an embodiment, the method comprises applying at least one of the one or more coatings, and optionally each of the one or more coatings or layers, by a step that comprises applying sufficient power to generate plasma within the lumen and feeding a precursor gas for a defined deposition time to produce the coating or layer, and then extinguishing the plasma. The plasma may be generated using a pulsed RF power source and may have a power of at least 100 W and a pulsing frequency of at least 5 Hz.

The use of relatively high power and frequency provides for high density coatings or layers having the desired properties, that can be applied in short deposition times and/or at lower thicknesses compared to conventional PECVD coating methods used in the field. The use of relatively high power also allows for the coating of a greater number of vessels, e.g. at least 12 vessels or at least 16 vessels at a time using the same RF power source, as well as a better control over the plasma conditions and stability within the lumen of each vessel and thus greater consistency between vessel coatings. When operating at relatively high power, pulsing is used to prevent over-heating and deformation of the thermoplastic material that makes up the vessel wall.

In some embodiments, pulsed RF power may also be used to improve gas distribution within a vessel lumen. In conventional methods for coating the inner surface of a vessel such as those described above, the precursor gas(es) is introduced into the lumen by a component that extends into the lumen and which has a plurality of outlets through which the precursor gas(es) flow relatively uniformly throughout the length of the lumen. This is necessary because introducing precursor gas directly into the lumen through an opening in the vessel results in a non-uniform coating in which the thickness of the coating near the vessel opening is significantly greater than the thickness of the coating at a distance from the vessel opening, e.g. at or near a closed end of the vessel. Use of the gas outlet component that extends into the lumen, however, produces the undesirable result that the component needs to be removed and cleaned and/or replaced after a number of coating cycles due to the build-up of coating on the component itself. For example, during a conventional process, one may need to stop a coating process after every 1.5 hours of operation in order to remove and replace the gas outlet component, a process that can take about 10 minutes, leading to a loss of about 10% of vessel coating throughput.

In some embodiments, the precursor gas flow rate and the pulsing of the RF power may be controlled in order to improve the distribution of precursor gas(es) within the lumen so that the precursor gas(es) can be supplied directly into the lumen through an open end of a vessel and without any gas outlet component being positioned within the lumen. For instance, the pulse rate of the RF power may be controlled so that the time between pulses allows for the gas introduced into the lumen to distribute substantially uniformly throughout the lumen, leading to a coating have a substantially uniform thickness. In some embodiments, a partition, e.g. an aluminum screen, is placed between a gas inlet (positioned outside of the vessel lumen) and the vessel lumen, the partition being permeable to the precursor gas(es) but preventing the plasma from igniting outside of the lumen.

Embodiments of the method of the present disclosure may thus comprise the steps of a. providing a vessel having a lumen defined at least in part by a plastic wall, the plastic wall having an interior surface facing the lumen and an outer surface; b. drawing a partial vacuum in the lumen; c. optionally applying a tie coating or layer of SiOxCy, wherein x is from about 0.5 to about 2.4 and y is from about 0.6 to about 3, each as determined by X-ray photoelectron spectroscopy (XPS), by a tie PECVD coating step that comprises applying a sufficient power to generate plasma within the lumen and feeding a precursor gas comprising a siloxane, optionally oxygen, and optionally an inert gas diluent, for a deposition time to produce the tie coating or layer on the interior surface. and then extinguishing the plasma; d. while maintaining the partial vacuum unbroken in the lumen, applying a barrier coating or layer of SiOx, wherein x is from 1.5 to 2.9 as determined by XPS, by a barrier PECVD coating step that comprises applying sufficient power to generate plasma within the lumen and feeding a precursor gas comprising a siloxane and oxygen, for a deposition time to produce the barrier coating or layer on the interior surface, optionally on the interior surface treated according to step c. to have a tie coating or layer, and then extinguishing the plasma; e. optionally applying a pH protective coating or layer of SiOxCy, wherein x is from about 0.5 to about 2.4 and y is from about 0.6 to about 3, each as determined by XPS, between the barrier coating or layer and the lumen, by a pH protective PECVD coating step that comprises applying sufficient power to generate plasma within the lumen and feeding a precursor gas comprising a siloxane, optionally oxygen, and optionally an inert gas diluent, for a deposition time to produce the pH protective coating or layer, and then extinguishing the plasma. The plasma in step d may be generated using pulsed RF having a power of at least 200 W, optionally at least 225 W, optionally at least 250 W, optionally at least 275 W, optionally at least 300 W, optionally at least 325 W, optionally at least 350 W, optionally at least 375 W, optionally at least 400 W, and a pulsing frequency of at least 50 Hz, optionally at least 75 Hz, optionally at least 100 Hz, optionally at least 125 Hz, optionally at least 150 Hz, optionally at least 175 Hz, optionally at least 200 Hz, optionally at least 225 Hz, optionally at least 250 Hz.

Where steps c. and/or e. are performed, the plasma in those steps may also be generated using pulsed RF having a power and pulsing frequency within any of the above-identified ranges. Moreover, where steps c. and/or e. are performed, the same siloxane precursor may be used for each of steps c., d., and/or e. In some embodiments, that siloxane precursor may comprise HMDSO, TMDSO, or a combination thereof. In some embodiments, that siloxane precursor may be HMDSO. Further, where steps c. and/or e. are performed, steps c., d., and/or e. may be performed without breaking the partial vacuum within the vessel or moving the vessel between separate coating stations.

The deposition time of step d. may be selected to provide a barrier layer having a desired thickness, i.e. a thickness that provides the vessel with a desired oxygen transmission rate (OTR). For instance, the deposition time of step d may be 20 seconds or less, optionally 15 seconds or less, optionally 10 seconds or less, optionally between 2 and 15 seconds, optionally between 3 and 10 seconds, optionally between 3 and 7 seconds. Relatedly, the deposition time may be selected (based on the power, pulsing frequency, etc.) to produce a barrier coating or layer having a mean thickness of at least 10 nm, optionally at least 15 nm, optionally at least 20 nm, optionally between 10 and 100 nm, optionally between 10 and 75 nm, optionally between 10 and 50 nm, optionally between 15 nm and 50 nm, optionally between 20 nm and 45 nm.

The deposition time of step c. may also be selected to provide a tie layer having a desired thickness. For instance, the deposition time of step c. may be 15 seconds or less, optionally 10 seconds or less, optionally 5 seconds or less, optionally between 2 seconds and 12 seconds, optionally between 3 seconds and 10 seconds, optionally between 3 seconds and 7 seconds. Relatedly, the deposition time may be selected (based on the power, pulsing frequency, etc.) to produce a tie coating or layer having a mean thickness of at least 5 nm, optionally at least 10 nm, optionally between 5 and 30 nm, optionally between 10 and 30 nm, optionally between 10 and 25 nm, optionally between 15 and 25 nm.

The deposition time of step e. may also be selected to provide a tie layer having a desired thickness. For instance, the deposition time of step e. may be 25 seconds or less, optionally 20 seconds or less, optionally 15 seconds or less, optionally 10 seconds or less, optionally between 4 seconds and 20 seconds, optionally between 5 seconds and 20 seconds, optionally between 5 seconds and 15 seconds, optionally between 5 seconds and 10 seconds. Relatedly, the deposition time may be selected (based on the power, pulsing frequency, etc.) to produce a pH protective coating or layer having a mean thickness of at least 30 nm, optionally at least 40 nm, optionally at least 50 nm.

In some embodiments, the method may further comprise a step f., which involves applying a lubricity coating or layer of SiOₓC_{y}, wherein x is from about 0.5 to about 2.4 and y is from about 0.6 to about 3, each as determined by XPS, between the barrier coating or layer or, if present, the pH protective coating or layer, and the lumen, by a lubricity PECVD coating step that comprises applying sufficient power to generate plasma within the lumen and feeding a precursor gas comprising a siloxane, optionally oxygen, and optionally an inert gas diluent, for a deposition time to produce the lubricity coating or layer, and then extinguishing the plasma. The plasma in step f. may also be generated using pulsed RF having a power of at least 200 W, optionally at least 225 W, optionally at least 250 W, optionally at least 275 W, optionally at least 300 W, optionally at least 325 W, optionally at least 350 W, optionally at least 375 W, optionally at least 400 W, and a pulsing frequency of at least 50 Hz, optionally at least 75 Hz, optionally at least 100 Hz, optionally at least 125 Hz, optionally at least 150 Hz, optionally at least 175 Hz, optionally at least 200 Hz, optionally at least 225 Hz, optionally at least 250 Hz.

The plasma in steps c., d., e., and/or f. may be generated using pulsed RF at a duty cycle of at least 25%, optionally at least 30%, optionally at least 35%, optionally at least 40%, optionally at least 45%, optionally at least 50%, optionally at least 55%. In some embodiments, for example, the plasma may have a duty cycle between 25% and 99%. In some embodiments, the plasma in steps c., d., e., and/or f. may be generated using pulsed RF having a pulse high power level between 250 W and 1000 W and/or a pulse low power level of 0 W. In some embodiments, the plasma in steps c., d., e., and/or f. may have a pulse train frequency between 150 kHz and 500 kHz.

In some embodiments, the precursor gas/gases may be introduced into the lumen of the vessel through a gas delivery device, or gas inlet probe, that extends within the lumen of the vessel.

In other embodiments, the precursor gas/gases may be supplied directly into the lumen of the vessel through an opening, e.g. open end, of the vessel. For instance, the pulsing rate of the plasma may be controlled so that no gas delivery device or gas outlet is positioned within the vessel lumen. Instead, for example, a gas outlet may be positioned outside (e.g. below in the illustrated systems) the vessel opening and the precursor gas/gases may flow through a partition before entering the lumen. The partition may be configured to be permeable to the precursor gas/gases, but to prevent a plasma from igniting outside of the vessel lumen, i.e. to operate as a plasma screen. For instance, the partition may comprise a metal mesh or a perforated metal plate.

Using systems such as that described herein, the above-described method may be used to coat eight or more vessels at the same time, optionally twelve or more vessels at the same time, optionally sixteen or more vessels at the same time. When coating a plurality of vessels at the same time, the plasma within the lumen of each of the plurality of vessels may be generated by the same power source. For instance, each of the vessels may be placed in a separate cavity of the same electrode. When coating a plurality of vessels at the same time, the precursor gas/gases introduced into the lumen of each of the plurality of vessels may be from the same gas supply and may be equally distributed to each of the plurality of vessels by a gas manifold, the vacuum drawn in the lumen of each of the plurality of vessels may be from the same vacuum source and may be equally distributed to each of the plurality of vessels by a vacuum manifold, or both.

In some embodiments, the method may comprise placing each of a plurality of vessels in one of a plurality of openings in a metal RF electrode, evacuating an internal volume of each of the plurality of vessels using a an exhaust manifold operably connected with a single vacuum and/or vacuum line, introducing one or more source gases into each of the plurality of vessels using a gas inlet manifold operably connected with a single precursor gas supply line, generating a plasma within each of the plurality of vessels using the one or more source gases and a pulsed RF signal applied to the metal RF electrode, and depositing a coating comprising at least one barrier coating or layer in each of the plurality of vessels using the plasma.

In some embodiments in which a plurality of vessels are being coated at the same time, the combination of steps c., d., and e.—i.e. the application of a trilayer coating set as described herein to each of the plurality of vessels—may be performed in less than 120 seconds, optionally less than 110 seconds, optionally less than 100 seconds, optionally less than 90 seconds, optionally less than 80 seconds, optionally less than 75 seconds, optionally less than 70 seconds, optionally less than 65 seconds.

Due to the uniformity of the coatings provided, in some embodiments in which a plurality of vessels are coated at the same time, each of the coated vessels may have substantially the same oxygen transmission rate constant as each of the other coated vessels. Similarly, due to the uniformity of the coatings provided, in some embodiments in which a plurality of vessels are coated at the same time, each of the coated vessels may have substantially the same amount and/or rate of silicon dissolution as each of the other coated vessels when contacted by a solution having a pH of 9 for 72 hours.

In some embodiments, the method may further comprise a step of applying one or more coatings to an outer surface of the vessel wall by pulsed RF PECVD. The step of applying one or more coatings to an outer surface of the vessel wall may be performed in the same system as the inner wall coating(s) described above, e.g. without moving the vessel to a separate coating station. The one or more coatings applied to an outer surface of the vessel wall may comprise an anti-static and/or anti-scratch coating, such as those described for example in US Pat. App. Pub. 2018/0049945 A1, the entirety of which is incorporated by reference herein.

In any embodiment, the method may be provide a desired coating set on on or more plastic vessels, including those in which the plastic wall comprises, consists essentially of, or consists of a COP or COC resin. In any embodiment, the method may be provide a desired coating set on on or more plastic vessels, including those in which the plastic wall comprises, consists essentially of, or consists of a cyclic block copolymer (CBC) resin; optionally wherein the plastic wall comprises or consists of a CBC resin selected from the group consisting of VIVION™ 0510, VIVION™ 0510HF, and VIVION™ 1325; optionally wherein the plastic wall comprises or consists of a CBC resin selected from the group consisting of VIVION™ 0510 and VIVION™ 0510HF; optionally wherein the plastic wall comprises or consists of VIVION™ 0510; optionally wherein the plastic wall comprises or consists of VIVION™ 0510HF.

Another aspect of the invention is a system for applying one or more coatings to a vessel, particularly to a vessel having a lumen defined at least in part by a plastic wall, the plastic wall having an inner surface facing the lumen and an outer surface, and more particularly to the inner surface of the vessel wall. The one or more coatings may include any combination of those described above.

In some embodiments, the system may utilize a gas outlet positioned within the vessel lumen. In other embodiments, the system may utilize a gas outlet positioned outside of the vessel lumen, e.g. below an opening of the vessel, so that the precursor gas(es) flow directly into the vessel lumen through the vessel opening.

Embodiments of the system of the present disclosure may thus comprise a radio frequency (RF) power supply; an RF electrode, the RF electrode comprising a plurality of openings each of which is configured to receive a vessel; an inlet gas manifold operable to split a single gas inlet to a plurality of gas source inputs, one for each vessel; and an exhaust manifold operable to exhaust each vessel into a single exhaust line. The system may be operable to receive a plurality of vessels in openings in the RF electrode; evacuate an internal volume of each of the plurality of vessels using a single vacuum line via the exhaust manifold; introduce one or more source gases into each of the plurality of vessels using a single source line via the gas inlet manifold; generate a plasma within each of the plurality of vessels using the one or more source gases and a pulsed RF signal applied to the metal RF electrode by the RF power supply; and deposit a coating comprising at least one barrier coating or layer in each of the plurality of vessels using the plasma.

### BRIEF DESCRIPTION OF THE DRAWINGS

FIG. 1 is a schematic sectional view of a vessel according to any embodiment of the invention.

FIG. 2 is an enlarged detail view of a portion of the vessel wall and coatings of FIG. 1.

FIG. 3 is a schematic view of a pharmaceutical package in the form of a syringe barrel as the vessel of FIGS. 1 and 2, containing a fluid and closed with a closure in the form of a plunger.

FIG. 4 is a schematic view of a pharmaceutical package in the form of a vial as the vessel of FIGS. 1 and 2 containing a fluid and closed with a closure.

FIG. 5 is a schematic view of a pharmaceutical package in the form of a blister package as the vessel of FIGS. 1 and 2 containing a fluid and closed with a closure in the form of a coated sheet defining an additional vessel wall.

FIG. 6 illustrates a pulsed RF PECVD reactor, in accordance with an example embodiment of the disclosure.

FIG. 7 illustrates a side view of a pulsed RF PECVD reactor, in accordance with an example embodiment of the disclosure.

FIG. 8 illustrates a top view of a pulsed RF PECVD reactor, in accordance with an example embodiment of the disclosure.

FIGS. 9 and 10 illustrate various views of an RF electrode, in accordance with an example embodiment of the disclosure

FIG. 11 illustrates a pulsed RF PECVD vessel deposition arrangement, in accordance with an example embodiment of the disclosure.

FIG. 12 illustrates a pulsed RF PECVD vessel deposition arrangement without an inlet probe, in accordance with an example embodiment of the disclosure.

FIG. 13 illustrates a pulsed RF PECVD syringe deposition arrangement without an inlet probe, in accordance with an example embodiment of the disclosure.

FIGS. 14 and 15 illustrate a pulsed RF PECVD arrangement for both inside and outside vessel deposition, in accordance with an example embodiment of the disclosure.

FIG. 16 illustrates cross-sectional views of a single vessel pulsed RF PECVD arrangement for both inside and outside vessel deposition, in accordance with an example embodiment of the disclosure.

FIG. 17 illustrates layer thickness versus layer growth time in a pulsed RF PECVD system with sixteen vessels coated concurrently, in accordance with an example embodiment of the disclosure.

FIG. 18 illustrates oxygen transmission rates for vials with barrier layers versus layer thickness, in accordance with an example embodiment of the disclosure.

FIGS. 19 and 20 show contour maps for vials grown in a sixteen vessel pulsed RF PECVD system, in accordance with an example embodiment of the disclosure.

FIG. 21 shows design-of-experiment scatter plots of dissolution rates for vials coated in a pulsed RF PECVD system, in accordance with an example embodiment of the disclosure.

FIGS. 22 and 23 illustrate oxygen barrier performance versus plasma pulsing rates, in accordance with an example embodiment of the disclosure.

FIG. 24 illustrates pressure uniformity between vessels in a pulsed RF PECVD system, in accordance with an example embodiment of the disclosure.

FIG. 25 illustrates pressure uniformity under gas flow between vessels in a pulsed RF PECVD system, in accordance with an example embodiment of the disclosure.

FIG. 26 illustrates the coating integrity of vessels coated in a pulsed RF PECVD system, in accordance with an example embodiment of the disclosure.

FIG. 27 is a plot comparing the pulsed RF PECVD process on two different systems over eight hours of continuous operation, in accordance with an example embodiment of the disclosure.

FIG. 28 is a plot showing the oxygen transmission rate (OTR) of various vessel wall materials both in an uncoated state and as coated with a barrier layer in accordance with an example embodiment of the disclosure.

FIG. 29 is a perspective view of an RF electrode in accordance with an example embodiment of the disclosure.

The following reference characters are used in the drawing figures:

| | | | |
|---|---|---|---|
| 210 | Pharmaceutical package | 274 | Lumen |
| 212 | Lumen | 276 | Wall-contacting surface |
| 214 | Wall | 278 | Inner or interior surface (of |
| 216 | Outer surface | 280 | Vessel wall |
| 218 | Fluid | 281 | Lubricity coating or layer |
| 220 | Interior surface (of 288) | 282 | Stopper |
| 222 | Outer surface (of 288) | 283 | Primer coating or layer |
| 224 | Interior surface (of 286) | 284 | Shield |
| 226 | Outer surface (of 286) | 285 | Vessel coating or layer set |
| 228 | Vial | 286 | pH protective coating or layer |
| 230 | Blister package | 287 | Deposit of lubricant |
| 250 | Syringe barrel | 288 | Barrier layer |
| 252 | Syringe | 289 | Tie coating or layer |
| 254 | Inner or interior surface (of 250) | 290 | Apparatus for coating, for |
| 256 | Back end (of 250) | 292 | Inner or interior surface (of |
| 258 | Plunger (of 252) (relatively | 294 | Restricted opening (of 250) |
| 259 | Lubricant | 296 | Processing vessel |
| 260 | Front end (of 250) | 298 | Outer surface (of 250) |
| 262 | Closure | 1101 | Gas delivery probe |
| 264 | Inner or interior surface (of 262) | 1105 | Vessel holder |
| 268 | Vessel | 1107 | Plasma screen |
| 270 | Closure | 1201 | Inlet line |
| 272 | Interior facing surface | 1400 | Quad pulsed RF PECVD |
| 600 | Pulsed plasma PECVD reactor | 1401A-C | Deposition chambers |
| 601 | RF power supply | 1405 | Manifold |
| 603 | RF electrode | 1407 | Manifold |
| 605 | Vessel cavities | 1600 | Pulsed RF PECVD |
| 607 | Camera | 1607 | Manifold |
| 609 | Exhaust manifold | | |
| 611 | Gas inlet manifold | | |
| 611A | Input port | | |
| 613 | Vacuum line | | |

In the context of the present invention, the following definitions and abbreviations are used:

Pulsed RF PECVD is pulsed radio frequency plasma enhanced chemical vapor deposition where a plasma is utilized to enhance deposition by dissociation of precursor materials utilizing a plasma that is pulsed at RF frequencies. In other example scenarios, the plasma may be pulsed at microwave frequencies.

The term “at least” in the context of the present invention means “equal or more” than the integer following the term. The word “comprising” does not exclude other elements or steps, and the indefinite article “a” or “an” does not exclude a plurality unless indicated otherwise. Whenever a parameter range is indicated, it is intended to disclose the parameter values given as limits of the range and all values of the parameter falling within said range.

“First” and “second” or similar references to, for example, deposits of lubricant, processing stations or processing devices refer to the minimum number of deposits, processing stations or devices that are present, but do not necessarily represent the order or total number of deposits, processing stations and devices or require additional deposits, processing stations and devices beyond the stated number. These terms do not limit the number of processing stations or the particular processing carried out at the respective stations. For example, a “first” deposit in the context of this specification can be either the only deposit or any one of plural deposits, without limitation. In other words, recitation of a “first” deposit allows but does not require an embodiment that also has a second or further deposit.

For purposes of the present invention, an “organosilicon precursor” is a compound having at least one of the linkages:

| | | |
|---|---|---|
| ┌ | | O Si C H |
| | Or | |
| ┌ | | NH Si C H |

which is a tetravalent silicon atom connected to an oxygen or nitrogen atom and an organic carbon atom (an organic carbon atom being a carbon atom bonded to at least one hydrogen atom). A volatile organosilicon precursor, defined as such a precursor that can be supplied as a vapor in a PECVD apparatus, is an optional organosilicon precursor. Optionally, the organosilicon precursor is selected from the group consisting of a linear siloxane, a monocyclic siloxane, a polycyclic siloxane, a polysilsesquioxane, an alkyl trimethoxysilane, a linear silazane, a monocyclic silazane, a polycyclic silazane, a polysilsesquiazane, and a combination of any two or more of these precursors.

The feed amounts of PECVD precursors, gaseous reactant or process gases, and carrier gas are sometimes expressed in “standard volumes” in the specification and claims. The standard volume of a charge or other fixed amount of gas is the volume the fixed amount of the gas would occupy at a standard temperature and pressure (without regard to the actual temperature and pressure of delivery). Standard volumes can be measured using different units of volume, and still be within the scope of the present disclosure and claims. For example, the same fixed amount of gas could be expressed as the number of standard cubic centimeters, the number of standard cubic meters, or the number of standard cubic feet. Standard volumes can also be defined using different standard temperatures and pressures, and still be within the scope of the present disclosure and claims. For example, the standard temperature might be 0° C. and the standard pressure might be 760 Torr (as is conventional), or the standard temperature might be 20° C. and the standard pressure might be 1 Torr. But whatever standard is used in a given case, when comparing relative amounts of two or more different gases without specifying particular parameters, the same units of volume, standard temperature, and standard pressure are to be used relative to each gas, unless otherwise indicated.

The corresponding feed rates of PECVD precursors, gaseous reactant or process gases, and carrier gas are expressed in standard volumes per unit of time in the specification. For example, in the working examples the flow rates are expressed as standard cubic centimeters per minute, abbreviated as sccm. As with the other parameters, other units of time can be used, such as seconds or hours, but consistent parameters are to be used when comparing the flow rates of two or more gases, unless otherwise indicated.

A “vessel” in the context of the present invention can be any type of vessel with at least one opening and a wall defining an inner or interior surface. The substrate can be the wall of a vessel having a lumen. Though the invention is not necessarily limited to pharmaceutical packages or other vessels of a particular volume, pharmaceutical packages or other vessels are contemplated in which the lumen has a void volume of from 0.5 to 50 mL, optionally from 1 to 10 mL, optionally from 0.5 to 5 mL, optionally from 1 to 3 mL. The substrate surface can be part or all of the inner or interior surface of a vessel having at least one opening and an inner or interior surface. Some examples of a pharmaceutical package include, but are not limited to, a vial, a plastic-coated vial, a syringe, a plastic coated syringe, a blister pack, an ampoule, a plastic coated ampoule, a cartridge, a bottle, a plastic coated bottle, a pouch, a pump, a sprayer, a stopper, a needle, a plunger, a cap, a stent, a catheter or an implant.

The term “at least” in the context of the present invention means “equal or more” than the integer following the term. Thus, a vessel in the context of the present invention has one or more openings. One or two openings, like the openings of a sample tube (one opening) or a syringe barrel (two openings) are preferred. If the vessel has two openings, they can be of same or different size. If there is more than one opening, one opening can be used for the gas inlet for a PECVD coating method according to the present invention, while the other openings are either capped or open. A vessel according to the present invention can be a sample tube, for example for collecting or storing biological fluids like blood or urine, a syringe (or a part thereof, for example a syringe barrel) for storing or delivering a biologically active compound or composition, for example a medicament or pharmaceutical composition, a vial for storing biological materials or biologically active compounds or compositions, a pipe, for example a catheter for transporting biological materials or biologically active compounds or compositions, or a cuvette for holding fluids, for example for holding biological materials or biologically active compounds or compositions.

A vessel can be of any shape, a vessel having a substantially cylindrical wall adjacent to at least one of its open ends being preferred. Generally, the interior wall of the vessel is cylindrically shaped, like, for example in a sample tube or a syringe barrel. Sample tubes and syringes or their parts (for example syringe barrels) are contemplated.

A “hydrophobic layer” in the context of the present invention means that the coating or layer lowers the wetting tension of a surface coated with the coating or layer, compared to the corresponding uncoated surface. Hydrophobicity is thus a function of both the uncoated substrate and the coating or layer. The same applies with appropriate alterations for other contexts wherein the term “hydrophobic” is used. The term “hydrophilic” means the opposite, i.e. that the wetting tension is increased compared to reference sample. The present hydrophobic layers are primarily defined by their hydrophobicity and the process conditions providing hydrophobicity

These values of w, x, y, and z are applicable to the empirical composition Si_{w}OₓC_{y}H_{z} throughout this specification. The values of w, x, y, and z used throughout this specification should be understood as ratios or an empirical formula (for example for a coating or layer), rather than as a limit on the number or type of atoms in a molecule. For example, octamethylcyclotetrasiloxane, which has the molecular composition Si₄O₄C₈H₂₄, can be described by the following empirical formula, arrived at by dividing each of w, x, y, and z in the molecular formula by 4, the largest common factor: Si₁O₁C₂H₆. The values of w, x, y, and z are also not limited to integers. For example, (acyclic) octamethyltrisiloxane, molecular composition Si₃O₂C₈H₂₄, is reducible to Si₁O_{0.67}C_{2.67}H₈. Also, although SiOₓC_{y}H_{z} is described as equivalent to SiOₓC_{y}, it is not necessary to show the presence of hydrogen in any proportion to show the presence of SiOₓC_{y}.

“Wetting tension” is a specific measure for the hydrophobicity or hydrophilicity of a surface. An optional wetting tension measurement method in the context of the present invention is ASTM D 2578 or a modification of the method described in ASTM D 2578. This method uses standard wetting tension solutions (called dyne solutions) to determine the solution that comes nearest to wetting a plastic film surface for exactly two seconds. This is the film's wetting tension. The procedure utilized is varied herein from ASTM D 2578 in that the substrates are not flat plastic films, but are tubes made according to the Protocol for Forming PET Tube and (except for controls) coated according to the Protocol for coating Tube Interior with Hydrophobic Coating or Layer (see Example 9 of EP2251671 A2).

The atomic ratio can be determined by XPS. Taking into account the H atoms, which are not measured by XPS, the coating or layer may thus in one aspect have the formula Si_{w}OₓC_{y}H_{z} (or its equivalent SiOₓC_{y}), for example where w is 1, x is from about 0.5 to about 2.4, y is from about 0.6 to about 3, and z is from about 2 to about 9. Typically, such coating or layer would hence contain 36% to 41% carbon normalized to 100% carbon plus oxygen plus silicon.

The term “syringe” is broadly defined to include cartridges, injection “pens,” and other types of barrels or reservoirs adapted to be assembled with one or more other components to provide a functional syringe. “Syringe” is also broadly defined to include related articles such as auto-injectors, which provide a mechanism for dispensing the contents.

A coating or layer or treatment is defined as “hydrophobic” if it lowers the wetting tension of a surface, compared to the corresponding uncoated or untreated surface. Hydrophobicity is thus a function of both the untreated substrate and the treatment.

The word “comprising” does not exclude other elements or steps.

The indefinite article “a” or “an” does not exclude a plurality.

### DETAILED DESCRIPTION

The present invention will now be described more fully, with reference to the accompanying drawings, in which several embodiments are shown. This invention can, however, be embodied in many different forms and should not be construed as limited to the embodiments set forth here. Rather, these embodiments are examples of the invention, which has the full scope indicated by the language of the claims. Like numbers refer to like or corresponding elements throughout. The following disclosure relates to all embodiments unless specifically limited to a certain embodiment.

Embodiments of the present disclosure are directed to the coating of vessels made, at least in part, from a thermoplastic material to achieve coated vessels that are suitable for containing, for instance, an injectable solution. This may be achieved using a pulsed RF PECVD coating process to apply a variety of layers that serve as an oxygen barrier, optionally a water vapor transmission (or moisture) barrier, optionally a tie layer, and optionally a pH protective layer. By using pulsed RF PECVD, coating defects may be minimized and process times may be reduced with increased number of vessels coated at a time. The pulsed RF PECVD system may comprise a single source that provides gas to each vessel via an input manifold and a single vacuum line that evacuates each vessel/chamber via an exhaust manifold. In this manner, a high degree of layer uniformity is enabled across multiple vessels. Furthermore, pulsed RF PECVD may be controlled to provide denser layers enabling similar or improved layer performance with thinner, higher density layers.

### Vessels and Coating Sets

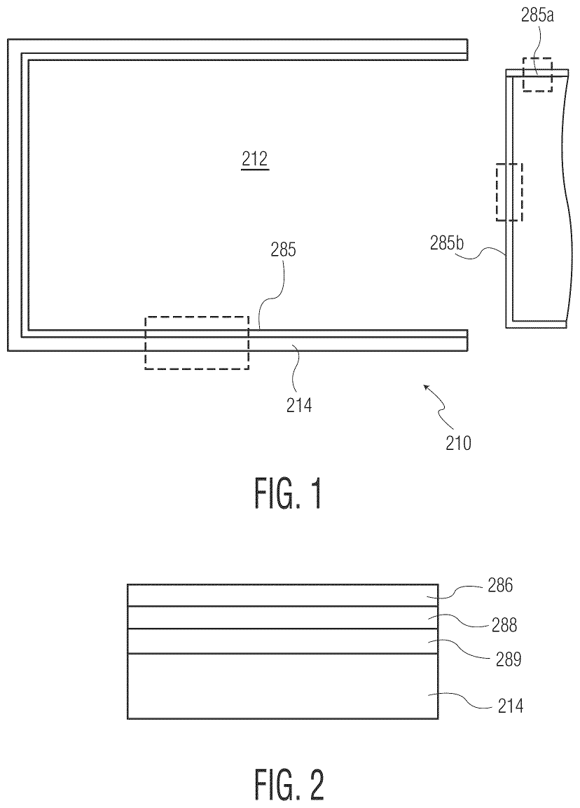

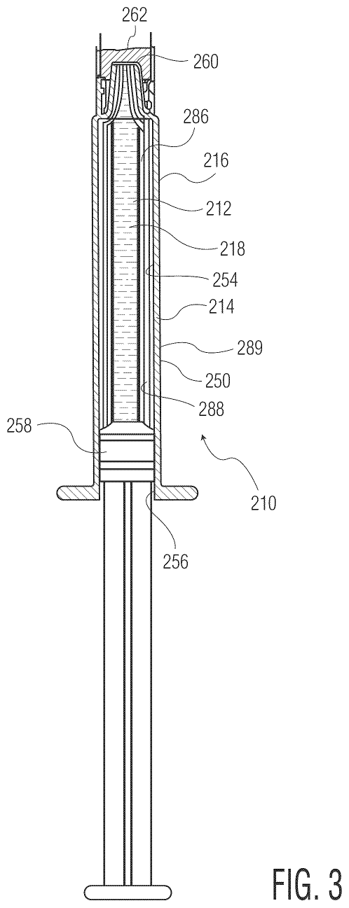

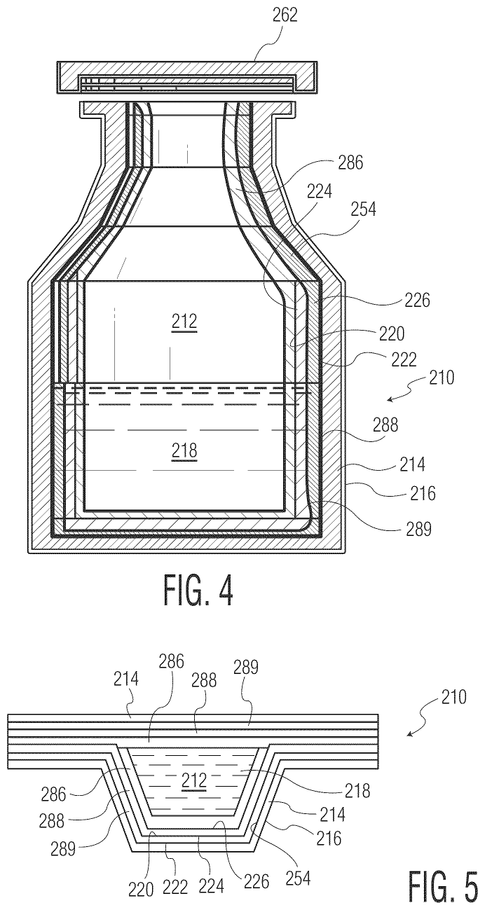

An aspect of the invention, illustrated most broadly by FIG. 1 and the detail view of FIG. 2, is a vessel 210 including a wall 214 enclosing a lumen 212 and a vessel coating or layer set 285 on at least a portion of the wall 214 facing the lumen 212. The vessel may be more specifically a vial, a syringe barrel, a blood collection tube, a blister pack, an ampoule, a cartridge, a bottle, a pouch, a pump, a sprayer, a stopper, a needle, a plunger, a cap, a stent, a catheter or an implant, or any other type of container or conduit for a fluid. FIGS. 1 through 5 show a vessel having at least a single opening, and should be understood to include a vessel having two or more openings, such as a syringe barrel, or a vessel having no openings, such as a pouch, blister pack, or ampoule.

An embodiment of the vessel coating or layer set 285 is at least one tie coating or layer 289, at least one barrier coating or layer 288, and at least one pH protective coating or layer 286, illustrated in FIGS. 1 and 2. This embodiment of the vessel coating or layer set is sometimes known as a “trilayer coating” in which the barrier coating or layer 288 of SiOx is protected against contents having a pH otherwise high enough to remove it by being sandwiched between the pH protective coating or layer 286 and the tie coating or layer 289, each an organic layer of SiOxCy as defined in this specification. A specific example of this trilayer coating is provided in this specification. The contemplated thicknesses of the respective layers in nm (preferred ranges in parentheses) are given in the Trilayer Thickness Table.

Trilayer Thickness Table

| Adhesion | Barrier | Protection |
|---|---|---|
| 5-50 | 2-100 | 50-500 |
| (15-25) | (20-45) | (50-100) |

Several particular coordinating coating sets 285, 285a, and 285b for a vessel 210 and closure of FIG. 1 are shown in the Table of Coating Sets:

Table of Coating Sets

| | Vessel wall | Closure sliding surface | Closure facing surface |
|---|---|---|---|
| Set | (285) | (285a) | (285b) |
| 1 | pH protective (286) | Lubricity (281) e.g. | Barrier |
| | barrier (288) | Parylene. | (288) - e.g. Parylene |
| | tie (289) | Sliding surface of closure, | Facing surface of closure, |
| | syringe barrel wall (214) | e.g. plunger tip | e.g. plunger tip. |
| 2 | Lubricant deposit (287) | No coating set 285a | pH protective (286) |
| | SiOx primer (283) | Sliding surface of closure, | barrier (288) |
| | pH protective (286) | e.g. plunger tip | Facing surface of closure |
| | barrier (288) | | |
| | tie (289) | | |
| | syringe barrel wall (214) | | |
| 3 | pH protective (286) | Lubricity (281) e.g. | Barrier (288) - e.g. |
| | barrier (288) | Parylene. | Parylene |
| | syringe barrel wall (214) | Sliding surface of closure, | Facing surface of closure, |
| 4 | SiOx primer (283) | Lubricity (281) e.g. | pH protective (286) |
| | pH protective (286) | SiOxCy | barrier (288) |
| | barrier (288) | Sliding surface of closure, | Facing surface of closure |
| | syringe barrel wall (214) | e.g. plunger tip | |
| 5 | pH protective (286) | Lubricant deposit (287) | Lubricant deposit (287) |
| | barrier (288) | Sliding surface of closure | Facing surface of closure |
| | Vial wall (214) | (e.g. septum) | (e.g. septum) |
| 6 | pH protective (286) | Lubricant deposit (287) | Lubricant deposit (287) |
| | barrier (288) | Sliding surface of closure | Facing surface of closure |
| | tie (289) | (e.g. septum) | (e.g. septum) |
| | Vial wall (214) | | |
| 7 | Lubricity (281) e.g. SiOxCy | Barrier (288) - e.g. | Barrier (288) - e.g. |
| | pH protective (286) | Parylene | Parylene |
| | barrier (288) | | |
| | tie (289) | | |
| | Vial wall (214) | | |
| 8 | Lubricity (281) e.g. SiOxCy | Barrier (288) - e.g. | Barrier (288) - e.g. |
| | pH protective (286) | Parylene | Parylene |
| | barrier (288) | | |
| | Vial or syringe wall (214) | | |
| 9 | pH protective (286) | Lubricant deposit (287) | Lubricant deposit (287) |
| | gas barrier (301) | Sliding surface of | Facing surface of |
| | moisture barrier (300) | closure | closure |
| | tie (289) | (e.g. septum) | (e.g. septum) |
| | Vial or syringe wall (214) | | |
| 10 | Lubricity (281) e.g. SiOxCy | Barrier (288) - e.g. | Barrier (288) - e.g. |
| | pH protective (286) | Parylene | Parylene |
| | gas barrier (301) | | |
| | tie (289) | | |
| | moisture barrier (300) | | |
| | Vial or syringe wall (214) | | |

Sets 1-4 and 7-8 and 10 in the Table of Coating Sets are among the useful alternatives for a syringe. The syringe barrel wall coatings (left column) of Set 1 are one example of the previously described trilayer coating, and Set 7 is a modification of the trilayer coating in which a pulsed RF PECVD lubricant coating or layer is the top layer of the set.

The Set 1 trilayer coating set 285, illustrated in FIG. 2, is applied to a plastic, e.g. COP, syringe barrel in one embodiment.

The Set 1 trilayer coating set 285 includes as a first layer an adhesion or tie coating or layer 289 that improves adhesion of the barrier coating or layer to the plastic substrate. The adhesion or tie coating or layer 289 is also believed to relieve stress on the barrier coating or layer 288, making the barrier layer less subject to damage from thermal expansion or contraction or mechanical shock. The adhesion or tie coating or layer 289 is also believed to decouple defects between the barrier coating or layer 288 and the plastic substrate. This is believed to occur because any pinholes or other defects that may be formed when the adhesion or tie coating or layer 289 is applied tend not to be continued when the barrier coating or layer 288 is applied, so the pinholes or other defects in one coating do not line up with defects in the other. The adhesion or tie coating or layer 289 has some efficacy as a barrier layer, so even a defect providing a leakage path extending through the barrier coating or layer 289 is blocked by the adhesion or tie coating or layer 289.

The Set 1 trilayer coating set 285 includes as a second layer a barrier coating or layer 288 that provides a barrier to oxygen that has permeated the plastic barrel wall and optionally a barrier to moisture that may permeate a plastic barrel wall. The barrier coating or layer 288 also is a barrier to extraction of the composition of the barrel wall 214 by the contents of the lumen 214.

The Set 1 trilayer coating set 285 includes as a third layer a pH protective coating or layer 286 that provides protection of the underlying barrier coating or layer 288 against contents of the syringe having a pH from 4 to 8, including where a surfactant is present. For a prefilled syringe that is in contact with the contents of the syringe from the time it is manufactured to the time it is used, the pH protective coating or layer 286 prevents or inhibits attack of the barrier coating or layer 288 sufficiently to maintain an effective oxygen and/or moisture barrier over the intended shelf life of the prefilled syringe.

Sets 5 and 6 and 9 are useful for a vial, for instance. The lubricant deposit as the coating set 285b represents a siliconized septum in which the entire surface is coated with a lubricant to aid insertion into a vial neck, so the facing surface of the closure is coated although the coating is not needed there.

The vessel wall coating set 285 represented by Set 6 is another trilayer coating set, again illustrated in FIG. 2, applied to a plastic, e.g. COP, vial in one embodiment. The trilayer coating has the same layers and provides the same performance as the syringe trilayer coating of Set 1 described above.

In some embodiments, the vessel wall or at least a portion of the vessel wall may comprise a cyclic block copolymer (CBC) resin, such as those in the VIVION™ family, such as VIVION™ 0510 or VIVION™ 0510HF or VIVION™ 1325, manufactured by USI Corporation (Taiwan). Cyclic block copolymers are fully hydrogenated polymers based on styrene and conjugated dienes via anionic polymerization. Cyclic block copolymers are lower cost materials relative to COP and COC resins, due at least in part to lower cost raw materials and lower cost catalysts used in the polymerization and finishing processes. Embodiments of the PECVD coating process and system described herein may be used to apply a coating set that provides a CBC vessel wall with sufficient barrier properties, e.g. oxygen barrier properties, to serve as a pharmaceutical package, e.g. vial, syringe barrel, etc., as described herein.

### Tie Coating or Layer

The tie coating or layer 289 has at least two functions. One function of the tie coating or layer 289 is to improve adhesion of a barrier coating or layer 288 to a substrate, in particular a thermoplastic substrate, although a tie layer can be used to improve adhesion to a glass substrate or to another coating or layer. For example, a tie coating or layer, also referred to as an adhesion layer or coating can be applied to the substrate and the barrier layer can be applied to the adhesion layer to improve adhesion of the barrier layer or coating to the substrate.

Another function of the tie coating or layer 289 has been discovered: a tie coating or layer 289 applied under a barrier coating or layer 288 can improve the function of a pH protective coating or layer 286 applied over the barrier coating or layer 288.

The tie coating or layer 289 can be composed of, comprise, or consist essentially of SiOxCy, in which x is between 0.5 and 2.4 and y is between 0.6 and 3. Alternatively, the atomic ratio can be expressed as the formula SiwOxCy, The atomic ratios of Si, O, and C in the tie coating or layer 289 are, as several options:

$$Si 100 : O 50 - 150 : C 90 - 200 ( i . e . w = 1 , x = 0.5 to 1.5 , y = 0.9 to 2 ) ;$$

$$Si 100 : O 70 - 130 : C 90 - 200 ( i . e . w = 1 , x = 0.7 to 1.3 , y = 0.9 to 2 )$$

$$Si 100 : O 80 - 120 : C 90 - 150 ( i . e . w = 1 , x = 0.8 to 1.2 , y = 0.9 to 1.5 )$$

$$Si 100 : O 90 - 120 : C 90 - 140 ( i . e . w = 1 , x = 0.9 to 1.2 , y = 0.9 to 1.4 ) , or$$

$$Si 100 : O 92 - 107 : C 116 - 133 ( i . e . w = 1 , x = 0.92 to 1.07 , y = 1.16 to 1.33 )$$

The atomic ratio can be determined by XPS. Taking into account the H atoms, which are not measured by XPS, the tie coating or layer 289 may thus in one aspect have the formula Si_{w}OₓC_{y}H_{z} (or its equivalent SiOₓC_{y}), for example where w is 1, x is from about 0.5 to about 2.4, y is from about 0.6 to about 3, and z is from about 2 to about 9. Typically, tie coating or layer 289 would hence contain 36% to 41% carbon normalized to 100% carbon plus oxygen plus silicon.

Optionally, the tie coating or layer can be similar or identical in composition with the pH protective coating or layer 286 described elsewhere in this specification, although this is not a requirement.

The tie coating or layer 289 is contemplated in any embodiment generally to be from 5 nm to 100 nm thick, preferably from 5 to 20 nm thick, particularly if applied by chemical vapor deposition. These thicknesses are not critical. Commonly but not necessarily, the tie coating or layer 289 will be relatively thin, since its function is to change the surface properties of the substrate.

In some embodiments, the tie coating or layer 289 may be omitted. In other embodiments, a thin tie coating or layer 289 may be applied by pulsed RF PECVD. In addition to the above-described SiOxCy, the tie coating or layer 289 applied by pulsed RF PECVD may be any material that is effective to improve adhesion between the subsequently applied barrier coating or layer 288 and the vessel wall 214 or any coating already applied thereon. Such materials include metals and metal oxides such as: Al₂O₃, TiO₂, ZrO₂, HfO₂, Ta₂O₅, Nb₂O₅, Y₂O₃, MgO, CeO₂, La₂O₃, SrTiO₃, BaTiO₃, BiₓTi_{y}O_{z}, In₂O₃, In₂O₃:Sn, In₂O₃:F, In₂O₃:Zr, SnO₂, SnO₂:Sb, ZnO, ZnO:Al, Ga₂O₃, NiO, CoOx, YBa₂Cu₃O₇₋ₓ, LaCoO₃, LaNiO₃, Si, Ge, Cu, Mo, Ta, and W. In some embodiments, zinc oxide (ZnO) or aluminum oxide (Al₂O₃) may be applied by pulsed RF PECVD as a tie coating or layer 289. Due to its adhesion to polymeric films, zinc oxide (ZnO) in particular may serve as a high-quality tie coating or layer 289.

Where a tie coating or layer 289 is applied by pulsed RF PECVD, the thickness of the tie coating or layer may be generally from 2 nm to 100 nm thick, preferably from 2 to 20 nm thick. These thicknesses are not critical. Commonly, but not necessarily, the tie coating or layer 289 will be relatively thin, since its function is to change the surface properties of the substrate.

In some embodiments, the barrier coating or layer 288 may be split between an oxygen barrier layer 301 and a moisture barrier layer 300, which may or may not be applied as adjacent coatings. In some embodiments, therefore, the tie coating or layer 289 may be applied by pulsed RF PECVD between the vessel wall 214 and a barrier coating 288 that includes both an oxygen barrier layer and a moisture barrier layer. In other embodiments, however, the tie coating or layer 289 may be applied by pulsed RF PECVD between an oxygen barrier layer 301 and a moisture barrier layer 300. For example, a moisture barrier layer 300 may be applied, e.g. by pulsed RF PECVD, to the vessel wall 214, after which the tie coating or layer 289 may be applied, after which the oxygen barrier layer 301 may be applied.

In one example, for instance, pulsed RF PECVD is used to apply a moisture barrier layer (e.g. of Al₂O₃), a tie coating or layer 289, an oxygen barrier layer of SiOₓ, and a pH protective coating or layer 286.

In other embodiments, multiple tie coating or layers 289 may be applied. For instance, a first tie coating or layer 289 may be applied by pulsed RF PECVD, followed by a first barrier layer such as a moisture barrier (e.g. Al₂O₃), followed by a second tie coating or layer, followed by a second barrier layer such as an oxygen barrier (e.g. SiOx), followed by a pH protective coating or layer 286.

In yet other examples, a moisture barrier layer (e.g. of Al₂O₃) is applied to the vessel wall by pulsed RF PECVD followed by an oxygen barrier layer of SiOₓ, and a pH protective coating or layer 286.

### Barrier Layer

A barrier coating or layer 288 optionally can be deposited by pulsed RF PECVD on the vessel of a pharmaceutical package, in particular a thermoplastic package, to prevent oxygen, carbon dioxide, or other gases from entering the vessel and/or to prevent leaching of the pharmaceutical material into or through the package wall.

The barrier coating or layer for any embodiment defined in this specification (unless otherwise specified in a particular instance) is a coating or layer, optionally applied by pulsed RF PECVD as described herein. The barrier layer optionally is characterized as an “SiOₓ” coating, and contains silicon, oxygen, and optionally other elements, in which x, the ratio of oxygen to silicon atoms, is from about 1.5 to about 2.9, or 1.5 to about 2.6, or about 2. These alternative definitions of x apply to any use of the term SiOₓ in this specification. The barrier coating or layer is applied, for example to the interior of a pharmaceutical package or other vessel, for example a sample collection tube, a syringe barrel, a vial, or another type of vessel.

The barrier coating 288 may comprise or consist essentially of SiOₓ, wherein x is from 1.5 to 2.9, from 2 to 1000 nm thick, the barrier coating 288 of SiOx having an interior surface 220 facing the lumen 212 and an outer surface 222 facing the wall 214 article surface 254, the barrier coating 288 being effective to reduce the ingress of atmospheric gas into the lumen 212 compared to an uncoated vessel 250. One suitable barrier composition is one where x is 2.3, for example.

For example, the barrier coating or layer such as 288 of any embodiment can be applied at a thickness of at least 2 nm, or at least 4 nm, or at least 7 nm, or at least 10 nm, or at least 20 nm, or at least 30 nm, or at least 40 nm, or at least 50 nm, or at least 100 nm, or at least 150 nm, or at least 200 nm, or at least 300 nm, or at least 400 nm, or at least 500 nm, or at least 600 nm, or at least 700 nm, or at least 800 nm, or at least 900 nm. The barrier coating or layer can be up to 1000 nm, or at most 900 nm, or at most 800 nm, or at most 700 nm, or at most 600 nm, or at most 500 nm, or at most 400 nm, or at most 300 nm, or at most 200 nm, or at most 100 nm, or at most 90 nm, or at most 80 nm, or at most 70 nm, or at most 60 nm, or at most 50 nm, or at most 40 nm, or at most 30 nm, or at most 20 nm, or at most 10 nm, or at most 5 nm thick. Ranges of 2-100 nm, optionally 5-20 nm, are particularly contemplated where the barrier coating or layer is applied by pulsed RF plasma PECVD. Specific thickness ranges composed of any one of the minimum thicknesses expressed above, plus any equal or greater one of the maximum thicknesses expressed above, are also expressly contemplated.

Where the barrier coating or layer is applied by pulsed RF PECVD, the thickness of the barrier coating or layer may be, for example, from 1 to 50 nm thick, alternatively from 1 to 20 nm thick, alternatively from 2 to 19 nm thick, alternatively from 2 to 15 nm thick.

The thickness of the SiOx or other barrier coating or layer can be measured, for example, by transmission electron microscopy (TEM), and its composition can be measured by X-ray photoelectron spectroscopy (XPS). The primer coating or layer described herein can be applied to a variety of pharmaceutical packages or other vessels made from plastic or glass, for example to plastic tubes, vials, and syringes.

A barrier coating or layer 288 of SiOx, in which x is between 1.5 and 2.9, is applied by pulsed RF PECVD directly or indirectly to the thermoplastic wall 214 (for example a tie coating or layer 289 can be interposed between them) so that in the filled pharmaceutical package or other vessel 210 the barrier coating or layer 288 is located between the inner or interior surface 220 of the thermoplastic wall 214 and the fluid 218.

The barrier coating or layer 288 of SiOx is supported by the thermoplastic wall 214. The barrier coating or layer 288 as described elsewhere in this specification, or in U.S. Pat. No. 7,985,188, can be used in any embodiment.

Certain barrier coatings or layers 288 such as SiOx as defined here have been found to have the characteristic of being subject to being measurably diminished in barrier improvement factor in less than six months as a result of attack by certain relatively high pH contents of the coated vessel as described elsewhere in this specification, particularly where the barrier coating or layer directly contacts the contents. This issue can be addressed using a pH protective coating or layer as discussed in this specification.

The barrier coating or layer 288 of SiOx also can function as a primer coating or layer 283, as discussed elsewhere in this specification.

In some embodiments, the barrier coating or layer 288 may be applied by pulsed RF PECVD such as a SiOₓ barrier coating as described above, having higher density and less defects than a similar barrier coating deposited by other methods. As a result, the barrier coating or layer 288 may have a reduced thickness when compared to the barrier coating or layer applied by conventional PECVD while still providing the same oxygen barrier properties. It has also been shown that barrier coating or layer 288 applied by pulsed RF PECVD according to embodiments of the present disclosure may have improved gas barrier properties when compared to a barrier coating or layer of the same composition applied by conventional (non-pulsed) PECVD, even when applied at a reduced thickness.

In some embodiments, the barrier coating or layer 288 may comprise one or more layers in addition to the SiOx layer described above. For instance, in some embodiments, one or more additional barrier layers may also be applied.

In some embodiments, it may be desirable to apply an additional moisture, i.e. water vapor, barrier layer in addition to the SiOₓ oxygen barrier. For instance, while some plastic materials that may make up the vessel wall may themselves have adequate moisture barrier properties, other plastic materials may require that one or more moisture barrier coatings or layers be applied. In some embodiments, the moisture barrier coating or layer may be applied by pulsed RF PECVD as described herein.

In some embodiments, for instance, the barrier coating or layer 288 may comprise both (i) an SiOx oxygen barrier layer applied by pulsed RF PECVD and (ii) a moisture barrier layer, e.g. Al₂O₃ applied by pulsed RF PECVD. By depositing these layers in the same process, yields may be improved and process times reduced because of the reduced number of process steps. The oxygen barrier layer and the moisture barrier layer may be applied sequentially, such that they are adjacent to one another, or they may be separated by one or more additional coatings or layers (e.g. a tie coating or layer as described above). When applied sequentially, the SiOₓ oxygen barrier layer may be applied first and the moisture barrier layer may be applied second, or vice versa.

In alternative embodiments, the barrier coating or layer 288 may comprise or consist essentially of any one or more materials that provide the vessel with adequate oxygen and/or moisture barrier properties. Such materials may include metals and metal oxides, such as: Al₂O₃, TiO₂, ZrO₂, HfO₂, Ta₂O₅, Nb₂O₅, Y₂O₃, MgO, CeO₂, La₂O₃, SrTiO₃, BaTiO₃, BiₓTi_{y}O_{z}, In₂O₃, In₂O₃:Sn, In₂O₃:F, In₂O₃:Zr, SnO₂, SnO₂:Sb, ZnO, ZnO:Al, Ga₂O₃, NiO, CoOx, YBa₂Cu₃O₇₋ₓ, LaCoO₃, LaNiO₃, Si, Ge, Cu, Mo, Ta, and W. In some embodiments, the one or more materials may be provided by atomic layer deposition (ALD).

### pH Protective Coating or Layer

The inventors have found that barrier layers or coatings of SiOx are eroded or dissolved by some fluids, for example aqueous compositions having a pH above about 5. Since coatings applied by chemical vapor deposition can be very thin—tens to hundreds of nanometers thick—even a relatively slow rate of erosion can remove or reduce the effectiveness of the barrier layer in less time than the desired shelf life of a product package. This is particularly a problem for fluid pharmaceutical compositions, since many of them have a pH of roughly 7, or more broadly in the range of 5 to 9, similar to the pH of blood and other human or animal fluids. The higher the pH of the pharmaceutical preparation, the more quickly it erodes or dissolves the SiOx coating. Optionally, this problem can be addressed by protecting the barrier coating or layer 288, or other pH sensitive material, with a pH protective coating or layer 286.

Optionally, the pH protective coating or layer 286 can be composed of, comprise, or consist essentially of Si_{w}OₓC_{y}H_{z} (or its equivalent SiOₓC_{y}) or Si_{w}NₓC_{y}H_{z} or its equivalent Si(NH)ₓC_{y}), each as defined previously. The atomic ratio of Si:O:C or Si:N:C can be determined by XPS (X-ray photoelectron spectroscopy). Taking into account the H atoms, the pH protective coating or layer may thus in one aspect have the formula Si_{w}OₓC_{y}H_{z}, or its equivalent SiOₓC_{y}, for example where w is 1, x is from about 0.5 to about 2.4, y is from about 0.6 to about 3, and z is from about 2 to about 9.

Typically, expressed as the formula Si_{w}OₓC_{y}, the atomic ratios of Si, 0, and C are, as several options:

$$Si 100 : O 50 - 150 : C 90 - 200 ( i . e . w = 1 , x = 0.5 to 1.5 , y = 0.9 to 2 ) ;$$

$$Si 100 : O 70 - 130 : C 90 - 200 ( i . e . w = 1 , x = 0.7 to 1.3 , y = 0.9 to 2 )$$

$$Si 100 : O 80 - 120 : C 90 - 150 ( i . e . w = 1 , x = 0.8 to 1.2 , y = 0.9 to 1.5 )$$

$$Si 100 : O 90 - 120 : C 90 - 140 ( i . e . w = 1 , x = 0.9 to 1.2 , y = 0.9 to 1.4 )$$

$$Si 100 : O 92 - 107 : C 116 - 133 ( i . e . w = 1 , x = 0.92 to 1.07 , y = 1.16 to 1.33 ) , or$$

$$Si 100 : O 80 - 130 : C 90 - 150.$$

Alternatively, the pH protective coating or layer can have atomic concentrations normalized to 100% carbon, oxygen, and silicon, as determined by X-ray photoelectron spectroscopy (XPS) of less than 50% carbon and more than 25% silicon. Alternatively, the atomic concentrations are from 25 to 45% carbon, 25 to 65% silicon, and 10 to 35% oxygen.

Alternatively, the atomic concentrations are from 30 to 40% carbon, 32 to 52% silicon, and 20 to 27% oxygen. Alternatively, the atomic concentrations are from 33 to 37% carbon, 37 to 47% silicon, and 22 to 26% oxygen.

The thickness of the pH protective coating or layer can be, for example: from 10 nm to 1000 nm; alternatively from 10 nm to 1000 nm; alternatively from 10 nm to 900 nm; alternatively from 10 nm to 800 nm; alternatively from 10 nm to 700 nm; alternatively from 10 nm to 600 nm; alternatively from 10 nm to 500 nm; alternatively from 10 nm to 400 nm; alternatively from 10 nm to 300 nm; alternatively from 10 nm to 200 nm; alternatively from 10 nm to 100 nm; alternatively from 10 nm to 50 nm; alternatively from 20 nm to 1000 nm; alternatively from 50 nm to 1000 nm; alternatively from 10 nm to 1000 nm; alternatively from 50 nm to 800 nm; alternatively from 100 nm to 700 nm; alternatively from 300 to 600 nm.

Optionally, the atomic concentration of carbon in the protective layer, normalized to 100% of carbon, oxygen, and silicon, as determined by X-ray photoelectron spectroscopy (XPS), can be greater than the atomic concentration of carbon in the atomic formula for the organosilicon precursor. For example, embodiments are contemplated in which the atomic concentration of carbon increases by from 1 to 80 atomic percent, alternatively from 10 to 70 atomic percent, alternatively from 20 to 60 atomic percent, alternatively from 30 to 50 atomic percent, alternatively from 35 to 45 atomic percent, alternatively from 37 to 41 atomic percent.

Optionally, the atomic ratio of carbon to oxygen in the pH protective coating or layer can be increased in comparison to the organosilicon precursor, and/or the atomic ratio of oxygen to silicon can be decreased in comparison to the organosilicon precursor.

Optionally, the pH protective coating or layer can have an atomic concentration of silicon, normalized to 100% of carbon, oxygen, and silicon, as determined by X-ray photoelectron spectroscopy (XPS), less than the atomic concentration of silicon in the atomic formula for the feed gas. For example, embodiments are contemplated in which the atomic concentration of silicon decreases by from 1 to 80 atomic percent, alternatively by from 10 to 70 atomic percent, alternatively by from 20 to 60 atomic percent, alternatively by from 30 to 55 atomic percent, alternatively by from 40 to 50 atomic percent, alternatively by from 42 to 46 atomic percent.

As another option, a pH protective coating or layer is contemplated in any embodiment that can be characterized by a sum formula wherein the atomic ratio C:O can be increased and/or the atomic ratio Si:O can be decreased in comparison to the sum formula of the organosilicon precursor.

The pH protective coating or layer 286 commonly is located between the barrier coating or layer 288 and the fluid 218 in the finished article. The pH protective coating or layer 286 is supported by the thermoplastic wall 214.

The pH protective coating or layer 286 optionally is effective to keep the barrier coating or layer 288 at least substantially undissolved as a result of attack by the fluid 218 for a period of at least six months.

The pH protective coating or layer can have a density between 1.25 and 1.65 g/cm³, alternatively between 1.35 and 1.55 g/cm³, alternatively between 1.4 and 1.5 g/cm3, alternatively between 1.4 and 1.5 g/cm³, alternatively between 1.44 and 1.48 g/cm³, as determined by X-ray reflectivity (XRR). Optionally, the organosilicon compound can be octamethylcyclotetrasiloxane and the pH protective coating or layer can have a density which can be higher than the density of a pH protective coating or layer made from HMDSO as the organosilicon compound under the same PECVD reaction conditions.

The pH protective coating or layer optionally can prevent or reduce the precipitation of a compound or component of a composition in contact with the pH protective coating or layer, in particular can prevent or reduce insulin precipitation or blood clotting, in comparison to the uncoated surface and/or to a barrier coated surface using HMDSO as precursor.

The pH protective coating or layer optionally can have an RMS surface roughness value (measured by AFM) of from about 5 to about 9, optionally from about 6 to about 8, optionally from about 6.4 to about 7.8. The Ra surface roughness value of the pH protective coating or layer, measured by AFM, can be from about 4 to about 6, optionally from about 4.6 to about 5.8. The Rmax surface roughness value of the pH protective coating or layer, measured by AFM, can be from about 70 to about 160, optionally from about 84 to about 142, optionally from about 90 to about 130.

The interior surface of the pH protective optionally can have a contact angle (with distilled water) of from 90° to 110°, optionally from 80° to 120°, optionally from 70° to 130°, as measured by Goniometer Angle measurement of a water droplet on the pH protective surface, per ASTM D7334-08 “Standard Practice for Surface Wettability of Coatings, Substrates and Pigments by Advancing Contact Angle Measurement.”

The passivation layer or pH protective coating or layer 286 optionally shows an O-Parameter measured with attenuated total reflection (ATR) of less than 0.4, measured as:

O-Parameter=(Intensity at 1253 cm⁻¹/Maximum Intensity in range of 1000-1100 cm⁻¹).

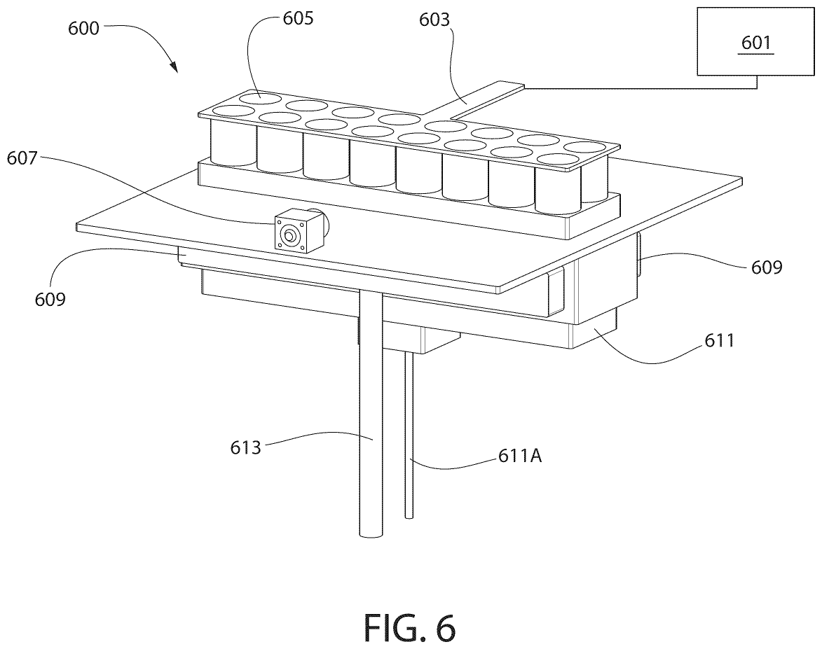

The O-Parameter is defined in U.S. Pat. No. 8,067,070, which claims an O-parameter value of most broadly from 0.4 to 0.9. It can be measured from physical analysis of an FTIR amplitude versus wave number plot to find the numerator and denominator of the above expression, as shown in FIG. 6, which is the same as FIG. 5 of U.S. Pat. No. 8,067,070, except annotated to show interpolation of the wave number and absorbance scales to arrive at an absorbance at 1253 cm⁻¹ of 0.0424 and a maximum absorbance at 1000 to 1100 cm⁻¹ of 0.08, resulting in a calculated O-parameter of 0.53. The O-Parameter can also be measured from digital wave number versus absorbance data.

U.S. Pat. No. 8,067,070 asserts that the claimed O-parameter range provides a superior pH protective coating or layer, relying on experiments only with HMDSO and HMDSN, which are both non-cyclic siloxanes. Surprisingly, it has been found by the present inventors that if the PECVD precursor is a cyclic siloxane, for example OMCTS, O-parameters outside the ranges claimed in U.S. Pat. No. 8,067,070, using OMCTS, provide even better results than are obtained in U.S. Pat. No. 8,067,070 with HMDSO.

Alternatively in the embodiment of FIGS. 1-5, the O-parameter has a value of from 0.1 to 0.39, or from 0.15 to 0.37, or from 0.17 to 0.35.

Even another aspect of the invention is a composite material as just described, exemplified in FIGS. 1-5, wherein the passivation layer shows an N-Parameter measured with attenuated total reflection (ATR) of less than 0.7, measured as:

N-Parameter=(Intensity at 850 cm⁻¹/Intensity at 799 cm⁻¹).

The N-Parameter is also described in U.S. Pat. No. 8,067,070, and is measured analogously to the O-Parameter except that intensities at two specific wave numbers are used—neither of these wave numbers is a range. U.S. Pat. No. 8,067,070 claims a passivation layer with an N-Parameter of 0.7 to 1.6. Again, the present inventors have made better coatings employing a pH protective coating or layer 286 having an N-Parameter lower than 0.7, as described above. Alternatively, the N-parameter has a value of at least 0.3, or from 0.4 to 0.6, or at least 0.53.

The rate of erosion, dissolution, or leaching (different names for related concepts) of the pH protective coating or layer 286, if directly contacted by the fluid 218, is less than the rate of erosion of the barrier coating or layer 288, if directly contacted by the fluid 218.

The thickness of the pH protective coating or layer is contemplated in any embodiment to be from 50-500 nm, with a preferred range of 100-200 nm.

The pH protective coating or layer 286 is effective to isolate the fluid 218 from the barrier coating or layer 288, at least for sufficient time to allow the barrier coating to act as a barrier during the shelf life of the pharmaceutical package or other vessel 210.

Certain pH protective coatings or layers of SiOₓC_{y} or Si(NH)ₓC_{y} formed from polysiloxane precursors, which pH protective coatings or layers have a substantial organic component, do not erode quickly when exposed to fluids, and in fact erode or dissolve more slowly when the fluids have higher pHs within the range of 5 to 9. For example, at pH 8, the dissolution rate of a pH protective coating or layer made from the precursor octamethylcyclotetrasiloxane, or OMCTS, is quite slow. These pH protective coatings or layers of SiOxCy or Si(NH)ₓC_{y} can therefore be used to cover a barrier layer of SiOx, retaining the benefits of the barrier layer by protecting it from the fluid in the pharmaceutical package. The protective layer is applied over at least a portion of the SiOx layer to protect the SiOx layer from contents stored in a vessel, where the contents otherwise would be in contact with the SiOx layer.

Although the present invention does not depend upon the accuracy of the following theory, it is further believed that effective pH protective coatings or layers for avoiding erosion can be made from siloxanes and silazanes as described in this disclosure. SiOₓC_{y} or Si(NH)ₓC_{y} coatings deposited from cyclic siloxane or linear silazane precursors, for example octamethylcyclotetrasiloxane (OMCTS), are believed to include intact cyclic siloxane rings and longer series of repeating units of the precursor structure. These coatings are believed to be nanoporous but structured and hydrophobic, and these properties are believed to contribute to their success as pH protective coatings or layers, and also protective coatings or layers. This is shown, for example, in U.S. Pat. No. 7,901,783.

SiOₓC_{y} or Si(NH)ₓC_{y} coatings also can be deposited from linear siloxane or linear silazane precursors, for example hexamethyldisiloxane (HMDSO) or tetramethyldisiloxane (TMDSO).

Optionally an FTIR absorbance spectrum of the pH protective coating or layer 286 of any embodiment has a ratio greater than 0.75 between the maximum amplitude of the Si—O—Si symmetrical stretch peak normally located between about 1000 and 1040 cm⁻¹, and the maximum amplitude of the Si—O—Si assymetric stretch peak normally located between about 1060 and about 1100 cm⁻¹. Alternatively in any embodiment, this ratio can be at least 0.8, or at least 0.9, or at least 1.0, or at least 1.1, or at least 1.2. Alternatively in any embodiment, this ratio can be at most 1.7, or at most 1.6, or at most 1.5, or at most 1.4, or at most 1.3. Any minimum ratio stated here can be combined with any maximum ratio stated here.

Optionally, in any embodiment the pH protective coating or layer 286, in the absence of the medicament, has a non-oily appearance. This appearance has been observed in some instances to distinguish an effective pH protective coating or layer from a lubricity layer, which in some instances has been observed to have an oily (i.e. shiny) appearance.

Optionally, for the pH protective coating or layer 286 in any embodiment, the silicon dissolution rate by a 50 mM potassium phosphate buffer diluted in water for injection, adjusted to pH 8 with concentrated nitric acid, and containing 0.2 wt. % polysorbate-80 surfactant, (measured in the absence of the medicament, to avoid changing the dissolution reagent), at 40° C., is less than 170 ppb/day. (Polysorbate-80 is a common ingredient of pharmaceutical preparations, available for example as Tween®-80 from Uniqema Americas LLC, Wilmington Delaware.)

Optionally, for the pH protective coating or layer 286 in any embodiment, the silicon dissolution rate is less than 160 ppb/day, or less than 140 ppb/day, or less than 120 ppb/day, or less than 100 ppb/day, or less than 90 ppb/day, or less than 80 ppb/day. Optionally, in any embodiment, the silicon dissolution rate is more than 10 ppb/day, or more than 20 ppb/day, or more than 30 ppb/day, or more than 40 ppb/day, or more than 50 ppb/day, or more than 60 ppb/day. Any minimum rate stated here can be combined with any maximum rate stated here for the pH protective coating or layer 286 in any embodiment.

Optionally, for the pH protective coating or layer 286 in any embodiment the total silicon content of the pH protective coating or layer and barrier coating, upon dissolution into a test composition with a pH of 8 from the vessel, is less than 66 ppm, or less than 60 ppm, or less than 50 ppm, or less than 40 ppm, or less than 30 ppm, or less than 20 ppm.

The inventors offer the following theory of operation of the pH protective coating or layer described here. The invention is not limited by the accuracy of this theory or to the embodiments predictable by use of this theory.

The dissolution rate of the SiOₓ barrier layer is believed to be dependent on SiO bonding within the layer. Oxygen bonding sites (silanols) are believed to increase the dissolution rate.

It is believed that the pH protective coating or layer bonds with the silanol sites on the SiOx barrier layer to “heal” or passivate the SiOx surface and thus dramatically reduces the dissolution rate. In this hypothesis, the thickness of the pH protective layer is not the primary means of protection—the primary means is passivation of the SiOx surface. It is contemplated in any embodiment that a pH protective coating or layer as described in this specification can be improved by increasing the crosslink density of the pH protective coating or layer.

### Hydrophobic Layer

The protective or lubricity coating or layer of Si_{w}OₓC_{y} or its equivalent SiOₓC_{y} also can have utility as a hydrophobic layer, independent of whether it also functions as a pH protective coating or layer Suitable hydrophobic coatings or layers and their application, properties, and use are described in U.S. Pat. No. 7,985,188. Dual functional protective/hydrophobic coatings or layers having the properties of both types of coatings or layers can be provided for any embodiment of the present invention.

An embodiment can be carried out under conditions effective to form a hydrophobic pH protective coating or layer on the substrate. Optionally, the hydrophobic characteristics of the pH protective coating or layer can be set by setting the ratio of the O₂ to the organosilicon precursor in the gaseous reactant, and/or by setting the electric power used for generating the plasma. Optionally, the pH protective coating or layer can have a lower wetting tension than the uncoated surface, optionally a wetting tension of from 20 to 72 dyne/cm, optionally from 30 to 60 dynes/cm, optionally from 30 to 40 dynes/cm, optionally 34 dyne/cm. Optionally, the pH protective coating or layer can be more hydrophobic than the uncoated surface.

Use of a coating or layer according to any described embodiment is contemplated in any embodiment as (i) a lubricity coating having a lower frictional resistance than the uncoated surface; and/or (ii) a pH protective coating or layer preventing dissolution of the barrier coating in contact with a fluid, and/or (iii) a hydrophobic layer that is more hydrophobic than the uncoated surface.

### Pulsed RF PECVD System

FIG. 6 illustrates a pulsed RF PECVD reactor, in accordance with an example embodiment of the disclosure. Referring to FIG. 6, there is shown pulsed RF PECVD reactor 600 comprising an RF power supply 601, RF electrode 603, vessel cavities 605, camera 607, exhaust manifolds 609, gas inlet manifold 611, and vacuum line 613. At the bottom of each vessel cavity 605 is a vessel holder 1105, 1107 against which an opening of the vessel is placed and through which precursor gas flows into the vessel (from the gas inlet manifold 611) and exhaust gas flows out of the vessel (to the exhaust manifold 609).

The RF power supply 601 may comprise suitable circuitry for providing an RF signal at a desired power level, duty cycle, pulse duration, and frequency, for example, to the RF electrode 603. The RF power supply 601 may comprise a tunable matching impedance network for tuning its output impedance to match that of the RF electrode 603. The RF power supply 601 may provide RF voltages with 100 mV resolution for optimum control of the plasma. In addition, the generated RF signal may have a pulse high power of 250 W to 1000 W, although power may be increased to several kW depending on other parameters. The pulse low power may be 0 W and the power frequency may be 13.65 MHz, for example. The duty cycle may be varied between 1% and 99%, preferably between 50% and 99%. The pulse train frequency may range from 250 Hz to 5000 Hz, which may be extended to 10000 Hz.

The RF electrode 603 may comprise a metal component for communicating the RF signal from the RF power supply to the individual PECVD chambers defined by the vessel cavities 605 and the vessels themselves. The RF electrode 603 comprises a plurality of orifices in the top surface within which the vessels to be coated are placed into individual vessel cavities 605.

The vessel cavities 605 comprise a portion of the RF electrode 603 within which the portions of the vessels to be coated are placed and each of which substantially surrounds the vessel wall. The potential between the RF electrode 603 and a ground plane (not shown) is configured to generate a plasma with the input gas provided by the gas inlet manifold 611. In this example, there are sixteen vessel cavities 605, with two rows of eight, although the disclosure is not so limited.

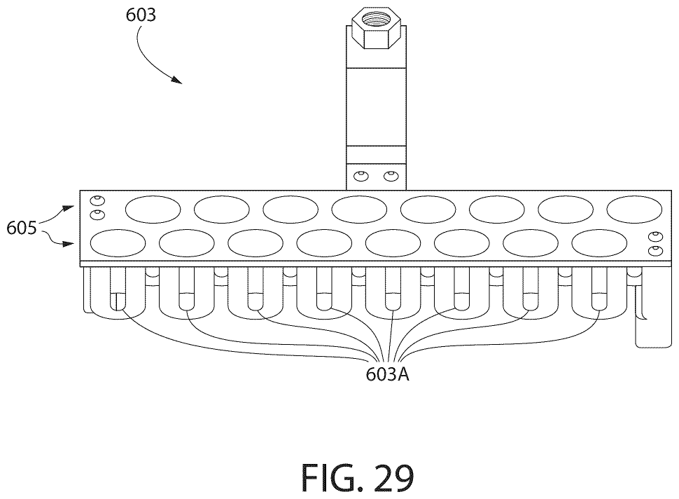

In some embodiments, the vessel cavities 605 may have “window” openings 603A in the walls of the RF electrode 603 that define the vessel cavities, for instance as shown in FIG. 29, enabling a camera 607 to have a view of the plasma generated by the applied RF signal in each vessel. In some embodiments, each vessel cavity 605 is provided with only a single window opening. A conventional system comprises multiple windows, e.g. to increase plasma stability. However, the present design of the plate electrode 603 and the vessel cavities 605 enables the wall of the RF electrode that defines each vessel cavity to have only a single window. Because gaps in the electrode, such as windows, generally reduce coating uniformity, this reduction to only a single window enables a more uniform coating to be applied on the inner surface of the vessel wall.

The camera 607 may comprise, for example, CCD or CMOS imaging sensors for monitoring the deposition. The camera 607 may be utilized to monitor plasma intensity, uniformity, and/or color, for example, to ensure the plasma conditions have been correctly configured for deposition and/or maintained during the deposition of the coating. In some embodiments, such as that illustrated in FIGS. 6-10, more than one camera may be needed to monitor the deposition of all, e.g. sixteen, chambers. In that illustrated embodiment, for example, a camera 607 may be placed on each side of the electrode 603. In other embodiments, including for example that shown in FIG. 29, the vessel cavities 605 may be arranged and configured so that a single camera 607 may be utilized to monitor the plasma in all of the vessels being coated. By staggering the vessel cavities 605 in a first row with the vessel cavities in a second row, as shown in FIG. 29 for example, each cavity may comprise a single window 603a, with all of the windows facing in the same direction. Accordingly, one or more cameras 607, and preferably one as shown in the illustrated embodiment, may be placed on a single side of the electrode 603 and used to monitor the plasma conditions within the vessels contained in both rows of cavities during the PECVD coating process.

In one embodiment the camera 607 may capture and interrogate images of the plasma in the visible light range. In another embodiment the camera 607 may capture and interrogate images of the plasma in the infrared range. In another embodiment the camera 607 may capture and interrogate images of the plasma in the ultraviolet (UV) range. Light within any one or more of these wavelength ranges may be captured and interrogated to assess the quality of the plasma process.

The interrogation of the captured images may be performed by a processor that is operably linked with the camera 607 and which is optionally further operably linked with a display and/or user interface. If, by interrogation of an image captured by the camera 607, it is determined that the plasma within one or more vessels is not within a predefined acceptable range of one or more properties, e.g. intensity, uniformity, or color, then an operator may be alerted, one or more of the PECVD variables (e.g. gas flowrates, vacuum level, RF power level, pulsing rate, etc.) may be adjusted, and/or the process may be stopped for system maintenance. The vessel(s) for which the plasma was deemed unacceptable may be discarded.

The exhaust manifolds 609 comprise a network of gas flow lines that enable the combining of multiple exhaust outputs down to one, enabling a single vacuum system/pump to evacuate a plurality of chambers equally, thus providing a uniform and consistently reproducible vacuum within each of the plurality of vessel lumens. In this example, each of the two sides of the exhaust manifold 609 combines the output from eight vessel lumens into one output line, with each output line coupled together at the vacuum line 613.

The vacuum line 613 may provide vacuum to the vessel cavities via the exhaust manifold 609, and the vacuum may be enabled by one or more pumps (not illustrated). By providing the same pressure at each vessel, the vessel-to-vessel uniformity in a deposition process may be ensured.

The gas inlet manifold 611 comprises a network of gas flow lines that enable the splitting of a single input gas line into multiple input lines for supplying gas to the vessels to be coated, enabling a single input port 611A to provide gas to each vessel equally, thus providing a uniform and consistently reproducible flow of precursor gas in each of the plurality of vessel lumens. In this example, the gas inlet manifold splits the output of gas input port 611A equally between sixteen vessels.

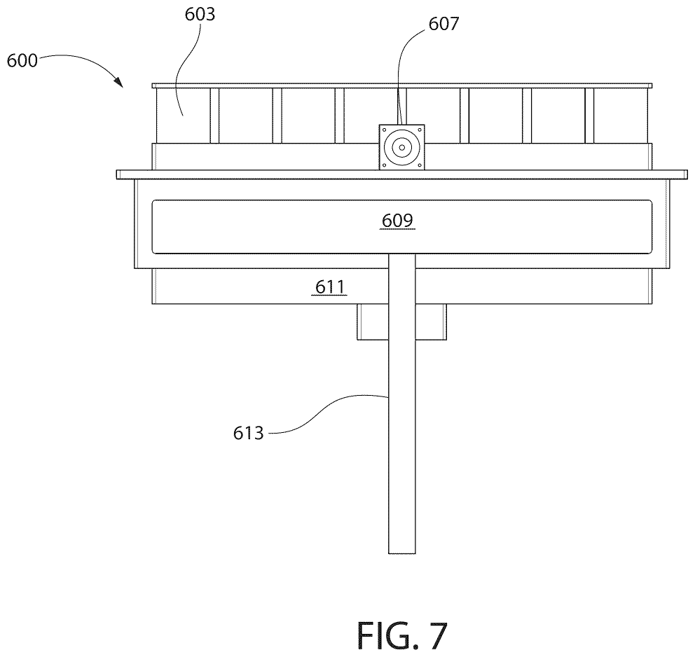

FIG. 7 illustrates a side view of a pulsed RF PECVD reactor, in accordance with an example embodiment of the disclosure. Referring to FIG. 7, there is shown pulsed RF PECVD reactor 600 comprising the RF electrode 603, camera 607, exhaust manifold 609, gas inlet manifold 611, and vacuum line 613.

This side view of the pulsed RF PECVD reactor 600 illustrates orientation of the gas inlet manifold 611 and the exhaust manifold 609, which is also present on the opposite side of the inlet manifold. In other embodiments, it is contemplated that the gas inlet manifold 611 and the exhaust manifold 609 may be reversed in orientation from that shown in the illustrated embodiment, such that the exhaust manifold is located substantially centrally and the gas inlet manifold is present on two opposing sides of the exhaust manifold.

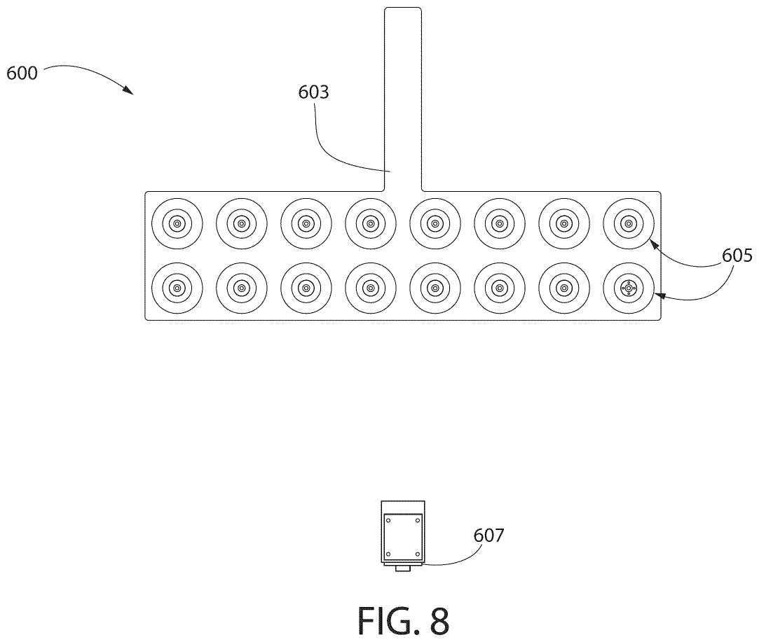

FIG. 8 illustrates a top view of a pulsed RF PECVD reactor, in accordance with an example embodiment of the disclosure. Referring to FIG. 8, there is shown pulsed RF PECVD reactor 600 comprising the RF electrode 603, vessel cavities 605, and camera 607.

This top view of the pulsed RF PECVD reactor 600 illustrates the vessel cavities 605 in the RF electrode 603, with two rows of eight enabling the processing of sixteen vessels concurrently. In addition, the RF electrode 603 extends from an in interconnect on the RF power supply 601 to the top plate from which the portions of the RF electrode that define the vessel cavities 605 extend.

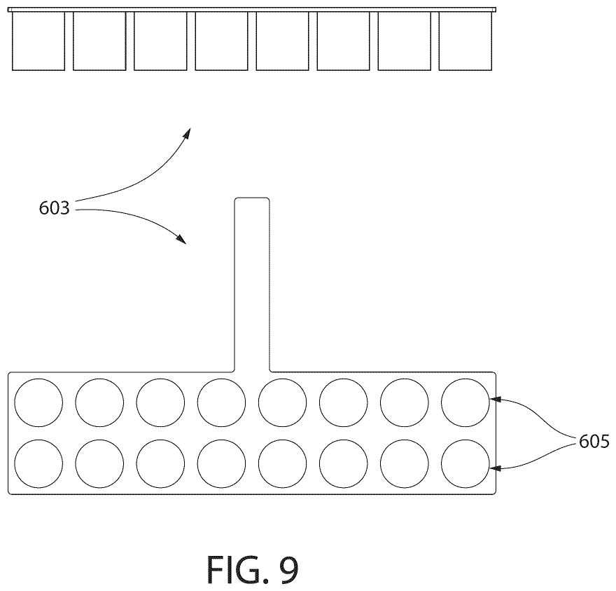

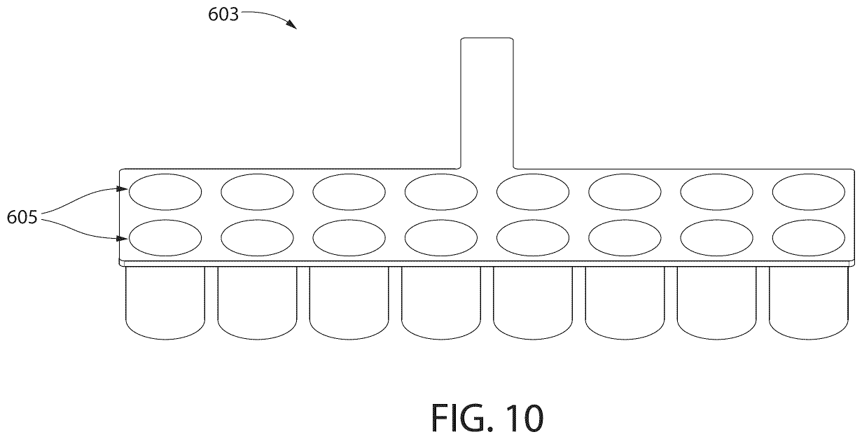

FIGS. 9 and 10 illustrate various views of an RF electrode, in accordance with an example embodiment of the disclosure. Referring to FIG. 9, there is shown side and top views of RF electrode 603, where the top view shows sixteen vessel cavities 605 within which the vessels to be coated are placed and the side view shows the vertical extent of the vessel cavities down from the top surface of the RF electrode 603. In an example scenario, the RF electrode comprises copper, although other metals are possible depending on desired conductivity.

FIG. 10 illustrates an oblique angle view of the RF electrode 603 showing the sixteen vessel cavities 605. The figure illustrates the cylindrical shape of the vessel cavities enabling a uniform plasma in the vessels to be coated.

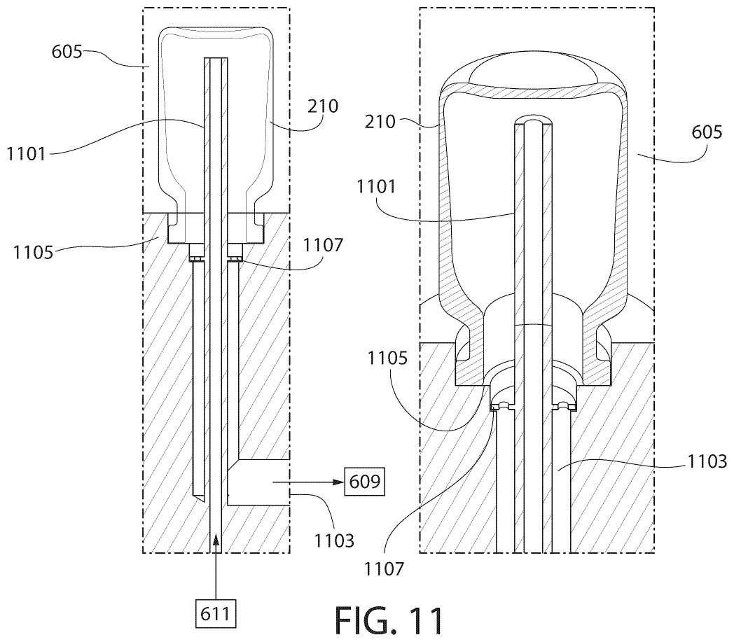

FIG. 11 illustrates a pulsed RF PECVD vessel deposition arrangement, in accordance with an example embodiment of the disclosure. Referring to FIG. 11 there is shown a cross-sectional view and a zoomed-in cross-sectional view of vessel 210, here a vial, placed within a vessel cavity 605 with the opening of the vessel 210 oriented downward in vessel holder 1105. In this example, there is also shown a gas delivery probe 1101 for supplying one or more precursor gases into the vessel 210 during the pulsed PECVD deposition process. In addition, the gas delivery probe 1101 may act as an inner electrode (e.g. may comprise metal and may be grounded), so that with the RF electrode 603 providing an RF signal, an electric field is generated thereby igniting a plasma within the vessel 210 during the deposition process.

FIG. 11 also shows a plasma screen 1107, that extends across the opening of the vacuum port 1103 and which ensures that the plasma is confined above the screen 1107 and in the vessel 210. In any embodiment, the plasma screen 1107 may take any of a variety of forms. In some embodiments, for instance, the plasma screen 1107 may comprise a perforated grate, e.g. a perforated metal disc or plate, as shown in the illustrated embodiments. In other embodiments, the plasma screen 1107 may comprise a metal mesh.

During the pulsed plasma PECVD coating process, one or more precursor gases flow from the gas inlet manifold 611 into the gas delivery probe 1101 and into the vessel 210 where a plasma may be generated by the pulsed RF signal, thereby causing deposition of the desired coating on the inner surfaces of the vessel 210 walls. The desired level of vacuum is maintained by flow of gas through the vacuum port 1103 to the exhaust manifold 609 described previously. Because the outlet of the gas delivery probe 1101 is positioned near the end of the vessel opposite the opening through which the vacuum is pulled, the precursor gases flow along the length of the vessel to provide a substantially uniform gas distribution and the coating can be applied substantially uniformly along the wall of the vessel.

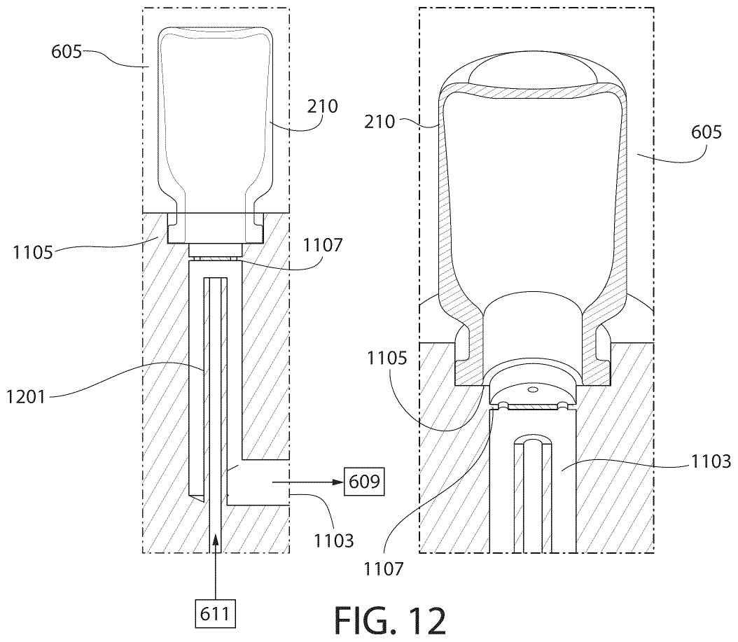

While the gas delivery probe 1101 may provide uniform gas distribution within the vessel 210, in other embodiments, pulsing the RF field that generates the plasma allows for the removal of probe 1101, as the pulsing (as well as the precursor gas flow) may be controlled to provide enough time between pulses for the precursor gas to distribute in the vessel before each pulse. An example of such an embodiment is illustrated in FIG. 12.

FIG. 12 illustrates a pulsed RF PECVD vessel coating system without a gas delivery probe, in accordance with an example embodiment of the disclosure. Referring to FIG. 12, there is shown a cross-sectional view and a zoomed-in cross-sectional view of vessel 210, here a vial, placed within a vessel cavity 605, similar to that of FIG. 11, but without a gas delivery probe within the vessel 210. In this example, a precursor gas inlet line 1201 is present but does not extend into the lumen of the vessel 210. Instead, the gas inlet line 1201 is separated from the lumen of the vessel by a plasma screen 1107 that extends across the opening of the gas inlet line and which ensures that the plasma is confined above the screen 1107 and in the vessel 210.

As with the arrangement shown in FIG. 11, the opening of the vessel 210 is oriented downward in vessel holder 1105. In this example, with the RF electrode 603 providing an RF signal, an electric field is generated between the RF electrode 603 and the plasma screen 1107, which may act as an “inner” (though in this instance, not inside the vessel) electrode (e.g. it may comprise metal and may be grounded), thereby igniting a plasma within the vessel 210 during the deposition process. In the illustrated embodiment, the plasma screen 1107 extends across both the outlet of the gas inlet line 1201 and the inlet of the vacuum port 1103. However, in other embodiments, a first plasma screen 1107 may be associated with the gas inlet line 1201 and a second plasma screen 1107 may be associated with the vacuum port 1103.

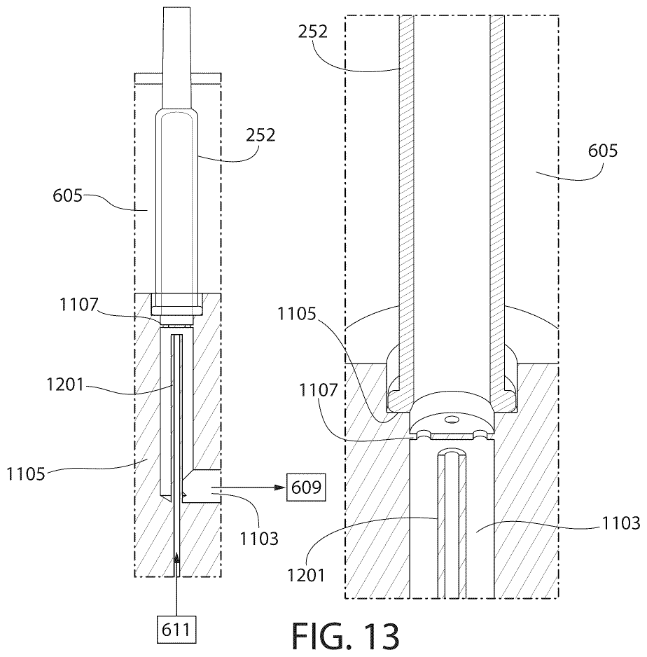

FIG. 13 illustrates a pulsed RF PECVD barrel coating system configured for coating the inner surfaces of a syringe barrel and which lacks an inlet probe, in accordance with an example embodiment of the disclosure. Referring to FIG. 13, there is shown a cross-sectional view and a zoomed-in cross-sectional view of a syringe barrel 252 placed within a vessel cavity 605, similar to that shown in FIGS. 12, in which there is no gas inlet probe. In this example, rather, gas inlet line 1201 is separated from the lumen of the syringe barrel 252 by screen 1107. In another (non-illustrated) embodiment, the pulsed RF PECVD syringe barrel coating system may comprise a gas inlet probe that extends into the lumen of the syringe barrel 252, similar to the system shown in FIG. 11.

As with the arrangements shown in FIGS. 11 and 12, the rear opening of the syringe barrel 252 is oriented downward in vessel holder 1105. In this example, with the RF electrode 603 providing an RF signal, an electric field is generated between the RF electrode 603 and the plasma screen 1107, which may act as an “inner” (though in this instance, not inside the vessel) electrode (e.g. it may comprise metal and may be grounded), thereby igniting a plasma within the lumen of the syringe barrel 252 during the deposition process.

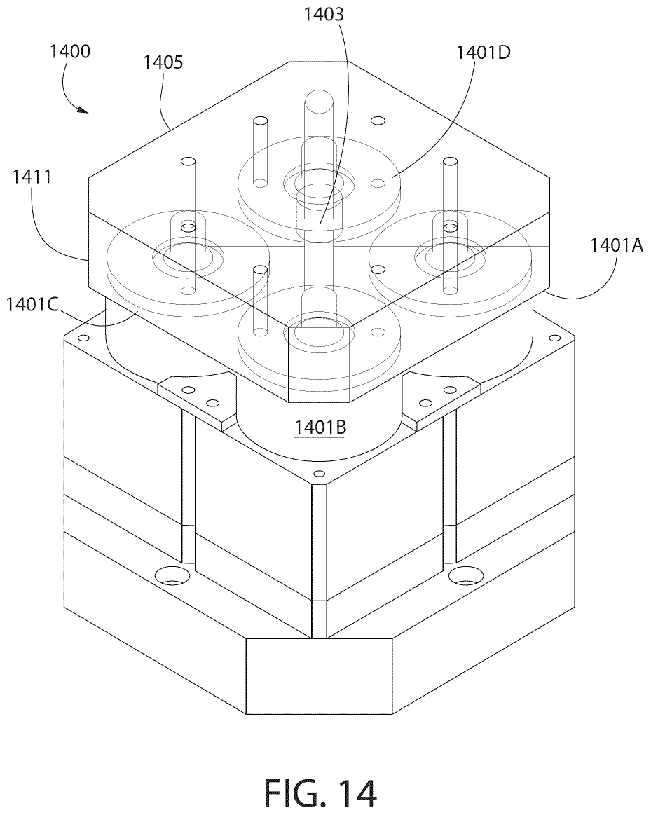

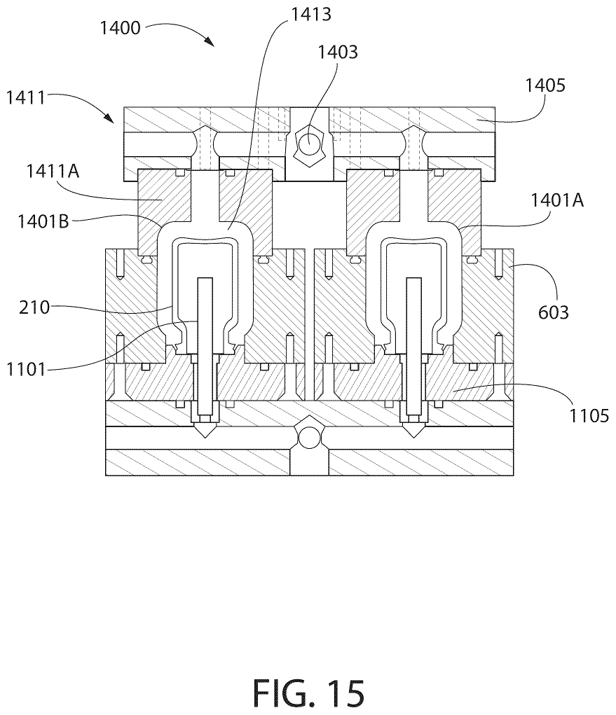

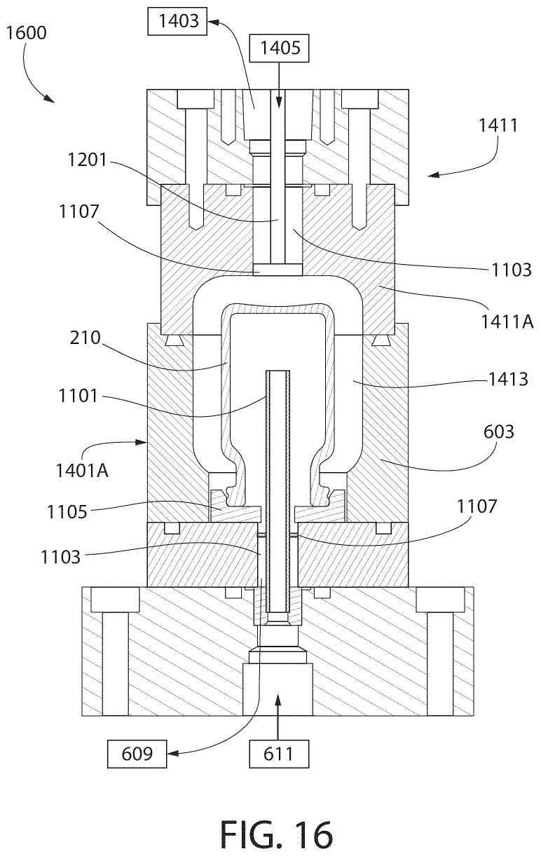

FIGS. 14, 15, and 16 illustrate a pulsed RF PECVD system configured to provide coatings to both the inner surfaces of the vessel and the outer surfaces of the vessel, in accordance with an example embodiment of the disclosure. Referring to FIG. 14, there is shown a pulsed RF PECVD system 1400 having four vessel chambers 1401A-1401D, where each chamber is operable to deposit one or more coatings or layers on the inner surface(s) of a vessel and one or more coatings or layers on the outer surface(s) of the vessel. An example coating that would be desired to be applied to the outer surface(s) of the vessel 201 is an anti-static coating, where static can lead to contaminants being drawn to the vessel. FIG. 15 illustrates a cross-sectional view of the quad pulsed RF PECVD coating system 1400 of FIG. 14, showing deposition chambers 1401A and 1401B. FIG. 16 shows a cross-sectional view of a single vessel coating system, e.g. showing a single deposition chamber 1401A, in greater detail.

In addition to the components described above with respect to any of the embodiments of FIGS. 6 through 13 (or the non-illustrated alternative embodiments described above), the system may comprise an upper sealing element 1411, which is closed over the vessel 210 once the vessel has been inserted into the vessel cavity 605 of the electrode 603. In this manner, a coating chamber 1413 may be formed around the outer wall of the vessel 210.

At least a portion of the upper sealing element 1411 may be a metal component that acts as part of electrode 603 PECVD coating process. In the illustrated embodiment, for example, the element 1411A that contacts electrode 603 and which forms part of the wall of coating chamber 1413 is a metal component, which serves as part of the outer electrode during the PECVD coating process. Desirably element 1411A is made of the same metal as electrode 603. For instance, where electrode 603 is copper, element 1411A is also desirably copper. Alternatively, where electrode 603 is aluminum, element 1411A is also desirably aluminum.

In some embodiments, such as that illustrated in FIGS. 14-15, the upper sealing element 1411 may comprise or be operably connected with a precursor gas inlet manifold 1405 for supplying one or more precursor gases to chamber 1413, a vacuum/exhaust manifold 1403 for providing the desired vacuum to chamber 1413, or both. For example, the upper sealing element 1411 of the illustrated embodiment comprises both (a) a gas inlet manifold 1405 and associated gas inlets 1201 through which the one or more precursor gases are introduced into chambers 1413 and (b) an exhaust manifold 1403 and associated vacuum ports 1103 through which exhaust gas exits the chambers 1413 to maintain the desired vacuum. The precursor gas inlets 1201 and exhaust gas outlets, i.e. vacuum ports, 1103 may be configured similarly to those shown (for coating to the inner surface(s) of the vessel) in FIGS. 12, 13. For instance, the precursor gas inlet and the exhaust gas outlet may both be separated from chamber 1413 by a plasma screen 1107 such as is described herein.

In other (non-illustrated) embodiments, the gas inlet manifold 1405 and the associated gas inlets 1201 through which the one or more precursor gases are introduced into chambers 1413, the exhaust manifold 1403 and the associated outlets 1103 through which exhaust gas exits the chambers 1413, or both may be associated with the vessel holder 1105 instead of with upper sealing element 1411. In some embodiments, for example, the gas inlet manifold 1405 and associated inlets through which one or more precursor gases are introduced into chambers 1403 may be positioned at one end of the vessels, e.g. by being associated with one of the upper sealing element 1411 and the vessel holder 1105, and the exhaust manifold 1403 and associated outlets through which the vacuum in chambers 1403 are produced may be positioned at the other end of the vessels, e.g. by being associated with the other one of the upper sealing element and the vessel holder. In such an embodiment, the precursor gases would travel along the length of the vessels between the gas inlets and the exhaust outlets.

RF electrode 603 (and optionally 1411A, as described above) may provide an RF electric field that ignites a plasma inside the vessels 210 in order to apply one or more PECVD coatings on the inner surface(s) of the vessel in the same manner as is described above. In this embodiment, RF electrode 603 (and optionally 1411A, as described above) may also provide an RF electric field that ignites a plasma in chamber 1413 in order to apply one or more PECVD coatings on the outer surface(s) of the vessel. The plasma in chamber 1413 may be ignited in the same manner as the plasma in vessel 210, e.g. by use of gas probe inlet 1101 and/or plasma screen 1107 as a grounded “inner” (though the screen is not itself inside either the vessel or the chamber) electrode to generate an electric field. The plasma may be formed in either the vessel 210 or in chamber 1413 by control of the gas flows into each (e.g. no plasma will be formed in chamber 1413 where there is no gas flow in that chamber and no plasma will be formed in the vessel 210 where there is no gas flow in the vessel).

FIG. 16 illustrates cross-sectional views of a single vessel pulsed RF PECVD coating system 1600 configured for coating both the inner surface and the outer surface of the vessel, in accordance with an example embodiment of the disclosure. Gas inlets at the top and bottom provide source gas for the outer and inner surfaces, respectively, of the vessel 210. The inlet gas probe 1101 may provide source gases to the interior of the vessel 201. As with the other embodiments described above, an RF electrode, such as RF electrode 603 (and optionally element 1411A of upper sealing element) may provide an RF signal, such that an electric field is generated between the RF electrode 603 and the inlet gas probe 1101, thereby igniting a plasma within the vessel 210 during deposition. In alternative embodiments, the system may be configured so as to lack the gas inlet probe 1101, such as is described above with respect to the embodiments illustrated in FIGS. 12 and 13.

### PECVD Coating Process

To carry out the process, a vessel 210 is provided including a wall 214 consisting essentially of thermoplastic polymeric material defining a lumen 212. Optionally in any embodiment, the wall includes a polyester, polyethylene terephthalate (PET), polyethylene naphthalate (PEN); a polyolefin, cyclic block copolymer (CBC), cyclic olefin polymer (COP), cyclic olefin copolymer (COC), polypropylene (PP), or a polycarbonate, preferably COP, COC, or CBC. Optionally in any embodiment, the vessel lumen has a capacity of from 2 to 12 mL, optionally from 3 to 5 mL, optionally from 8 to 10 mL. The wall 214 has an inside surface 303 facing the lumen and an outside surface 305.

A partial vacuum is drawn in the lumen. In some embodiments, for example, the partial vacuum may be between about 20 and about 60 mTorr, alternatively between about 30 and about 50 mTorr.

While maintaining the partial vacuum unbroken in the lumen, the tie coating or layer 289 of SiOxCy is optionally applied by a pulsed PECVD tie layer coating step comprising applying sufficient pulsed RF power (alternatively the same concept is referred to in this specification as “energy”) to generate plasma within the lumen while feeding a precursor gas comprising a siloxane precursor, preferably a linear siloxane precursor, optionally oxygen, and optionally an inert gas diluent to stabilize the plasma. In some embodiments, the precursor gas may be introduced and the ratio of gas components stabilized before ignition of the plasma. Then, while maintaining the partial vacuum unbroken in the lumen, the plasma may be extinguished, which has the effect of stopping application of the tie coating or layer of SiOₓC_{y}.

After the plasma used in the tie PECVD coating process is extinguished and before the barrier PECVD coating process is commenced, the feed of the gas employed in the tie PECVD coating process can be stopped and replaced, or simply changed, to a gas feed that is more suitable for depositing the barrier coating or layer, for example by increasing the ratio of oxygen to siloxane precursor, and optionally reducing or eliminating the inert gas (e.g. argon) from the gas feed.

While still maintaining the partial vacuum unbroken in the lumen, the barrier coating or layer 288 is applied by a pulsed PECVD barrier coating step comprising applying sufficient pulsed RF power to generate plasma within the lumen while feeding a precursor gas comprising a siloxane, preferably a linear siloxane, and oxygen. In some embodiments, the precursor gas may be introduced and the ratio of gas components stabilized before ignition of the plasma. After applying the barrier coating or layer, while maintaining the partial vacuum unbroken in the lumen, the plasma may be extinguished, which has the effect of stopping application of the barrier coating or layer. A barrier coating or layer of SiOx, wherein x is from 1.5 to 2.9 as determined by XPS is produced between the tie coating or layer and the lumen as a result of the barrier coating step.

After the plasma used in the barrier PECVD coating process is extinguished and before the optional pH protective PECVD coating process, if used, is commenced, the feed of the gas employed in the barrier PECVD coating process can be stopped and replaced, or simply changed, to a gas feed that is more suitable for depositing the pH protective coating or layer, for example by decreasing the ratio of oxygen to siloxane precursor, and optionally increasing or introducing the inert gas (e.g. argon) to the gas feed.

Then while maintaining the partial vacuum unbroken in the lumen, the pH protective coating or layer 286 of SiOₓC_{y} may be applied by a pulsed RF PECVD pH protective coating step. The pH protective coating or layer is optionally applied between the barrier coating or layer and the lumen. The pH protective PECVD step comprises applying sufficient pulsed RF power to generate plasma within the lumen while feeding a precursor gas comprising a siloxane precursor, preferably a linear siloxane precursor, optionally oxygen, and optionally an inert gas diluent to stabilize the plasma. In some embodiments, the precursor gas may be introduced and the ratio of gas components stabilized before ignition of the plasma.

If the pH protective coating layer is the final layer, then the vacuum may be broken and the coated vessel removed. If, on the other hand, another layer such as a lubricity layer is to be applied, while maintaining the partial vacuum unbroken in the lumen, the lubricity coating or layer of SiOₓC_{y} may be applied by a pulsed RF PECVD lubricity coating step. The lubricity PECVD step comprises applying sufficient pulsed RF power to generate plasma within the lumen while feeding a precursor gas comprising a siloxane precursor, preferably a linear siloxane precursor, optionally oxygen, and optionally an inert gas diluent. After applying the lubricity coating, while maintaining the partial vacuum unbroken in the lumen, the plasma may be extinguished, which has the effect of stopping application of the lubricity coating or layer.

Optionally in any embodiment, each linear siloxane precursor used to deposit the optional tie coating or layer, the barrier coating or layer, and the optional the pH protective coating or layer, can be hexamethylenedisiloxane (HMDSO) or tetramethylenedisiloxane (TMDSO), preferably HMDSO. Optionally in any embodiment, the same linear siloxane precursor is used in each coating process, which can be, for example the tie PECVD coating process, the barrier PECVD coating process, and optionally the pH protective PECVD coating process. Using the same siloxane allows for the use of the same coating equipment without the need for valving arrangements to feed a different siloxane, and increases the throughput of the coating process (by eliminating time needed to switch between gases). Optionally in any embodiment, the technology can be further generalized to the use of any plasma enhanced chemical vapor deposition process using any precursors to generate multiple coatings, employing a process as described in this specification or claims.

Optionally in any embodiment, the RF pulse high power provided to generate plasma within the lumen for applying the barrier coating or layer in a 16-Up coater, such as that illustrated herein, is from 218 to 600 watts, optionally from 218 to 436 watts, optionally from 450 to 500 watts, optionally from 250 to 300 watts.

Optionally in any embodiment, the RF pulse high power provided to generate plasma within the lumen for applying the tie coating or layer in a 16-Up coater, such as that illustrated herein, is from 100 to 350 watts, optionally from 200 to 270 watts, optionally from 135 to 350 watts, optionally from 100 to 200 watts.

Optionally in any embodiment, the RF pulse high power provided to generate plasma within the lumen for applying the pH protective coating or layer in a 16-Up coater, such as that illustrated herein, is from 100 to 350 watts, optionally from 200 to 270 watts, optionally from 135 to 350 watts, optionally from 100 to 200 watts.

Optionally in any embodiment, the RF pulse high power provided to generate plasma within the lumen for applying the lubricity coating or layer in a 16-Up coater, such as that illustrated herein, is from 2 to 1000 watts, optionally from 3 to 50 watts.

Optionally in any embodiment, the RF power provided to generate plasma within the lumen for applying the barrier coating or layer in a 16-Up coater, such as that illustrated herein, may be pulsed at a pulse train frequency of from 2 to 10,000 Hz, optionally from 250 to 10,000 Hz, optionally from 30 to 500 Hz, optionally from 2 to 25 Hz.

Optionally in any embodiment, the RF power provided to generate plasma within the lumen for applying the tie coating or layer in a 16-Up coater, such as that illustrated herein, may be pulsed at a pulse train frequency of from 10 to 10,000 Hz, optionally from 250 to 10,000 Hz, optionally from 30 to 500 Hz, optionally from 2 to 25 Hz.

Optionally in any embodiment, the RF power provided to generate plasma within the lumen for applying the pH protective coating or layer in a 16-Up coater, such as that illustrated herein, may be pulsed at a pulse train frequency of from 10 to 10,000 Hz, optionally from 250 to 10,000 Hz, optionally from 20 to 400 Hz, optionally from 10 to 20 Hz.

Optionally in any embodiment, the RF power provided to generate plasma within the lumen for applying the lubricity coating or layer in a 16-Up coater, such as that illustrated herein, may be pulsed at a pulse train frequency of from 1 to 10,000 Hz, optionally from 100 to 10,000 Hz.

Optionally in any embodiment, the RF power provided to generate plasma within the lumen for applying the barrier coating or layer in a 16-Up coater, such as that illustrated herein, may be pulsed at a power frequency of from 13.56 to 72 MHz.

Optionally in any embodiment, the RF power provided to generate plasma within the lumen for applying the tie coating or layer in a 16-Up coater, such as that illustrated herein, may be pulsed at a power frequency of from 13.56 to 72 MHz.

Optionally in any embodiment, the RF power provided to generate plasma within the lumen for applying the pH protective coating or layer in a 16-Up coater, such as that illustrated herein, may be pulsed at a power frequency of from 13.56 to 72 MHz.

Optionally in any embodiment, the RF power provided to generate plasma within the lumen for applying the lubricity coating or layer in a 16-Up coater, such as that illustrated herein, may be pulsed at a power frequency of from 13.56 to 72 MHz.

Optionally in any embodiment, the pulsed RF power provided to generate plasma within the lumen for applying the barrier coating or layer in a 16-Up coater, such as that illustrated herein, may have a duty cycle of from 20 to 99%, optionally from 80 to 99%, optionally from 96 to 99%, optionally from 20 to 50%.

Optionally in any embodiment, the pulsed RF power provided to generate plasma within the lumen for applying the tie coating or layer in a 16-Up coater, such as that illustrated herein, may have a duty cycle of from 15 to 99%, optionally from 25 to 80%, optionally from 80 to 99%, optionally from 15 to 25%.

Optionally in any embodiment, the pulsed RF power provided to generate plasma within the lumen for applying the pH protective coating or layer in a 16-Up coater, such as that illustrated herein, may have a duty cycle of from 15 to 99%, optionally from 25 to 80%, optionally from 80 to 99%, optionally from 15 to 25%.

Optionally in any embodiment, the pulsed RF power provided to generate plasma within the lumen for applying the lubricity coating or layer in a 16-Up coater, such as that illustrated herein, may have a duty cycle of from 10 to 99%, optionally from 60 to 80%.

Optionally in any embodiment, the plasma generated for applying the barrier coating or layer may be applied for a deposition time of 3 to 40 seconds, optionally for 6 to 40 seconds, optionally for 6 to 30 seconds, optionally for 6 to 25 seconds, optionally for 6 to 20 seconds, optionally for 6 to 15 seconds, optionally for 7 to 40 seconds, optionally for 7 to 30 seconds, optionally for 7 to 25 seconds, optionally for 7 to 20 seconds, optionally for 7 to 15 seconds optionally for 10 to 40 seconds, optionally for 10 to 30 seconds, optionally for 10 to 25 seconds, optionally for 10 to 20 seconds, optionally for 10 to 15 seconds.

Optionally in any embodiment, the plasma generated for applying the tie coating or layer may be applied for a deposition time of 2 to 5 seconds, optionally for 2 to 3.5 seconds, optionally for 3.5 to 5 seconds.

Optionally in any embodiment, the plasma generated for applying the pH protective coating or layer may be applied for a deposition time of 10 to 40 seconds, optionally 10 to 30 seconds, optionally 10 to 20 seconds, optionally 10 to 15 seconds, optionally 15 to 20 seconds.

Optionally in any embodiment, the plasma generated for applying the lubricity coating or layer may be applied for a deposition time of 10 to 120 seconds, optionally for 30 to 90 seconds.

Optionally in any embodiment, a trilayer (tie layer, barrier layer, pH protective layer) coating may be simultaneously applied to 16 vessels by a 16-Up coater, such as that illustrated herein, in less than 120 seconds, optionally less than 110 seconds, optionally less than 100 seconds, optionally less than 90 seconds, optionally less than 80 seconds, optionally less than 75 seconds, optionally less than 70 seconds, optionally less than 65 seconds.

Optionally in any embodiment, the barrier coating or layer may be applied in a 16-Up coater, such as that illustrated herein, using a siloxane precursor feed rate, optionally of HMDSO, of from 1 to 10 sccm, optionally 3 to 5 sccm; and an oxygen precursor feed rate of from 10 to 100 sccm, optionally 20 to 50 sccm.

Optionally in any embodiment, the tie coating or layer may be applied in a 16-Up coater, such as that illustrated herein, using a siloxane precursor feed rate, optionally of HMDSO, of from 6 to 10 sccm, optionally 8 to 9 sccm; an oxygen precursor feed rate of from 1.7 to 4 sccm, optionally 2.5 to 4 sccm; and an inert gas (e.g. argon) feed rate of from 50 to 100 sccm, optionally 80 to 100 sccm.

Optionally in any embodiment, the pH protective coating or layer may be applied in a 16-Up coater, such as that illustrated herein, using a siloxane precursor feed rate, optionally of HMDSO, of from 6 to 10 sccm, optionally 8 to 9 sccm; an oxygen precursor feed rate of from 1.7 to 4 sccm, optionally 2.5 to 4 sccm; and an inert gas (e.g. argon) feed rate of from 50 to 100 sccm, optionally 80 to 100 sccm.

Optionally in any embodiment, the lubricity coating or layer may be applied in a 16-Up coater, such as that illustrated herein, using a siloxane precursor feed rate, optionally of OMCTS, of from 1 to 30 sccm, optionally 25 to 30 sccm; an oxygen precursor feed rate of from 0 to 100 sccm, optionally 0 to 10 sccm; a nitrogen precursor feed rate of from 0 to 100 sccm; and an inert gas (e.g. argon) feed rate of from 0 to 100 sccm, optionally 0 to 20 sccm.

Optionally in any embodiment, at least 12 vessels, alternatively at least 16 vessels, may be coated simultaneously (e.g., in a 12-Up coater, a 16-Up coater, a 24-Up coater, a 32-Up coater, or the like) using the same RF power source, the same vacuum source, the same precursor gas source(s), or any combination thereof. Optionally, during each coating step, the precursor gas may be equally distributed to all of the vessels by a gas manifold. Optionally, during each coating step, the vacuum may be equally distributed to all of the vessels by a vacuum manifold.

Optionally, in any embodiment, the precursor gases may be supplied directly into the lumen through a vessel opening, e.g. an open end of the vessel. In other embodiments, the precursor gases may be supplied through a gas outlet probe positioned within the lumen of the vessel. Optionally, in any embodiment, the outer surface of the vessel may also be coated, such as with an anti-static and/or anti-scratch coating, by PECVD and optionally pulsed PEVCD.

The pulsed RF plasma enables a more stable plasma vessel-to-vessel and run-to-run. Similarly, the 16 vessel coating system described herein enables more resolution on measured inputs such as pressure of the vacuum, gas flow, and power. The tunable RF generator provides 100 mV resolution, which provides better plasma control. In addition, the matching network of the RF generator provides improved tunability covering a wide range of conductance that can be adjusted to match any changes in reactor layout, such as electrode geometry, for example. The matching network of the RF power supply 601 may be tuned to match the system design to process inputs, which may be different for different sized and/or shaped vessels, such as vials, syringes, etc.

With the increased volume to fill with a single source of gas and single source of evacuation in a sixteen vessel coating system as described above, there is more resolution and less error in run-to-run variation for the mass flow controllers and pressure gauges. Furthermore, the pulsing of the plasma RF power minimizes the effect of heat load during the coating process, which in turn allows higher power than in conventional systems to get the best barrier performance possible. Depositing a trilayer coating without breaking vacuum greatly reduces process time and can improve layer quality as there is no exposure to the environment between layers as occurs in separate layer coatings.

Further, the RF electrode design, with a single electrode and connection, results in improved plasma uniformity as compared to having an electrode for every vessel to be coated, and also minimizes parasitic effects when applying the RF signal. The goal of the coating layers is to provide a barrier that can mimic the performance of glass as a gas barrier, such as an oxygen barrier. An optimized barrier has reduced defects with a higher coating density grown with a stable plasma, with efficient hardware and control. Increasing the capacity of the system to sixteen vessels or more allows for improved stability electrically with stable process pressure and gas delivery control. The RF power supply 601 may provide RF powers up to 1 kW or more, where at 1 kW the RF energy is more reproducible and allows for 100 mV resolution control.

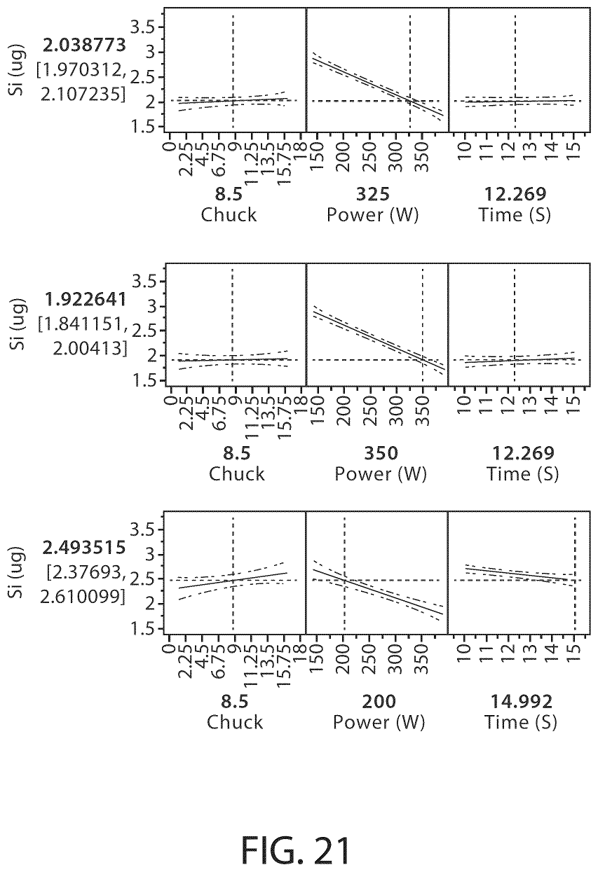

FIG. 21 shows design-of-experiment scatter plots of dissolution rates for vials coated in a pulsed RF PECVD system, in accordance with an example embodiment of the disclosure. Referring to FIG. 21, the design-of-experiments show that in the 300-350 W power range for a pH protective layer, the cycle time can be 10 or 15 sec, and performance per dissolution (Si(μg)) performs equally over all 16 parts, indicated by the essentially flat Si(μg) plot for each chuck position 1-16. In contrast, it is shown that some variation in coating performance may result at lower powers, such as 200 W.

### EXAMPLES

### Example 1

To characterize the performance of the barrier layer for 10 mL vials coated using an embodiment of the method and system disclosed herein, 80 COP vessels were coated with a barrier layer for one of nine different defined periods of time (with all other coating parameters kept the same). For each period of time, five vessels were coated. Two of the five vessels were used for thickness testing and three of the five vessels were used for OTR testing. For each vessel, a 2-second adhesive (tie) layer was first applied, thus ensuring that the plasma for the barrier layer ignites with minimum delays. The coating parameters are shown in Table 1, below:

TABLE 1

| | | Delay | Argon | Oxygen | HMDSO | Power | Time | Layers for |
|---|---|---|---|---|---|---|---|---|
| Condition | Layer | (s) | (sccm) | (sccm) | (sccm) | (W) | (s) | Filmetrics |
| 1 | A | 5 | 60 | 2.5 | 9 | 270 | 2 | |
| | Barrier | 5 | 0 | 99 | 2 | 500 | 1 | 10 |
| 2 | A | 5 | 60 | 2.5 | 9 | 270 | 2 | |
| | Barrier | 5 | 0 | 99 | 2 | 500 | 20 | 1 |
| 3 | A | 5 | 60 | 2.5 | 9 | 270 | 2 | |
| | Barrier | 5 | 0 | 99 | 2 | 500 | 5 | 5 |
| 4 | A | 5 | 60 | 2.5 | 9 | 270 | 2 | |
| | Barrier | 5 | 0 | 99 | 2 | 500 | 30 | 1 |
| 5 | A | 5 | 60 | 2.5 | 9 | 270 | 2 | |
| | Barrier | 5 | 0 | 99 | 2 | 500 | 3 | 10 |
| 6 | A | 5 | 60 | 2.5 | 9 | 270 | 2 | |
| | Barrier | 5 | 0 | 99 | 2 | 500 | 2 | 10 |
| 7 | A | 5 | 60 | 2.5 | 9 | 270 | 2 | |
| | Barrier | 5 | 0 | 99 | 2 | 500 | 7 | 5 |
| 8 | A | 5 | 60 | 2.5 | 9 | 270 | 2 | |
| | Barrier | 5 | 0 | 99 | 2 | 500 | 10 | 2 |
| 9 | A | 5 | 60 | 2.5 | 9 | 270 | 2 | |
| | Barrier | 5 | 0 | 99 | 2 | 500 | 15 | 2 |

The coated samples were then tested for barrier layer thickness (by a filmetrics sensor) and as oxygen transmission rate (OTR). From the thickness data, the general trend is that as the deposition time for the barrier layer increases, the thickness of the layer increases at a mostly steady rate.

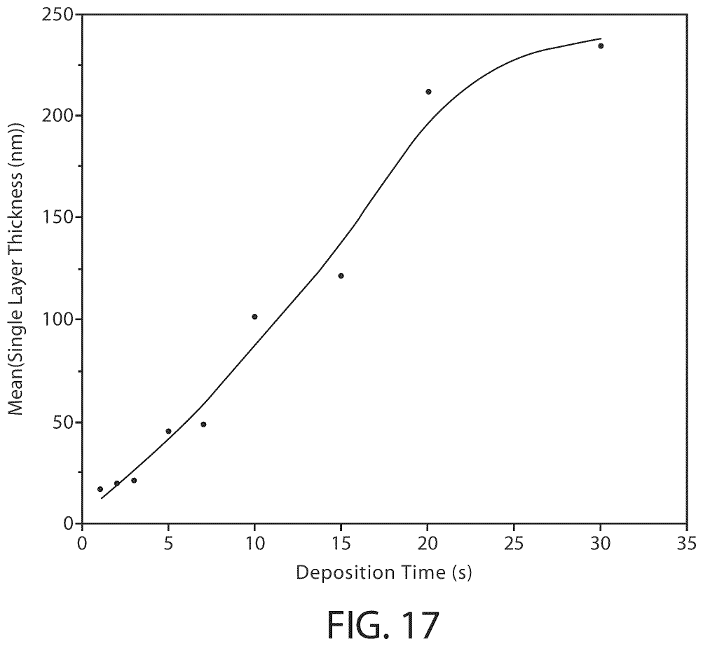

The results are shown in FIG. 17. Specifically, FIG. 17 illustrates layer thickness versus layer growth time in a pulsed RF PECVD system with sixteen vessels coated concurrently, in accordance with an example embodiment of the disclosure. Referring to FIG. 17, there is shown a thickness plot showing a near linear thickness variation with time, with some non-linearity at longer deposition times, such as over 20 seconds, for example.

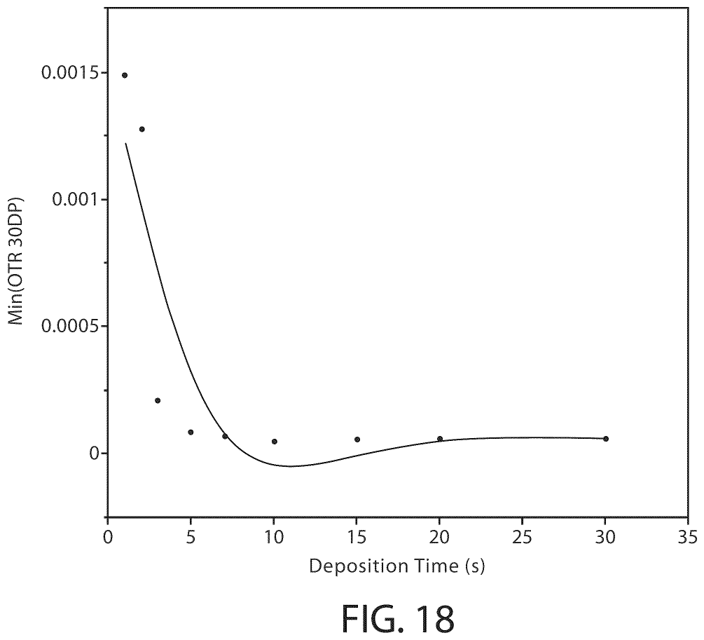

The results of the oxygen transmission rate testing are shown in FIG. 18. Specifically, FIG. 18 illustrates oxygen transmission rates for vials with barrier layers versus layer thickness, in accordance with an example embodiment of the disclosure. Referring to FIG. 18, the OTR results show that as deposition time increases, OTR decreases until around 10 seconds, at which point the OTR for greater deposition times remain low, indicating that beyond 10 seconds, the added time does not add to performance.

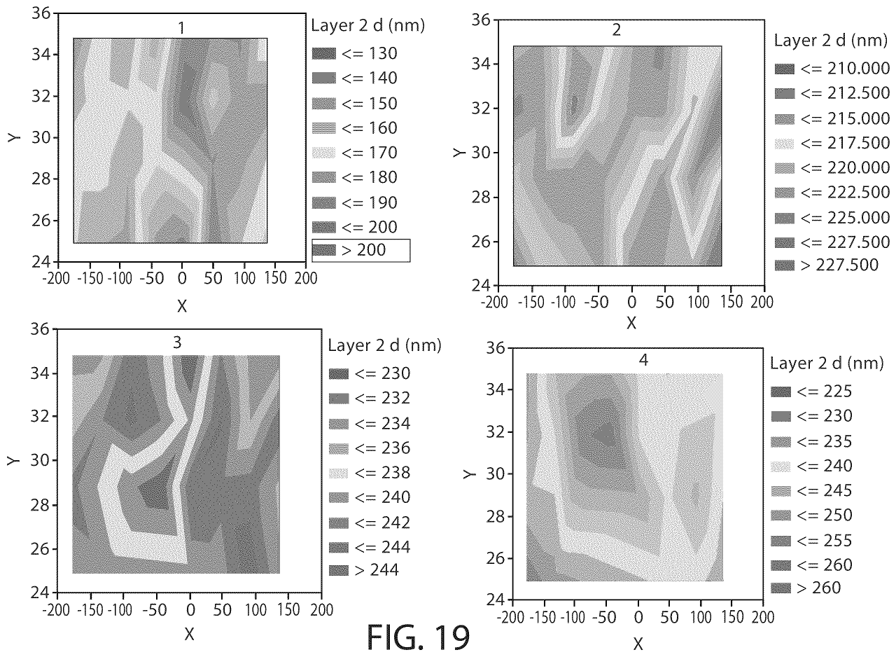

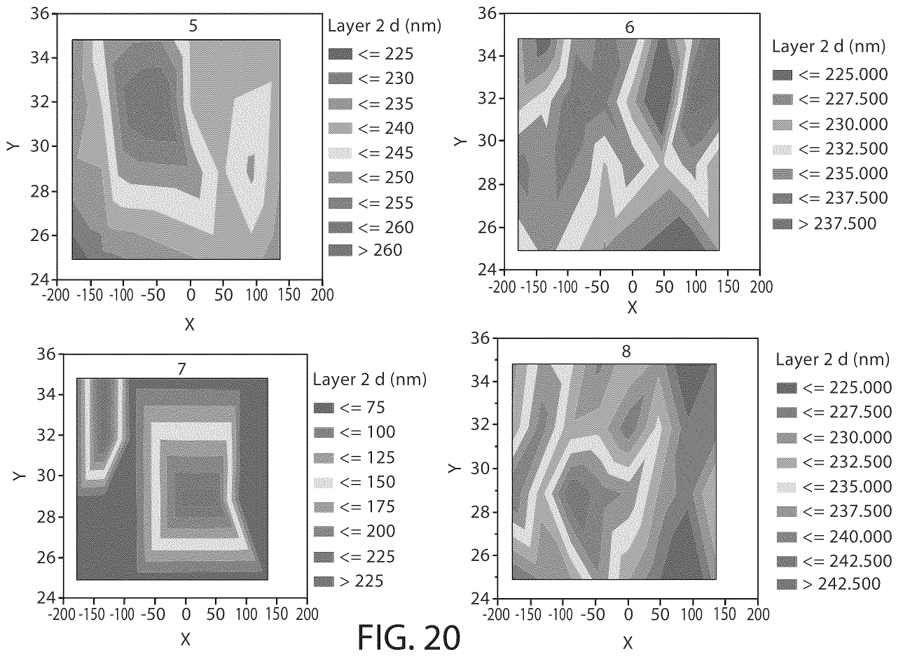

As part of the thickness testing, contour maps of the coating were also created. The results are shown in FIGS. 19 and 20. Referring to the figures, the contour maps show that the variation in thickness is random, rather than being due to a gradation along the length of the vial.

### Example 2

Pulsing rates (frequency and duty cycle) may impact the barrier performance of a coating set, e.g. a trilayer coating as described herein. To demonstrate the effects of pulsing rates, a 10 mL COP vessel was coated with a trilayer (tie layer, barrier layer, pH protective layer) using varying pulsing rates. The coating parameters for application of the barrier layer, using various duty cycles and various frequencies are shown in the tables below.

Pulsing at 25% DC:

| | Delay | Argon | Oxygen | HMDSO | Power | Time | Frequency | Duty |
|---|---|---|---|---|---|---|---|---|
| Condition | (s) | (sccm) | (sccm) | (sccm) | (W) | (s) | (Hz) | Cycle (%) |
| 1 | 10 | 0 | 99 | 2 | 436 | 30 | 200 | 25 |
| 2 | 10 | 0 | 99 | 2 | 436 | 30 | 150 | 25 |
| 3 | 10 | 0 | 99 | 2 | 436 | 30 | 100 | 25 |
| 4 | 10 | 0 | 99 | 2 | 436 | 30 | 75 | 25 |
| 5 | 10 | 0 | 99 | 2 | 436 | 30 | 50 | 25 |
| 6 | 10 | 0 | 100 | 1 | 500 | 50 | 40 | 25 |
| 7 | 10 | 0 | 100 | 1 | 500 | 50 | 40 | 25 |
| 8 | 10 | 0 | 99 | 2 | 436 | 30 | 30 | 25 |
| 9 | 10 | 0 | 99 | 2 | 436 | 30 | 10 | 25 |
| 10 | 10 | 0 | 100 | 1 | 200 | 30 | 4 | 25 |
| 11 | 10 | 0 | 100 | 1 | 200 | 70 | 4 | 25 |

Pulsing at 50% DC:

| | Delay | Argon | Oxygen | HMDSO | Power | Time | Frequency | Duty |
|---|---|---|---|---|---|---|---|---|
| Condition | (s) | (sccm) | (sccm) | (sccm) | (W) | (s) | (Hz) | Cycle (%) |
| 1 | 10 | 0 | 100 | 4 | 200 | 40 | 4 | 50 |
| 2 | 10 | 0 | 100 | 4 | 200 | 60 | 4 | 50 |
| 3 | 10 | 0 | 100 | 1 | 200 | 30 | 4 | 50 |
| 4 | 10 | 0 | 100 | 4 | 600 | 50 | 40 | 50 |
| 5 | 10 | 0 | 100 | 4 | 600 | 30 | 40 | 50 |
| 6 | 10 | 0 | 100 | 4 | 600 | 70 | 40 | 50 |
| 7 | 10 | 0 | 99 | 2 | 450 | 15 | 200 | 50 |
| 8 | 10 | 0 | 99 | 2 | 450 | 15 | 250 | 50 |
| 9 | 10 | 0 | 99 | 2 | 450 | 15 | 300 | 50 |
| 10 | 10 | 0 | 99 | 2 | 450 | 15 | 350 | 50 |
| 11 | 10 | 0 | 99 | 2 | 450 | 15 | 400 | 50 |
| 12 | 10 | 0 | 99 | 2 | 450 | 15 | 450 | 50 |
| 13 | 10 | 0 | 99 | 2 | 450 | 15 | 500 | 50 |

Pulsing at 80% DC:

| | Delay | Argon | Oxygen | HMDSO | Power | Time | Frequency | Duty |
|---|---|---|---|---|---|---|---|---|
| Condition | (s) | (sccm) | (sccm) | (sccm) | (W) | (s) | (Hz) | Cycle (%) |
| 1 | 10 | 0 | 99 | 2 | 450 | 15 | 500 | 80 |
| 2 | 10 | 0 | 99 | 2 | 450 | 15 | 450 | 80 |
| 3 | 10 | 0 | 99 | 2 | 450 | 15 | 400 | 80 |
| 4 | 10 | 0 | 99 | 2 | 450 | 15 | 350 | 80 |
| 5 | 10 | 0 | 99 | 2 | 450 | 15 | 300 | 80 |
| 6 | 10 | 0 | 99 | 2 | 450 | 15 | 250 | 80 |
| 7 | 10 | 0 | 99 | 2 | 450 | 15 | 200 | 80 |
| 8 | 10 | 0 | 99 | 2 | 436 | 30 | 150 | 80 |

Pulsing at various DC:

| | Delay | Argon | Oxygen | HMDSO | Power | Time | Frequency | Duty |
|---|---|---|---|---|---|---|---|---|
| Condition | (s) | (sccm) | (sccm) | (sccm) | (W) | (s) | (Hz) | Cycle (%) |
| 1 | 10 | 0 | 99 | 2 | 436 | 30 | 150 | 100 |
| 2 | 10 | 0 | 99 | 2 | 436 | 30 | 150 | 30 |
| 3 | 10 | 0 | 99 | 2 | 436 | 30 | 150 | 10 |

Oxygen transmission rate (OTR) testing was utilized on the coated samples to evaluate barrier layer performance. To perform the testing, a sensor was placed within a coated vial and the vial was epoxied on a glass slide in a glove box. The partial pressure of oxygen was measured by a Mocon-Optech oxygen-platinum system at different points. These readings were then converted by a macro into the OTR constant, which is a metric that judges the barrier layer performance of the vial. Typically, uncoated vials have an OTR constant of about 0.007. Glass has a reference value of 0.

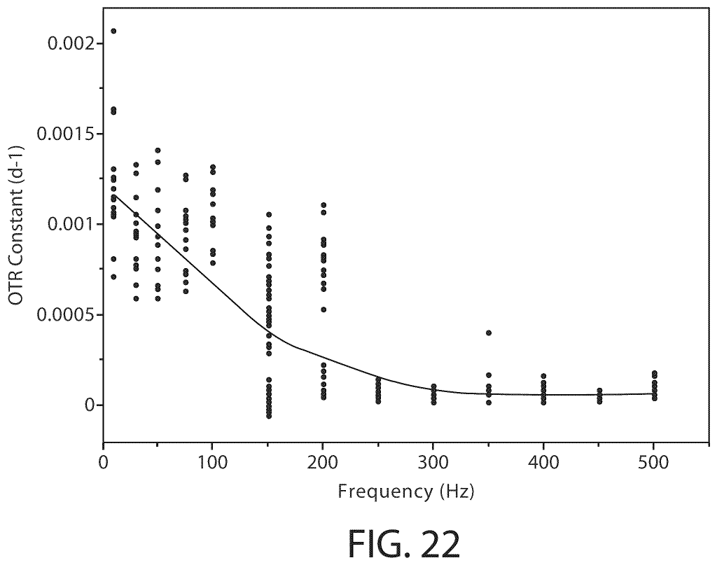

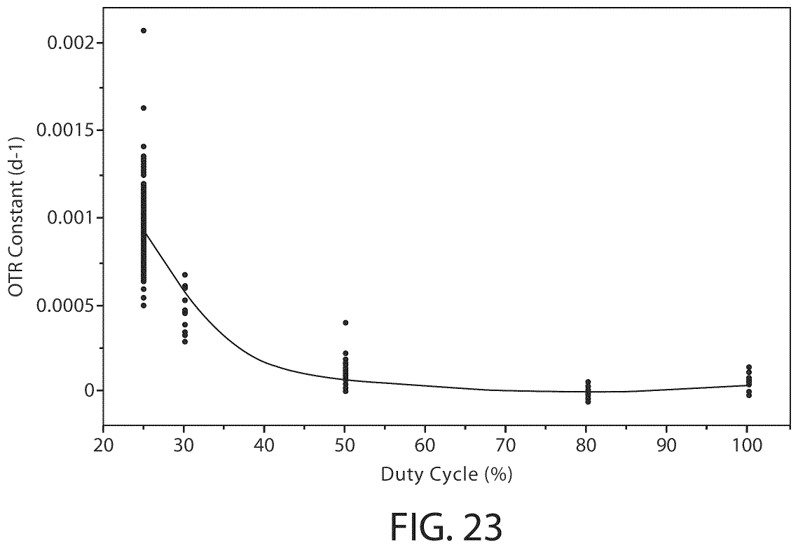

The results are shown in FIGS. 22 and 23, which illustrate OTR constants versus plasma pulsing rates. FIG. 22 shows improved OTR with increased frequency, with the improvement levelling off above 200 Hz at an OTR constant of less than 0.00025 d⁻¹. Similarly, FIG. 23 shows improved OTR with increased duty cycle, with the improvement leveling off above 50% at an OTR constant below 0.00025 d⁻¹. The results demonstrate that significant improvement in barrier layer OTR can be obtained through control of the RF power pulsing frequency. Namely, higher frequency and increased duty cycle pulsing produces lower OTR constants and better barrier performance, though the effect levels off beyond a certain frequency and duty cycle.

### Example 3

In order to obtain consistency between the coatings on vessels that are coated in a high-capacity system, such as an embodiment of a 16-cavity system as described herein, it is important that the vacuum pressure in each vessel is substantially identical to the vacuum pressure in every other vessel within the multi-cavity system. It is also important that the amount of precursor gas introduced into each vessel during each coating step is substantially identical to the amount of precursor gas introduced into every other vessel within the multi-cavity system.

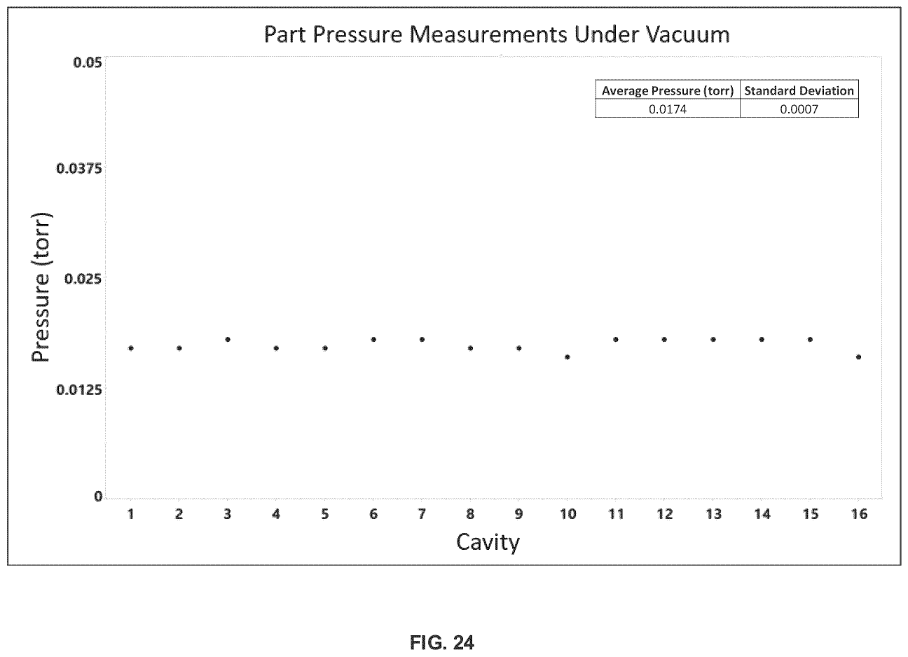

FIG. 24 illustrates vacuum pressure uniformity that was achieved between vessels placed in a 16-cavity pulsed RF PECVD system in accordance with an example embodiment of the disclosure. Referring to FIG. 24, there is shown pressure readings under vacuum for each vessel in the 16-cavity pulsed RF PECVD system equipped with an exhaust manifold as described above. As can be seen from the plot, the pressure is highly uniform across all sixteen vessels (also referred to as parts) being coated, with a 0.07% standard deviation and a 0.0174 Torr average.

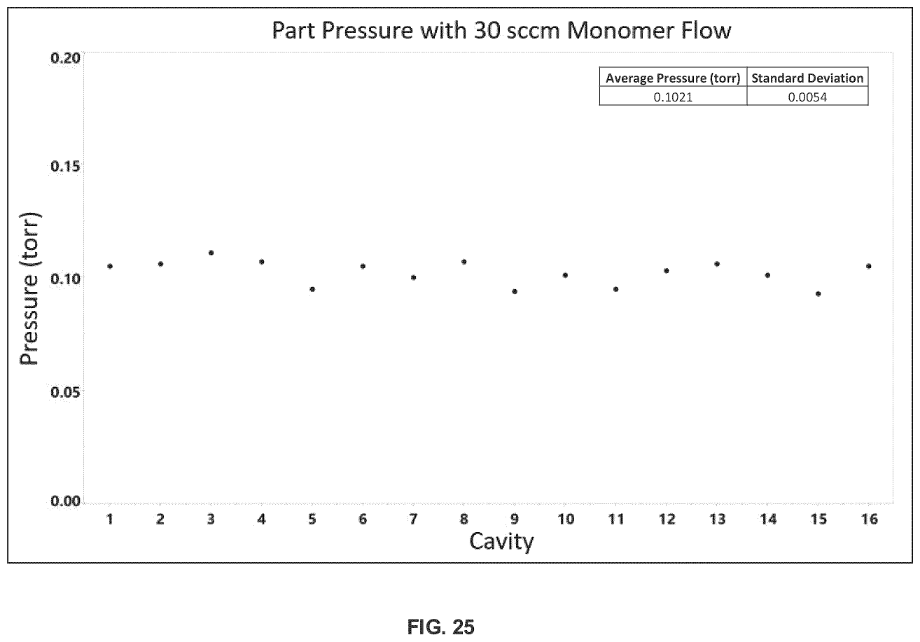

FIG. 25 illustrates pressure uniformity that was achieved under a precursor gas flow between vessels placed in a 16-cavity pulsed RF PECVD system in accordance with an example embodiment of the disclosure. Referring to FIG. 25, there is shown pressure readings under 30 sccm monomer gas flow for each vessel in the 16-cavity pulsed RF PECVD system equipped with a gas distribution manifold as described above. As can be seen from the plot, the pressure is highly uniform across all sixteen vessels (also referred to as parts) being coated, with a 0.54% standard deviation and a 0.1021 Torr average.

### Example 4

Further testing was performed to analyze the consistency and coating integrity of the coatings applied across vessels coated in a 16-cavity pulsed RF PECVD system in accordance with an embodiment of the disclosure. Sample vials were coated in a 16-cavity pulsed RF PECVD system in accordance with an embodiment of the disclosure, and then each of the coated vessels was tested for total silicon dissolution after 3 days when contacted with a fluid having a pH of 9.

The vessels were coated according to the following parameters:

| | Delay to | Argon | Oxygen | HMDSO | Power | Time | Frequency | Duty |
|---|---|---|---|---|---|---|---|---|
| Layer | start(sec) | (sccm) | (sccm) | (sccm) | (W) | (Sec) | (Hz) | Cycle |
| Adhesion | 5 | 60 | 2.5 | 9 | 270 | 5 | 250 | 80 |
| Barrier | 5 | 0 | 100 | 2 | 450 | 15 | 250 | 99 |
| Protective | 5 | 60 | 2.5 | 9 | 270 | 10 | 250 | 80 |

A five second delay to start (i.e. time before the RF power was turned on for each coating step) was included in order to ensure stabilization of the pressure and gas flows within each vessel for purposes of the testing. It is believed that the delay to start time could be minimized to less, and perhaps significantly less, than 5 seconds, however, without major sacrifices in consistency.

The vessels were then tested for total silicon dissolution. The test method quantifies silicon using inductively coupled plasma optical emission spectroscopy (ICP-OES). A pH 9 solution is used to extract silicon from the coating of the vessels under controlled conditions and for a set period of time to provide information about the lot-to-lot functional and compositional consistency of the protective layer of the coating. This method also provides a means of confirming the presence and/or functionality of an adhesive layer through a visual assessment of delamination.

For testing, each vessel was filled with a 50 mM potassium phosphate solution that had been adjusted to a pH of 9. A stopper (treated to remove any silicone oil) was then inserted into the lumen opening. The filled, sealed containers were then placed in an incubator at 40° C. and remained there for about 72 hours. A visual inspection was utilized to confirm that there were no particulates or delamination. The vessel was then opened and the contents poured into a polypropylene centrifuge tube and diluted with 2% nitric acid. The diluted solution was then analyzed by ICP-OES, e.g. by an ICP-OES Perkin Elmer Optima 8300 with ESI auto sampler or an equivalent, using calibration standards to ensure accurate measurements.

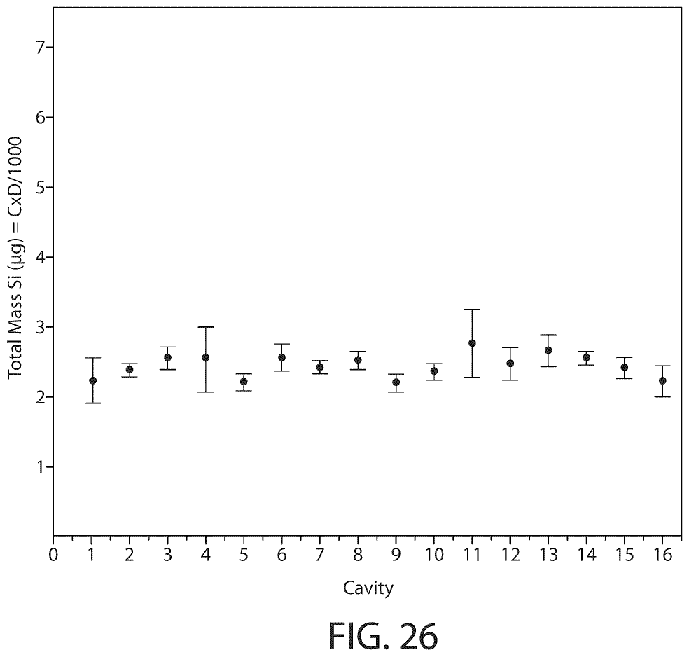

The results of the coating integrity and consistency testing are shown in FIG. 26. Referring to FIG. 26, the total mass of dissolved silicon for each of sixteen vessels that were coated using a 16-cavity pulsed RF PECVD system in accordance with an embodiment of the present disclosure is shown. The results of FIG. 26 demonstrate substantially equal coating integrity performance, within the error of the test method.

### Example 5

Additional testing was performed to analyze the consistency of the oxygen barrier properties of coatings applied to vessels using multiple 16-cavity pulsed RF PECVD systems across eight hours of continuous production.

The vials were coated according to the following parameters:

| | Delay to | Argon | Oxygen | HMDSO | Power | Time | Frequency | Duty |
|---|---|---|---|---|---|---|---|---|
| Layer | start(sec) | (sccm) | (sccm) | (sccm) | (W) | (Sec) | (Hz) | Cycle |
| Adhesion | 5 | 60 | 2.5 | 9 | 270 | 5 | 250 | 80 |
| Barrier | 5 | 0 | 100 | 2 | 450 | 15 | 250 | 99 |
| Protective | 5 | 60 | 2.5 | 9 | 270 | 10 | 250 | 80 |

A five second delay to start (i.e. time before the RF power was turned on for each coating step) was included in order to ensure stabilization of the pressure and gas flows within each vessel for purposes of the testing. It is believed that the delay to start time could be minimized to less, and perhaps significantly less, than 5 seconds, however, without major sacrifices in consistency

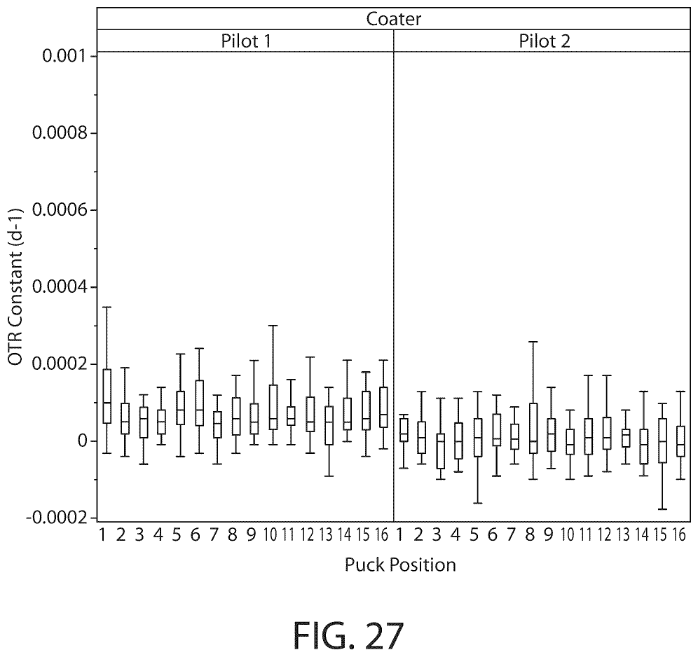

Sixteen vessels coated by each of the two different systems were selected and tested for oxygen transmission rate (OTR) as described above. The results of the testing are shown in FIG. 27. Referring to FIG. 27, there is shown OTR constant measurements for coated vessels, identified by cavity or puck position #1 through #16, for two different coating systems, i.e. coaters, operating over eight hours. The results show equivalent oxygen barrier performance between the vessels, with the OTR differences being within the error of the test method. Some negative values are due to there being no change in oxygen ingress, meaning perfect barrier performance over the duration of the oxygen transmission rate testing.

### Example 6

Additional testing was performed to analyze the oxygen barrier properties of CBC vessels coated using a 16-cavity pulsed RF PECVD system in accordance with en embodiment of the disclosure and to compare their oxygen barrier performance to COP vessels coated under the same conditions.

10 mL vials of (1) VIVION™ 0510 CBC, (2) VIVION™ 0510HF CBC, and (3) ZEONEX® 690R COP (manufactured by Zeon Chemicals L.P.) were coated according to the following parameters:

| | Delay to | Argon | Oxygen | HMDSO | Power | Time | Frequency | Duty |
|---|---|---|---|---|---|---|---|---|
| Layer | start(sec) | (sccm) | (sccm) | (sccm) | (W) | (Sec) | (Hz) | Cycle |
| Adhesion | 5 | 60 | 2.5 | 9 | 270 | 5 | 250 | 80 |
| Barrier | 5 | 0 | 100 | 2 | 450 | 15 | 250 | 99 |
| Protective | 5 | 60 | 2.5 | 9 | 270 | 10 | 250 | 80 |

A five second delay to start (i.e. time before the RF power was turned on for each coating step) was included in order to ensure stabilization of the pressure and gas flows within each vessel for purposes of the testing. It is believed that the delay to start time could be minimized to less, and perhaps significantly less, than 5 seconds, however, without major sacrifices in consistency

The coated vials were then tested for oxygen transmission rate (OTR) as described above. Uncoated samples of each type of vial were also tested for OTR as a control and to demonstrate the improvement in OTR provided by the coating set.

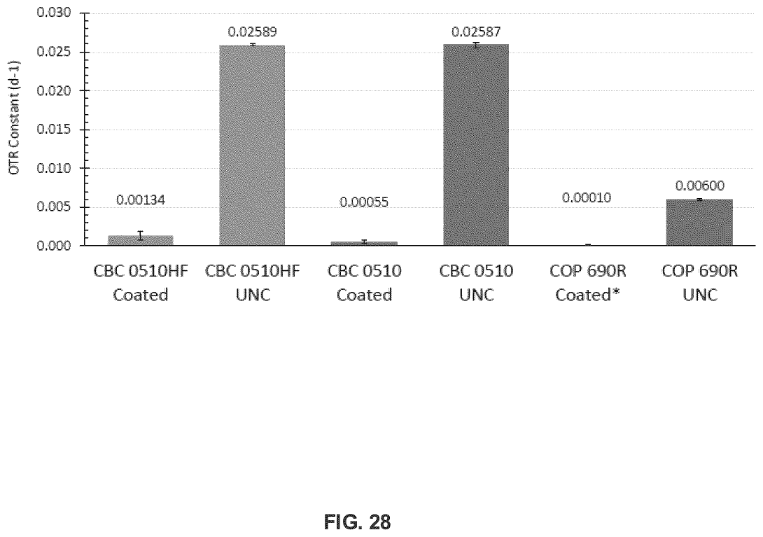

FIG. 28 is a plot showing the results. The results demonstrated that the vials made from the two CBC resins had significantly higher oxygen transmission rate constants than the vial made from the COP resin, in particular about 4 times higher. Notably, however, the application of the coating reduced the oxygen transmission rate constant of the vials made from the two CBC resins to about 2% to about 5% of the oxygen transmission rate constant of the uncoated CBC vial, i.e. a reduction of about 95% to about 98%, producing a CBC vessel having an oxygen transmission rate constant relatively close to that of the coated COP vial. Moreover, by varying the thickness of the barrier coating, it is believed that the OTR constant of a vial made from a CBC resin can be reduced even further.

In some embodiments, for example, a vessel, e.g. a vial, having a wall made of a CBC resin may be coated with a barrier coating so as to provide the wall with an oxygen transmission rate constant (d-1) of less than 0.0020, alternatively less than 0.0015, alternatively less than 0.0013, alternatively less than 0.0010, alternatively less than 0.0009, alternatively less than 0.0008, alternatively less than 0.0007, alternatively less than 0.0006, alternatively less than 0.0005, alternatively less than 0.0004, alternatively less than 0.0003, alternatively less than 0.0002, alternatively less than 0.0001.

It can be seen that the described embodiments provide unique and novel methods, systems, and coated vessels that have a number of advantages over those in the art. While there is shown and described herein certain specific structures embodying the invention, it will be manifest to those skilled in the art that various modifications and rearrangements of the parts may be made without departing from the spirit and scope of the underlying inventive concept and that the same is not limited to the particular forms herein shown and described except insofar as indicated by the scope of the appended claims.

1. A method of simultaneously coating a plurality of vessels, the method comprising:
placing the plurality of vessels in openings in a metal RF electrode;
evacuating an internal volume of each of the plurality of vessels using a single vacuum line via an exhaust manifold;
introducing one or more source gases into each of the plurality of vessels using a single source line via a gas inlet manifold;
generating a plasma within each of the plurality of vessels using the one or more source gases and a pulsed RF signal applied to the metal RF electrode; and
depositing a coating comprising at least one barrier coating or layer in each of the plurality of vessels using the plasma;
wherein the metal RF electrode comprises a plurality of wall portions, each of which surrounds a wall of one of the plurality of vessels;
wherein each of the wall portions is integral with the rest of the electrode; and
wherein the plurality of vessels comprises at least twelve vessels.

2. The method of claim 1, wherein the pulsed RF signal has a pulse high power level between 250 W and 1000 W.

3. The method according to claim 2, where the pulsed RF signal has a pulse low power level of 0 W.

4. The method according to claim 1, wherein the pulsed RF signal has a duty cycle between 25% and 99%.

5. The method according to claim 1, wherein the pulsed RF signal has a pulse train frequency between 150 kHz and 500 kHz.

6. The method according to claim 1, comprising introducing the one or more source gases into each vessel without a gas inlet probe within the vessel.

7. The method according to claim 1, comprising introducing the one or more source gases into each vessel using a gas inlet probe within the vessel.

8. The method according to claim 1, wherein the coating further comprises a tie coating or layer, the tie coating or layer having an interior surface facing the barrier coating or layer and an outer surface facing the wall interior surface.

9. The method of claim 8, wherein the tie coating or layer comprises SiOₓC_{y} or SiNₓC_{y} wherein x is from about 0.5 to about 2.4 and y is from about 0.6 to about 3.

10. The method according to claim 1, wherein the coating further comprises a pH coating or layer, the pH coating or layer having an interior surface facing the lumen and an outer surface facing the barrier coating or layer.

11. The method of claim 10, wherein the pH protective coating or layer comprises SiOₓC_{y} or SiNₓC_{y} wherein x is from about 0.5 to about 2.4 and y is from about 0.6 to about 3.

12. The method of claim 1, in which a vessel wall being coated comprises or consists of a thermoplastic.

13. The method of claim 12, wherein the vessel wall being coated comprises a cyclic block copolymer (CBC) resin.

14. The method of claim 1, wherein each of the plurality of wall portions comprises a window opening through which the plasma can be viewed.

15. The method of claim 14, further comprising one or more cameras configured to capture images of the plasma through the plurality of windows.

16. The method of claim 15, further comprising interrogating images captured by the one or more camera to determine whether the plasma within each of the plurality of vessels has one or more properties within a predefined acceptable range.

17. The method of claim 1, wherein an opening of each of the plurality of vessels is oriented downward in the opening of the RF electrode, and wherein each of the gas inlet manifold and the exhaust manifold are positioned below the metal RF electrode.

18. The method of claim 1, wherein the vessels are syringe barrels, vials, or blood collection tubes.

19. A method of simultaneously coating a plurality of vessels, the method comprising:
placing the plurality of vessels in openings in a metal RF electrode;
evacuating an internal volume of each of the plurality of vessels using a single vacuum line via an exhaust manifold;
introducing one or more source gases into each of the plurality of vessels using a single source line via a gas inlet manifold; wherein the one or more source gases flow through a partition immediately before entering the vessel through an opening of the vessel, the partition being permeable to the one or more source gases but preventing the plasma from igniting outside of the vessel;
generating a plasma within each of the plurality of vessels using the one or more source gases and a pulsed RF signal applied to the metal RF electrode; and
depositing a coating comprising at least one barrier coating or layer in each of the plurality of vessels using the plasma;
wherein the plurality of vessels comprises at least twelve vessels.

20. The method of claim 19, wherein the vessels are syringe barrels, vials, or blood collection tubes.
